(19) United States
(12) Patent Application Publication
(10) Pub. No.: US 2026/0150486 A1
(43) Pub. Date: May 28, 2026

(54) ORGANIC ELECTROLUMINESCENT DEVICE

(71) Applicant: DuPont Specialty Materials Korea Ltd., Chungcheongnam-do (KR)

(72) Inventors: Doo-Hyeon MOON, Gyeonggi-do (KR); Mi-Ja LEE, Gyeonggi-do (KR); Chi-Sik KIM, Gyeonggi-do (KR); Yoo-Jin DOH, Gyeonggi-do (KR); HaeYeon KIM, Gyeonggi-do (KR); So-Mi PARK, Gyeonggi-do (KR); Su-Hyun LEE, Gyeonggi-do (KR)

(21) Appl. No.: 19/049,577

(22) Filed: Feb. 10, 2025

(30) Foreign Application Priority Data
Mar. 4, 2024 (KR) 10-2024-0030638
Dec. 26, 2024 (KR) 10-2024-0196924

(51) Int. Cl. H10K 50/12; C09K 11/06; H10K 50/18; H10K 50/19; H10K 85/30; H10K 85/60; H10K 101/00

(52) U.S. Cl. CPC H10K 50/12; C09K 11/06; H10K 50/181; H10K 50/19; H10K 85/342; H10K 85/622; H10K 85/626; H10K 85/633; H10K 85/636; H10K 85/654; H10K 85/656; H10K 85/6572; H10K 85/6574; H10K 85/6576; C09K 2211/1011; H10K 2101/90

(57) ABSTRACT

The present disclosure relates to an organic electroluminescent device. By including a compound and/or an organic electroluminescent material according to the present disclosure, an organic electroluminescent device exhibiting longer lifespan characteristics compared to a conventional organic electroluminescent device can be provided.

### TECHNICAL FIELD

The present disclosure relates to an organic electroluminescent device.

### BACKGROUND ART

The TPD/Alq₃ bilayer small-molecule organic electroluminescent device (OLED) with green emission, which is constituted with a light-emitting layer and a charge transport layer, was first developed by Tang et al. of Eastman Kodak in 1987. Thereafter, studies on organic electroluminescent devices have proceeded rapidly, and OLEDs have since been commercialized. At present, OLEDs primarily use phosphorescent materials having excellent luminous efficiency in panel implementation. In many applications such as TVs and lightings, OLED lifetime is insufficient, and high OLED efficiency is still required. Typically, the higher the luminance of an OLED becomes, the lifetime of the OLED shortens correspondingly. Therefore, an OLED having long lifespan characteristics is required for long-term use and high display resolution.

Various materials or concepts have been proposed for the organic layer of an organic electroluminescent device in order to improve lifespan characteristics, but these have not been satisfactory for practical use. In addition, there is a continuous need to develop organic electroluminescent devices with improved performance, such as improved lifespan characteristics compared to previously disclosed specific combination of compounds.

However, Korean Patent Application Laid-open No. 2023-0046493, Korean Patent Application Laid-open No. 2022-0081251, and Korean Patent Application Laid-open No. 2022-0147537 disclose an organic electroluminescent device comprising deuterated compounds, but do not specifically disclose an organic electroluminescent device having overall device stability by including deuterated compounds in at least one of a hole transport zone, a light-emitting layer, and an electron transport zone.

### DISCLOSURE OF THE INVENTION

### Technical Problem

The object of the present disclosure is to provide an organic electroluminescent device exhibiting longer lifespan characteristics than conventional organic electroluminescent devices.

### Solution to Problem

As a result of intensive studies to solve the technical problem above, the present inventors found that the aforemention'ed objective can be achieved by an organic electroluminescent device comprising: a first electrode; a second electrode; and a hole transport zone, at least one light-emitting layer, and an electron transport zone positioned between the first electrode and the second electrode, wherein the light-emitting layer comprises at least one deuterated compound and at least four different compounds, and at least one zone of the hole transport zone and the electron transport zone comprises at least one deuterated compound, thereby completing the present invention.

### Advantageous Effects of Invention

By comprising at least one deuterated compound in each of the light-emitting layer and at least one zone of the hole transport zone and the electron transport zone as an organic electroluminescent material, the organic electroluminescent device according to the present disclosure exhibits significantly improved long lifespan characteristics.

### EMBODIMENTS OF THE INVENTION

Hereinafter, the present disclosure will be described in detail. However, the following description is intended to explain the invention, and is not meant in any way to restrict the scope of the invention.

The organic electroluminescent device according to the present disclosure comprises a first electrode; a second electrode; and a hole transport zone, at least one light-emitting layer, and an electron transport zone positioned between the first electrode and the second electrode, wherein the light-emitting layer comprises at least one deuterated compound and at least four different compounds, and at least one zone of the hole transport zone and the electron transport zone comprises at least one deuterated compound.

Herein, the term “organic electroluminescent compound” in the present disclosure means a compound that may be used in an organic electroluminescent device, and this may be comprised in any material layer constituting an organic electroluminescent device, as necessary.

Herein, the term “organic electroluminescent material” means a material that may be used in an organic electroluminescent device, and this may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron-blocking material, a light-emitting material (containing host and dopant materials), an electron buffer material, a hole-blocking material, an electron transport material, or an electron injection material, etc.

The term “a plurality of organic electroluminescent materials” in the present disclosure means an organic electroluminescent material comprising a combination of at least two compounds, which may be comprised in any layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of at least two compounds, which may be comprised in at least one layer of a hole injection layer, a hole transport layer, a hole auxiliary layer, a light-emitting auxiliary layer, an electron-blocking layer, a light-emitting layer, an electron buffer layer, a hole-blocking layer, an electron transport layer, and an electron injection layer. As such, at least two compounds may be comprised in the same layer or in different layers, and may be mixture-evaporated or co-evaporated, or may be individually evaporated.

Herein, the term “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g., after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two compounds are comprised in one light-emitting layer, the at least two compounds may be mixture-evaporated to form a layer or may be individually and simultaneously co-evaporated to form a layer.

Herein, “(C₁-C₃₀)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. Herein, the “(C₃-C₃₀)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. “(3- to 7-membered)heterocycloalkyl” in the present disclosure is meant to be a cycloalkyl having 3 to 7 ring backbone atoms, preferably 5 to 7 ring backbone atoms and including at least one heteroatom selected from the group consisting of B, N, O, S, Si, and P, preferably O, S, and N, and includes tetrahydrofuran, pyrrolidine, thiolan, tetrahydropyran, etc. The “(C6-C30)aryl(ene)” in the present disclosure is meant to be a monocyclic or fused ring radical derived from an aromatic hydrocarbon having 6 to 30 ring backbone carbon atoms, in which the number of the ring backbone carbon atoms is preferably 6 to 20, more preferably 6 to 15. The above aryl may be partially saturated and may comprise a spiro structure. Examples of the aryl specifically include phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl, spiro[fluorene-fluorene]yl, spiro[fluorene-benzofluorene]yl, azulenyl, tetramethyl-dihydrophenanthrenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. The “(3- to 30-membered)heteroaryl(ene)” in the present disclosure is an aryl having 3 to 30 ring backbone atoms and including at least one heteroatom selected from the group consisting of B, N, O, S, Si, P, Se, and Ge in which the number of the ring backbone atoms is preferably 5 to 25. The number of the heteroatoms in the heteroaryl is preferably 1 to 4. The above heteroaryl may be a monocyclic ring, or a fused ring condensed with at least one benzene ring, and may be partially saturated. Also, the above heteroaryl herein may be one formed by linking at least one heteroaryl or aryl group to a heteroaryl group via a single bond(s). Examples of the heteroaryl specifically may include a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthiridinyl, benzofuropyrimidinyl, naphthofuropyrimidinyl, benzothienoquinolinyl, benzothienoquinazolinyl, benzothienonaphthiridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “heteroaryl(ene)” can be classified as a heteroaryl(ene) with electronic properties or a heteroaryl(ene) with hole properties. A heteroaryl(ene) with electronic properties is a substituent with relatively abundant electrons in the parent nucleus, and for example, it may be a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. A heteroaryl(ene), which has hole properties, is a substituent with a relative lack of electrons in the parent nucleus, and for example, it may be a substituted or unsubstituted carbazolyl, a substituted or unsubstituted dibenzofuranyl, or a substituted or unsubstituted dibenzothiophenyl. Herein, “a fused ring of (C3-C30) aliphatic ring and (C6-C30) aromatic ring” means a ring formed by fusing at least one aliphatic ring having 3 to 30 ring backbone carbon atoms in which the number of carbon atoms is preferably 3 to 25, more preferably 3 to 18, and at least one aromatic ring having 6 to 30 ring backbone carbon atoms in which the number of carbon atoms is preferably 6 to 25, more preferably 6 to 18. For example, the fused ring may be a fused ring of at least one benzene and at least one cyclohexane, or a fused ring of at least one naphthalene and at least one cyclopentane, etc. Herein, the carbon atoms in the fused ring of (C3-C30) aliphatic ring and (C6-C30) aromatic ring may be replaced with at least one heteroatom selected from B, N, O, S, Si, and P, preferably at least one heteroatom selected from N, O, and S. The “halogen” in the present disclosure includes F, Cl, Br, and I.

In addition, “ortho-” (“o-”), “meta-” (“m-”), and “para-” (“p-”) are meant to signify the substitution position of all substituents. An ortho-configuration describes a compound with substituents which are adjacent to each other, e.g., at the 1 and 2 positions on benzene. A meta-configuration indicates the next substitution position of the immediately adjacent substitution position, e.g., a compound with substituents at the 1 and 3 positions on benzene. A para-configuration indicates the next substitution position from the meta-position, e.g., a compound with substituents at the 1 and 4 positions on benzene.

Herein, “a ring formed in linking to an adjacent substituent” means a substituted or unsubstituted (3- to 30-membered) mono- or polycyclic, alicyclic, aromatic ring, or a combination thereof, formed by linking or fusing two or more adjacent substituents, and preferably this may be a substituted or unsubstituted (3- to 26-membered) mono- or polycyclic, alicyclic, aromatic ring, or a combination thereof. Further, the formed ring may include at least one heteroatom selected from the group consisting of B, N, O, S, Si, and P, preferably N, O, and S. According to one embodiment of the present disclosure, the number of ring backbone atoms is 5 to 20; according to another embodiment of the present disclosure, the number of ring backbone atoms is 5 to 15. In one embodiment, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, or a substituted or unsubstituted carbazole ring, etc.

In addition, the term “substituted” in the expression “substituted or unsubstituted” means that a hydrogen atom in a certain functional group is replaced with another atom or functional group, i.e., a substituent. Unless otherwise specified, the substituents may not be limited to hydrogen at positions where the substituents may be substituted, and when two or more hydrogen atoms are each replaced with a substituent in a functional group, the substituents may be the same as or different from each other. It also includes that the hydrogen atom is replaced with a group formed by a linkage of two or more substituents of the above substituents. For example, the “group formed by a linkage of two or more substituents” may be pyridine-triazine. That is, pyridine-triazine may be heteroaryl or may be interpreted as one substituent in which two heteroaryls are connected. Preferably, the substituted alkyl, the substituted alkenyl, the substituted cycloalkyl, the substituted cycloalkenyl, the substituted heterocycloalkyl, the substituted silyl, the substituted aryl(ene), the substituted heteroaryl(ene), the substituted alkoxy, the substituted trialkylsilyl, the substituted dialkylarylsilyl, the substituted alkyldiarylsilyl, the substituted triarylsilyl, the substituted fused ring of aliphatic ring and aromatic ring, the substituted mono- or di-alkylamino, the substituted mono- or di-alkenylamino, the substituted mono- or di-arylamino, the substituted mono- or di-heteroarylamino, the substituted alkylalkenylamino, the substituted alkylarylamino, the substituted alkylheteroarylamino, the substituted alkenylarylamino, the substituted alkenylheteroarylamino, the substituted arylheteroarylamino, the substituted dibenzofuranyl, the substituted dibenzothiophenyl, or the substituted carbazolyl in the formulas of the present disclosure each independently may be substituted with least one selected from the group consisting of: deuterium; halogen; cyano; carboxyl; nitro; hydroxyl; phosphine oxide; (C1-C30)alkyl; halo(C1-C30)alkyl; (C2-C30)alkenyl; (C2-C30)alkynyl; (C1-C30)alkoxy; (C1-C30)alkylthio; (C3-C30)cycloalkyl; (C3-C30)cycloalkenyl; (3- to 7-membered)heterocycloalkyl; (C6-C30)aryloxy; (C6-C30)arylthio; (C6-C30)aryl unsubstituted or substituted with at least one of (C1-C30)alkyl, (C6-C30)aryl and (3- to 30-membered)heteroaryl; (3- to 30-membered)heteroaryl unsubstituted or substituted with at least one (C6-C30)aryl; tri(C1-C30)alkylsilyl; tri(C6-C30)arylsilyl; di(C1-C30)alkyl(C6-C30)arylsilyl; (C1-C30)alkyldi(C6-C30)arylsilyl; a fused ring of (C3-C30) aliphatic ring and (C6-C30) aromatic ring; amino; mono- or di-(C1-C30)alkylamino; mono- or di-(C2-C30)alkenylamino; mono- or di-(C6-C30)arylamino unsubstituted or substituted with (C1-C30)alkyl; mono- or di-(3- to 30-membered)heteroarylamino; (C1-C30)alkyl(C2-C30)alkenylamino; (C1-C30)alkyl(C6-C30)arylamino; (C1-C30)alkyl(3- to 30-membered)heteroarylamino; (C2-C30)alkenyl(C6-C30)arylamino; (C2-C30)alkenyl(3- to 30-membered)heteroarylamino; (C6-C30)aryl(3- to 30-membered)heteroarylamino; (C1-C30)alkylcarbonyl; (C1-C30)alkoxycarbonyl; (C6-C30)arylcarbonyl; di(C6-C30)arylboronyl; di(C1-C30)alkylboronyl; (C1-C30)alkyl(C6-C30)arylboronyl; (C6-C30)ar(C1-C30)alkyl; and (C1-C30)alkyl(C6-C30)aryl. For example, the substituted alkyl, etc., each independently may be substituted with least one selected from the group consisting of (C1-C25)alkyl; (C3-C25)cycloalkyl; (C6-C25)aryl unsubstituted or substituted with at least one of (C1-C30)alkyl, (C6-C30)aryl, and (3- to 30-membered)heteroaryl; (3- to 25-membered)heteroaryl unsubstituted or substituted with at least one (C6-C30)aryl; and mono- or di-(C6-C25)arylamino unsubstituted or substituted with (C6-C30)aryl. For example, the substituted alkyl, etc., may be substituted with methyl, phenyl, phenyl substituted with cyano, biphenyl, terphenyl, naphthyl, naphthyl substituted with phenyl, naphthyl substituted with naphthyl, naphthyl substituted with dibenzofuranyl, phenanthrenyl, triphenylene, cyano, benzofluorenyl, benzofluorenyl substituted with methyl, benzofluorenyl substituted with phenyl, carbazolyl, carbazolyl substituted with phenyl, dibenzofuranyl, dibenzothiophenyl, diphenylamino, phenylbiphenylamino, etc.

When a substituent is not shown in the chemical formula or the compound structure of the present disclosure, it may signify that all positions that may be present as substituents are hydrogen or deuterium. That is, in the case of deuterium, an isotope of hydrogen, some of the hydrogen atoms may be deuterium, which is an isotope; and in this case, the content of deuterium may be 0% to 100%. In the case where a substituent is not shown in the chemical formula or the compound structure of the present disclosure, when deuterium is not explicitly excluded, hydrogen and deuterium may be mixed and used in the compound, such as when the content of deuterium is 0%, the content of hydrogen is 100%, and all substituents are hydrogen. The deuterium is an element having a deuteron composed of one proton and one neutron as an atomic nucleus, which is one of the isotopes of hydrogen, and may be represented by hydrogen-2, and the element symbol may be D or ²H. The isotope having the same atomic number (Z) and a different mass number (A) may also be interpreted as an element having the same number of protons and the different number of neutron.

Herein, “combinations thereof” signifies that one or more components of the corresponding list are combined to form a known or chemically stable arrangement that a person skilled in the art could conceive of from the corresponding list. For example, alkyl and deuterium may be combined to form partially or entirely deuterated alkyl groups; halogen and alkyl may be combined to form halogenated alkyl substituents; and halogen, alkyl, and aryl may be combined to form halogenated arylalkyl. For example, preferred combinations of substituents may include up to 50 atoms excluding hydrogen and deuterium, or include up to 40 atoms excluding hydrogen and deuterium, or include up to 30 atoms excluding hydrogen and deuterium, or in many cases, preferred combinations of substituents may include up to 20 atoms excluding hydrogen and deuterium.

In the formulas of the present disclosure, when multiple substituents are indicated by the same symbol, each of these substituents represented by the same symbol may be the identical or different from one another.

Hereinafter, the organic electroluminescent device according to one embodiment will be described in detail.

The organic electroluminescent device according to the present disclosure comprises a first electrode; a hole transport zone disposed on the first electrode; at least one light-emitting layer disposed on the hole transport zone; an electron transport zone disposed on the light-emitting layer; and a second electrode disposed on the electron transport zone.

In more detail, the organic electroluminescent device according to the present disclosure comprises a first electrode; a second electrode; and a hole transport zone, at least one light-emitting layer, and an electron transport zone positioned between the first electrode and the second electrode, wherein the light-emitting layer comprises at least one deuterated compound and at least four different compounds, and at least one zone of the hole transport zone and the electron transport zone comprises at least one deuterated compound.

According to one embodiment, a hole transport zone is positioned on a first electrode, and is configured by sequentially stacking a hole injection layer, at least one hole transport layer, and at least one layer of a hole auxiliary layer and an electron blocking layer, wherein at least one layer of the hole injection layer, the hole transport layer, the hole auxiliary layer, and the electron blocking layer comprises a deuterated compound.

In one embodiment, the hole transport zone may comprise a compound represented by the following Formula 1.

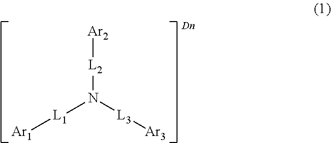

In Formula 1,
L₁ to L₃ each independently represent a single bond, a substituted or unsubstituted (C6-C30)arylene, or a substituted or unsubstituted (3- to 30-membered)heteroarylene;
Ar₁ to Ar₃ each independently represent hydrogen, deuterium, a halogen, a cyano, a substituted or unsubstituted (C1-C30)alkyl, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted (C6-C30)aryl, a substituted or unsubstituted (3- to 30-membered)heteroaryl, a substituted or unsubstituted mono- or di-(C6-C30)arylamino, a substituted or unsubstituted mono- or di-(C1-C30)alkylamino, a substituted or unsubstituted mono- or di-(C2-C30)alkenylamino, a substituted or unsubstituted (C1-C30)alkyl(C6-C30)arylamino, a substituted or unsubstituted mono- or di-(3- to 30-membered)heteroarylamino, or a substituted or unsubstituted (C6-C30)aryl(3- to 30-membered)heteroarylamino;
provided that at least one of Ar₁ to Ar₃ comprises deuterium and is a substituted or unsubstituted (C6-C30)aryl or a substituted or unsubstituted (3- to 30-membered)heteroaryl; and
Dₙ means that n number of hydrogens is replaced with deuterium, wherein n is an integer of 1 or more, and the upper limit of n is determined according to the number of hydrogens in the non-deuterated compound.

In one embodiment, L₁ to L₃ each independently may be a single bond, a substituted or unsubstituted (C6-C25)arylene, or a substituted or unsubstituted (5- to 25-membered)heteroarylene, preferably, a single bond, a substituted or unsubstituted (C6-C18)arylene, or a substituted or unsubstituted (5- to 18-membered)heteroarylene. For example, L₁ to L₃ each independently may be a single bond, a substituted or unsubstituted phenylene, a substituted or unsubstituted biphenylene, a substituted or unsubstituted carbazolylene, a substituted or unsubstituted dibenzothiophenylene, or a substituted or unsubstituted dibenzofuranylene. Wherein, the substituent may be further substituted with deuterium.

In one embodiment, Ar₁ to Ar₃ each independently may be hydrogen, deuterium, a substituted or unsubstituted (C6-C30)aryl, or a substituted or unsubstituted (5- to 30-membered)heteroaryl, a substituted or unsubstituted mono- or di-(C6-C30)arylamino, or a substituted or unsubstituted (C6-C30)aryl(5- to 30-membered)heteroarylamino, preferably hydrogen, deuterium, a substituted or unsubstituted (C6-C25)aryl, a substituted or unsubstituted (5- to 25-membered)heteroaryl, a substituted or unsubstituted di(C6-C25)arylamino, a substituted or unsubstituted (C6-C25)aryl(5- to 25-membered)heteroarylamino, more preferably at least one of Ar₁ to Ar₃ comprises deuterium and may be a substituted or unsubstituted (C6-C30)aryl or a substituted or unsubstituted (5- to 30-membered)heteroaryl.

In one embodiment, at least one of Ar₁ to Ar₃ may be (C6-C30)aryl substituted with deuterium or (5- to 30-membered)heteroaryl substituted with deuterium.

In one embodiment, at least one of Ar₁ to Ar₃ may be a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl.

For example, Ar₁ to Ar₃ each independently may be a substituted or unsubstituted fluorenyl, a substituted or unsubstituted benzofluorenyl, a substituted or unsubstituted spirobifluorenyl, a substituted or unsubstituted phenyl, a substituted or unsubstituted o-biphenyl, a substituted or unsubstituted m-biphenyl, a substituted or unsubstituted p-biphenyl, a substituted or unsubstituted o-terphenyl, a substituted or unsubstituted m-terphenyl, a substituted or unsubstituted phenanthrenyl, a substituted or unsubstituted carbazolyl, a substituted or unsubstituted dibenzothiophenyl, a substituted or unsubstituted dibenzofuranyl, a substituted or unsubstituted diphenylamino, a substituted or unsubstituted phenylbiphenylamino, or phenyldibenzofuranylamino, or a substituted or unsubstituted phenyldibenzothiophenylamino. Wherein, the substituent may be substituted with at least one selected from deuterium, methyl, phenyl, biphenyl, phenanthrenyl, benzofluorenyl substituted with methyl, benzofluorenyl substituted with phenyl, carbazolyl, carbazolyl substituted with phenyl, dibenzofuranyl, diphenylamino, and phenylbiphenylamino.

In one embodiment, the deuterium substitution rate in Formula 1 is preferably 20% to 100%, more preferably 20% to 95%, even more preferably 30% to 95%, and even more preferably 40% to 95% of the total number of hydrogens.

According to one embodiment, the deuterium compound represented by Formula 1 can be more specifically exemplified by the compounds below, but is not limited thereto.

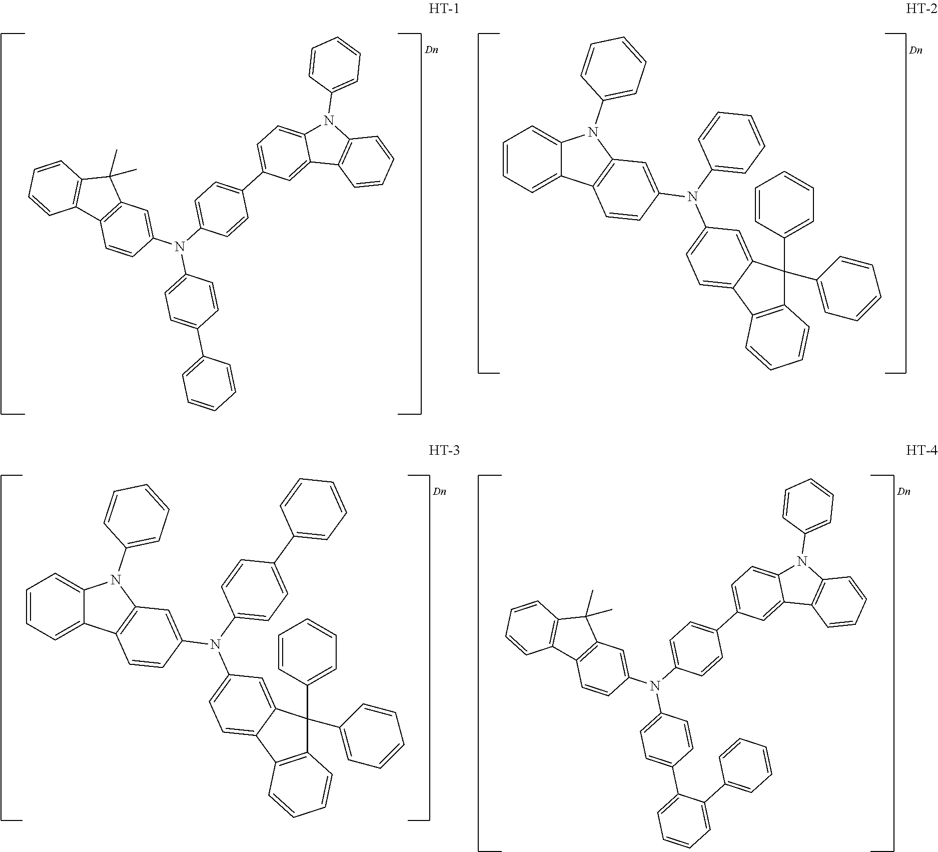

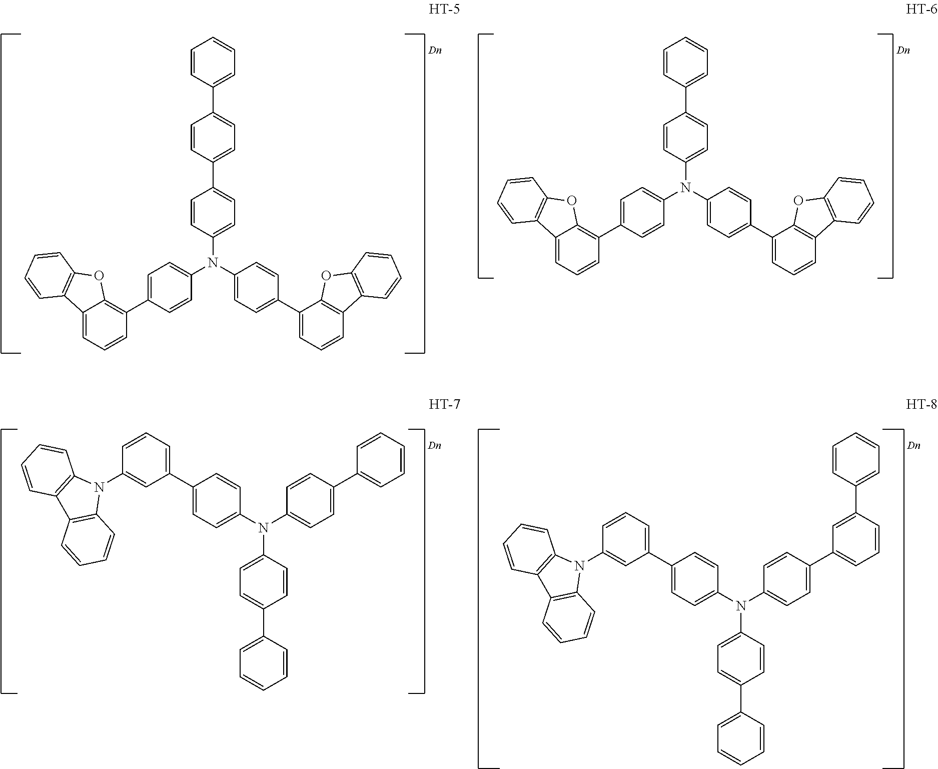

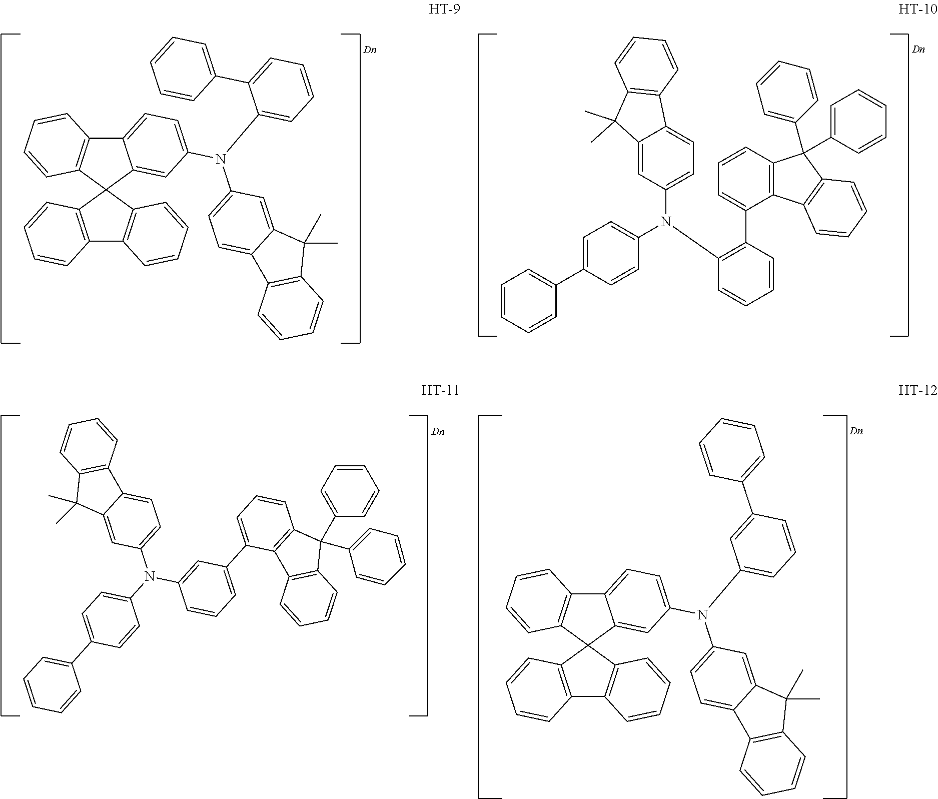

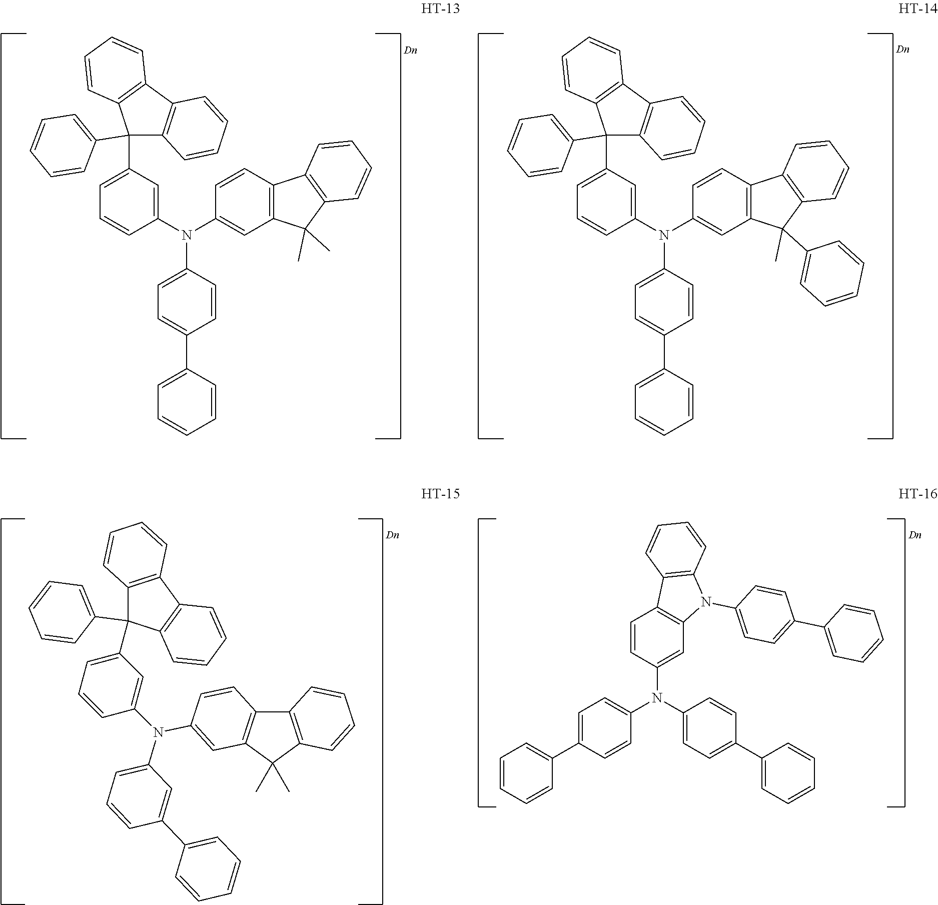

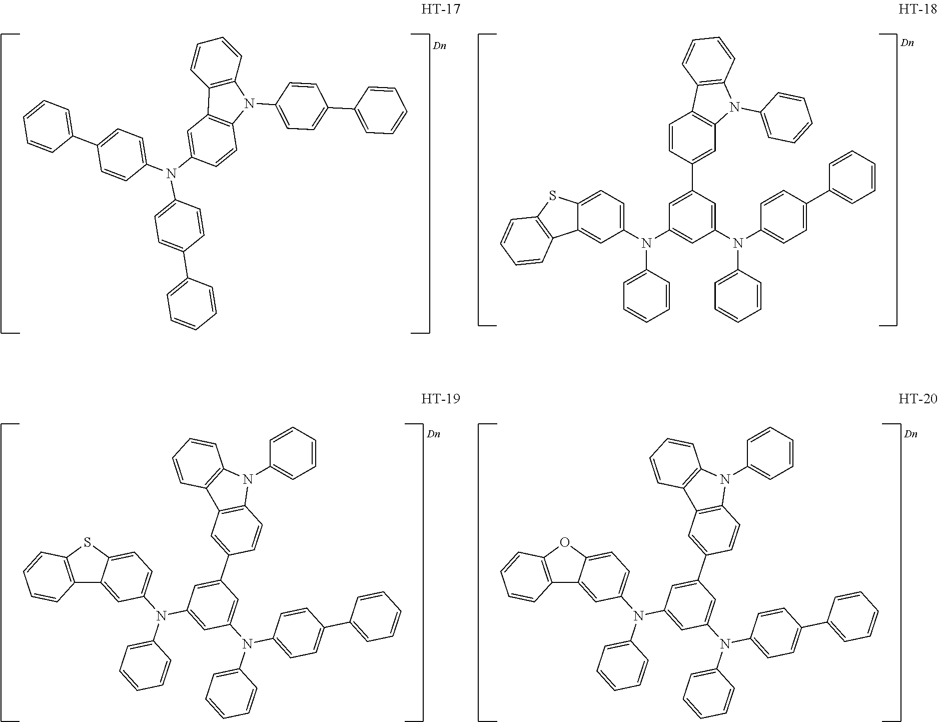

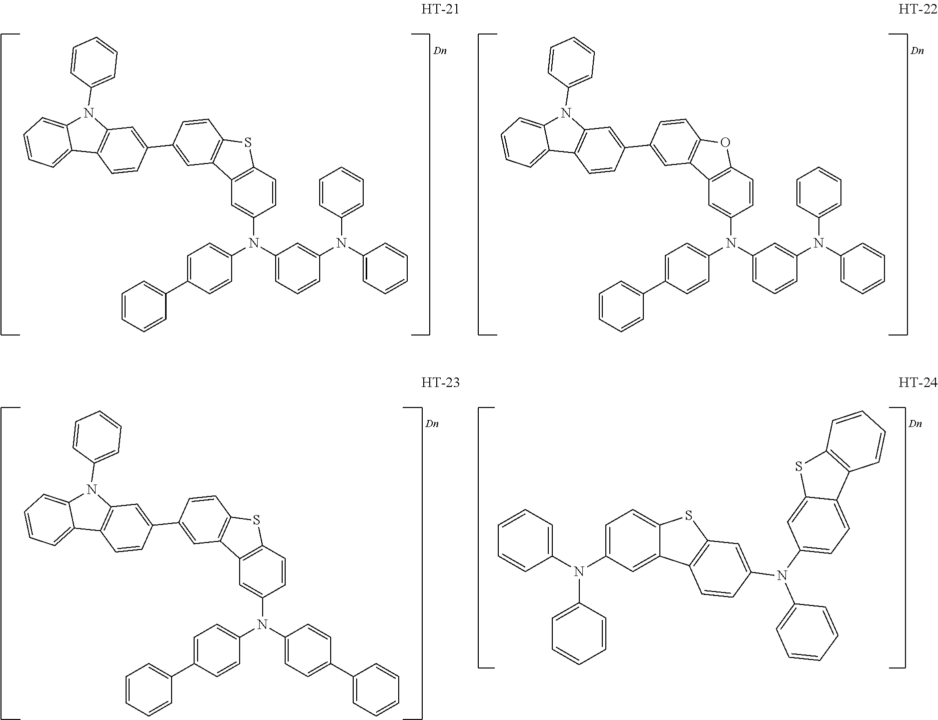

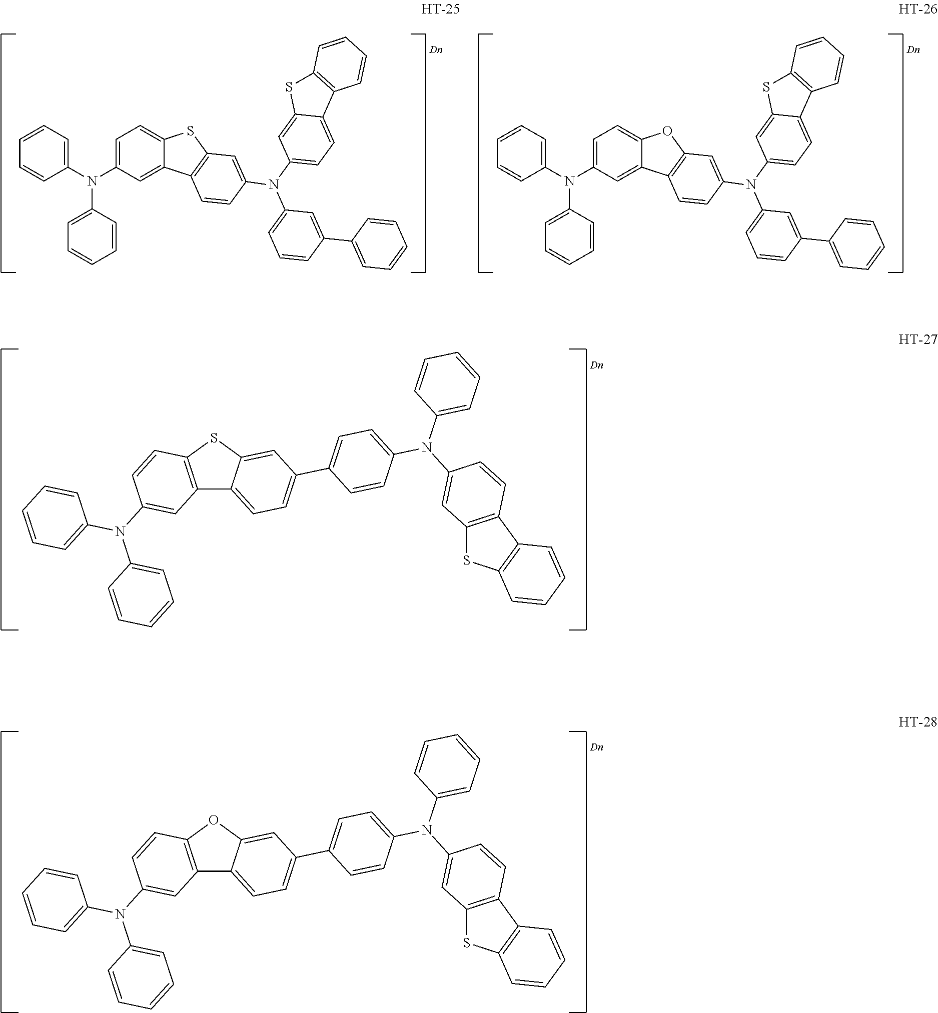

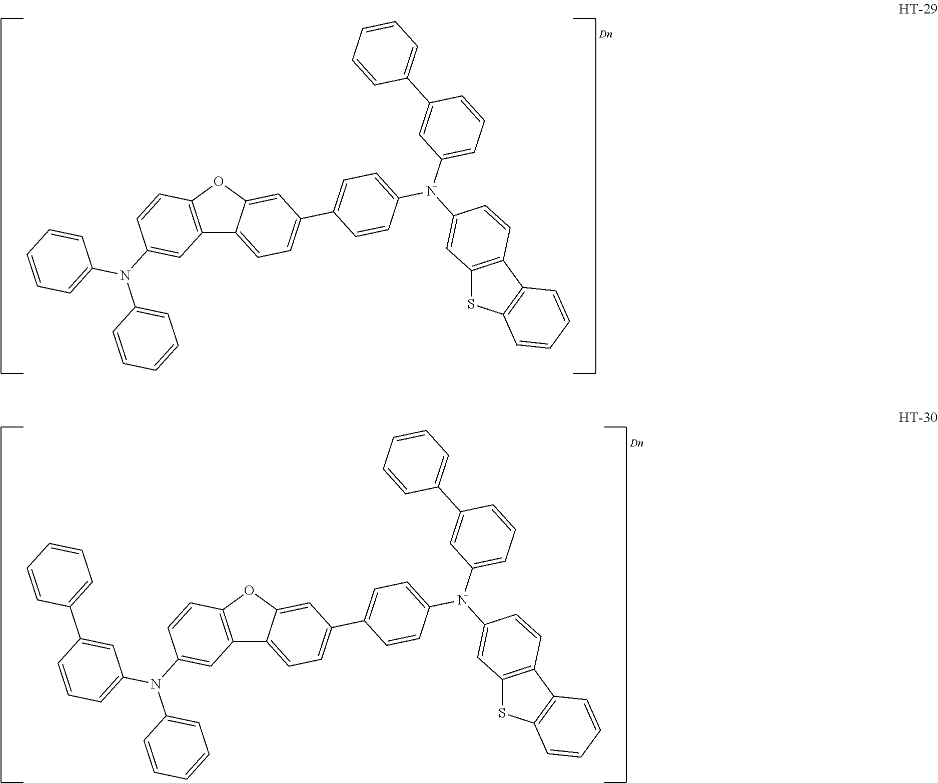

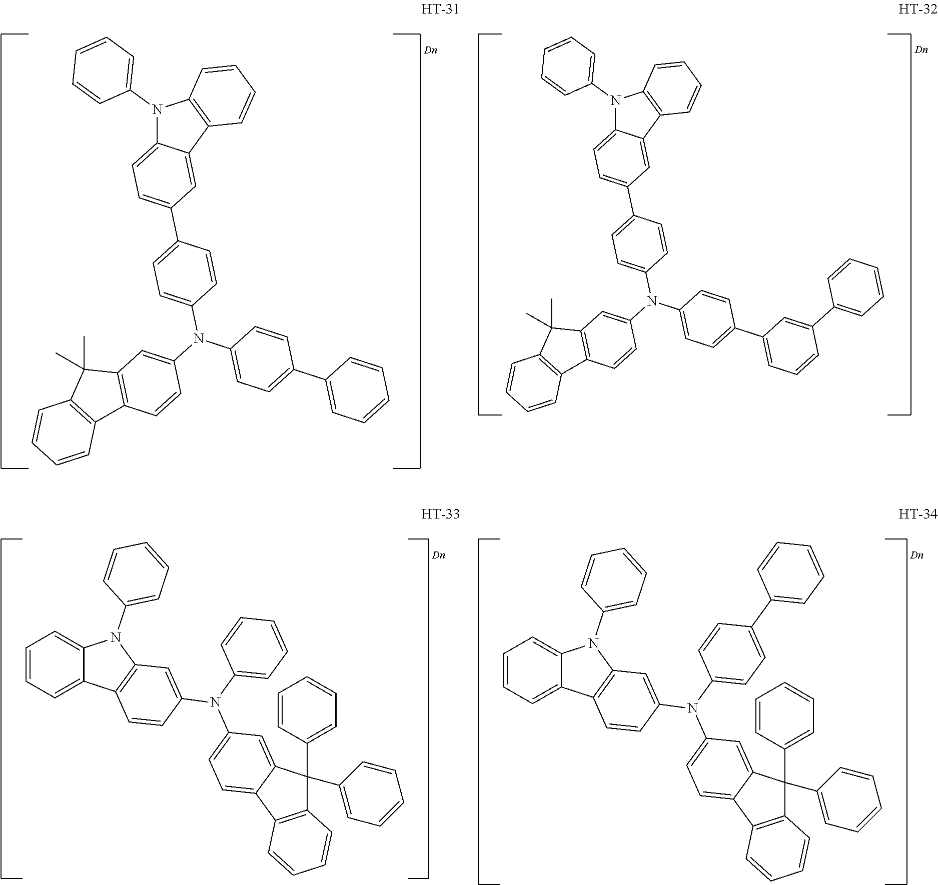

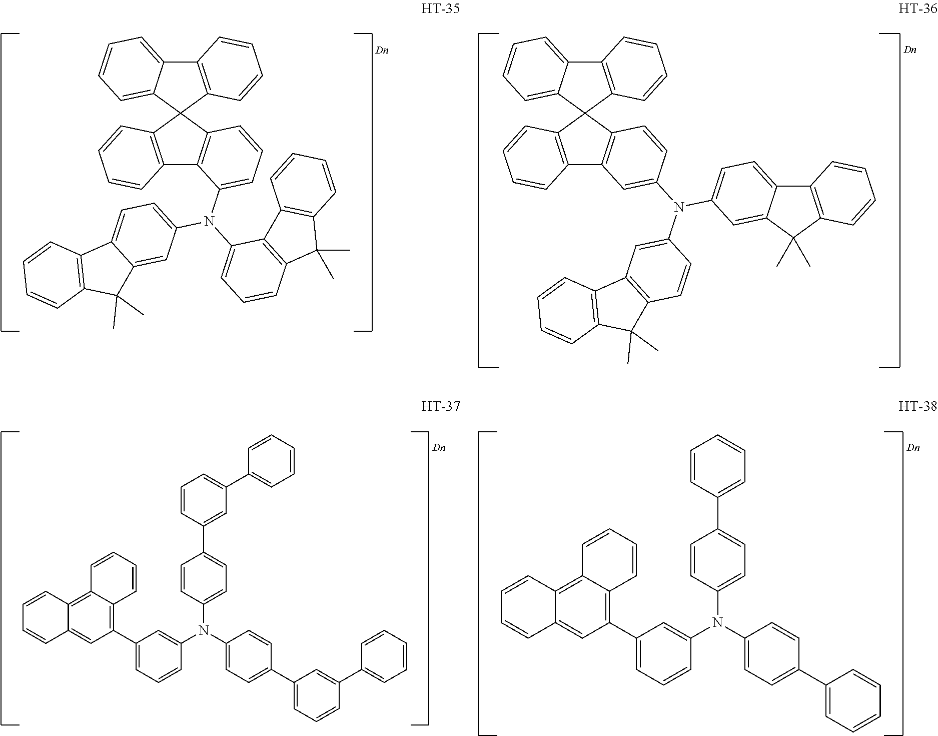

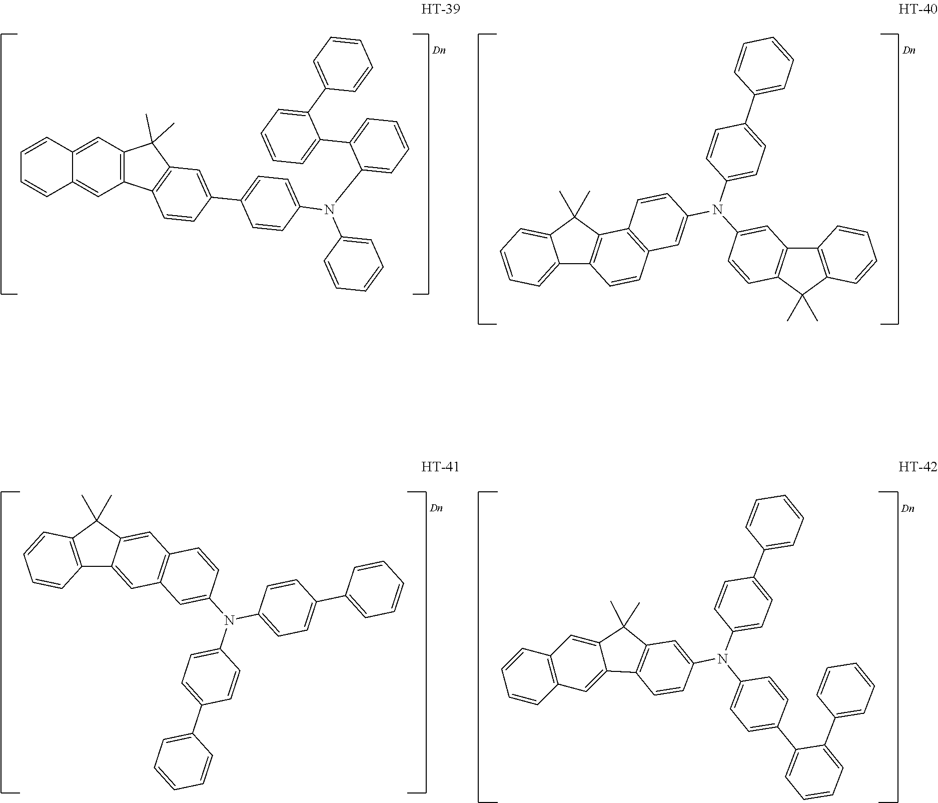

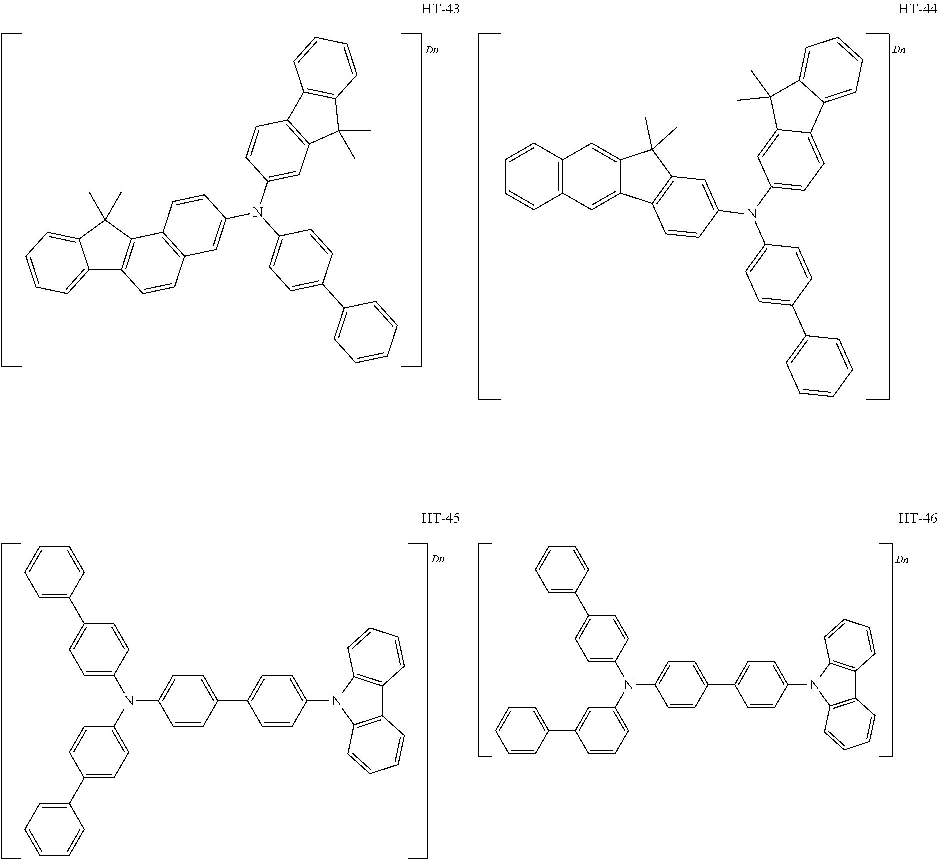

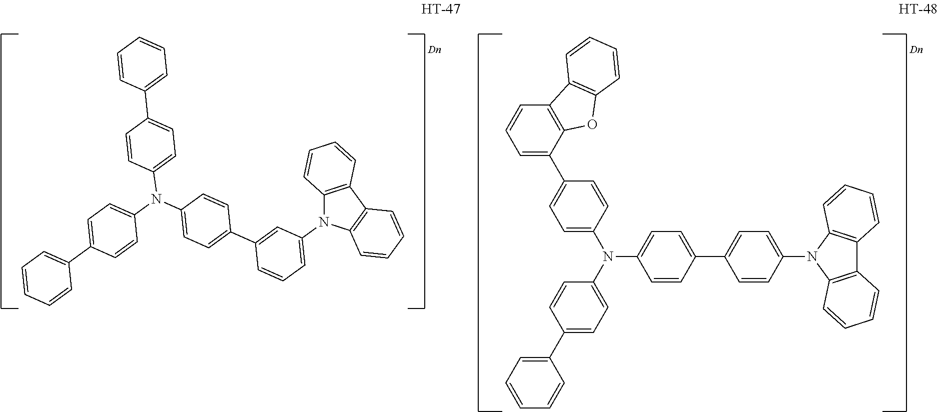

wherein Dₙ means that n number of hydrogens is replaced with deuterium, wherein n is an integer of 1 or more, and the upper limit of n is determined according to the number of hydrogens in the non-deuterated compound.

According to one embodiment, the light-emitting layer is disposed on the hole transport zone, comprises at least one deuterated compound, and comprises at least three different host compounds and one dopant compound.

According to another embodiment, the light-emitting layer may comprises at least one deuterated compound, and may comprises at least two different host compounds and at least two different dopant compounds.

In one embodiment, the at least one light-emitting layer may comprises a compound represented by the following Formula 4 or 5.

The compound represented by Formula 4 included in the light-emitting layer according to one embodiment is as follows.

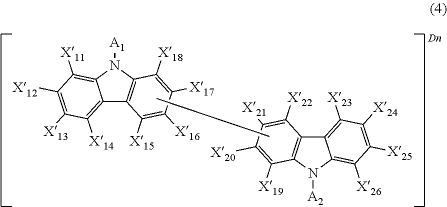

In Formula 4,
A₁ and A₂ each independently represent a substituted or unsubstituted (C6-C30)aryl, a substituted or unsubstituted dibenzofuranyl, a substituted or unsubstituted dibenzothiophenyl, or a substituted or unsubstituted carbazolyl;
any one of X′₁₅ to X′₁₈ and any one of X′₁₉ to X′₂₂ are linked to each other to form a single bond;
X′₁₁ to X′₁₄, X′₂₃ to X′₂₆, and X′₁₅ to X′₂₂ which do not form a single bond, each independently represent hydrogen, deuterium, a substituted or unsubstituted (C6-C30)aryl, or a substituted or unsubstituted (3- to 30-membered)heteroaryl; or may be linked to the adjacent substituents to form a ring(s);
at least one of X′₁₁, X′₁₈, X′₁₉ and X′₂₆ is deuterium; and
Dₙ means that n number of hydrogens is replaced with deuterium, wherein n is an integer of 1 or more, and the upper limit of n is determined according to the number of hydrogens in the non-deuterated compound.

In one embodiment, A₁ and A₂ each independently may be a substituted or unsubstituted (C6-C30)aryl or a substituted or unsubstituted dibenzofuranyl, preferably a substituted or unsubstituted (C6-C18)aryl or a substituted or unsubstituted dibenzofuranyl. For example, A₁ and A₂ each independently may be a substituted or unsubstituted phenyl, a substituted or unsubstituted p-biphenyl, a substituted or unsubstituted m-biphenyl, a substituted or unsubstituted naphthyl, a substituted or unsubstituted m-terphenyl, a substituted or unsubstituted p-terphenyl, a substituted or unsubstituted triphenylenyl, or a substituted or unsubstituted dibenzofuranyl. Wherein, the substituents may be substituted with at least one selected from deuterium, phenyl, naphthyl, triphenylenyl, and dibenzofuranyl.

In one embodiment, X′₁₁ to X′₁₄, X′₂₃ to X′₂₆, and X′₁₅ to X′₂₂ which do not form a single bond, each independently may be hydrogen or deuterium, preferably at least one of X′₁₁, X′₁₈, X′₁₉ and X′₂₆ is deuterium.

In one embodiment, the deuterium substitution rate in Formula 4 is preferably 20% to 100%, more preferably 20% to 95%, even more preferably 30% to 95%, and even more preferably 40% to 95% of the total number of hydrogens.

According to one embodiment, the compound represented by Formula 5 included in the light-emitting layer is as follows.

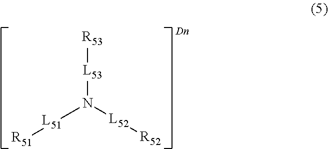

In Formula 5,
L₅₁ to L₅₃ each independently represent a single bond, a substituted or unsubstituted (C6-C30)arylene, to a substituted or unsubstituted (3- to 30-membered)heteroarylene;
R₅₁ to R₅₃ each independently represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted a fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino; or may be linked to the adjacent substituents to form a ring(s);
provided that at least one of R₅₁ to R₅₃ in Formula 5 comprises the following Formula 5-1 or 5-2;

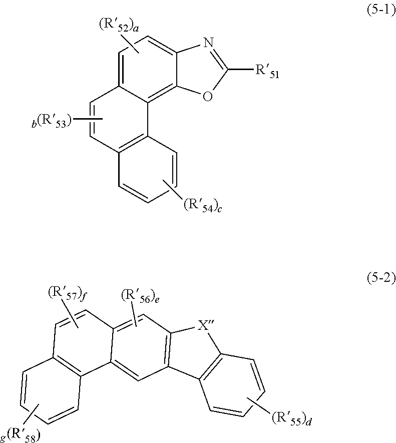

or, when L₅₁ and L₅₂ are a single bond, while R₅, and R₅₂ are linked to each other to form a ring(s), the Formula 5 is represented by any one of the following Formulas 5-3 to 5-5;

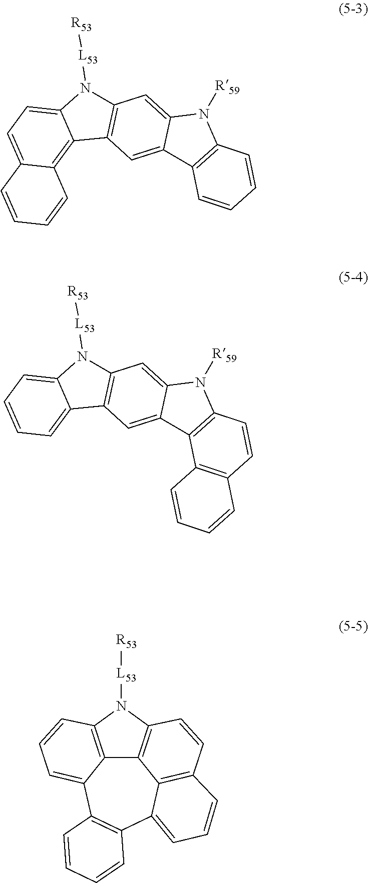

In Formulas 5-1 to 5-5,
R′₅₁ to R′₅₉ are the same as the definition of R₅₁ to R₅₃;
X″ represents —O— or —S—;
a, b, e, and f each independently represent 1 or 2, c, d, and g represent an integer of 1 to 4, when a to g are an integer of 2 or more, each of R′₅₁ to each of R′₅₉ may be the same as or different from each other; and
Dₙ means that n number of hydrogens is replaced with deuterium, wherein n is an integer of 1 or more, and the upper limit of n is determined according to the number of hydrogens in the non-deuterated compound.

In one embodiment, L₅₁ to L₅₃ each independently may be a single bond, a substituted or unsubstituted (C6-C30)arylene, preferably a single bond or a substituted or unsubstituted (C6-C25)arylene, more preferably a single bond or a substituted or unsubstituted (C6-C18)arylene. For example, L₅₁ to L₅₃ each independently may be a single bond, a substituted or unsubstituted phenylene, or a substituted or unsubstituted biphenylene, which may be further substituted with at least one deuterium.

According to one embodiment, at least one of R₅₁ to R₅₃ in Formula 5 comprises the Formula 5-1 or 5-2.

In one embodiment, R₅₁ to R₅₃, which do not comprise the Formula 5-1 or 5-2, each independently may be a substituted or unsubstituted (C6-C30)aryl, a substituted or unsubstituted (5- to 30-membered)heteroaryl, or a substituted or unsubstituted mono- or di-(C6-C30)arylamino, preferably a substituted or unsubstituted (C6-C25)aryl, a substituted or unsubstituted (5- to 25-membered)heteroaryl, or a substituted or unsubstituted di(C6-C25)arylamino, more preferably a substituted or unsubstituted (C6-C18)aryl, a substituted or unsubstituted (5- to 25-membered)heteroaryl, or a substituted or unsubstituted di(C6-C18)arylamino. For example, R₅₁ to R₅₃, which do not comprise the Formula 5-1 or 5-2 each independently may be a substituted or unsubstituted phenyl, a substituted or unsubstituted o-biphenyl, a substituted or unsubstituted m-biphenyl, a substituted or unsubstituted p-biphenyl, a substituted or unsubstituted o-terphenyl, a substituted or unsubstituted phenanthrenyl, a substituted or unsubstituted 23-membered heteroaryl, a substituted or unsubstituted dibenzothiophenyl, a substituted or unsubstituted dibenzofuranyl, a substituted or unsubstituted diphenylamino, a substituted or unsubstituted phenylbiphenylamino, a substituted or unsubstituted phenylnaphthylamino, or a substituted or unsubstituted dibiphenylamino. Wherein, the substituents can be further substituted with at least one deuterium.

In one embodiment, R′₅₁ may be a substituted or unsubstituted (C6-C30)aryl, for example, a substituted or unsubstituted phenyl.

In one embodiment, R′₅2 to R′₅₉ each independently may be hydrogen or deuterium.

In one embodiment, X″ may be —O—.

According to another embodiment, when L₅₁ and L₅₂ are a single bond, while R₅₁ and R₅₂ are linked to each other to form a ring(s), the Formula 5 is represented by any one of the Formulas 5-3 to 5-5.

In one embodiment, R′₅₉ in Formula 5-4 may be a substituted or unsubstituted (C6-C30)aryl or a substituted or unsubstituted (5- to 30-membered)heteroaryl, preferably a substituted or unsubstituted (C6-C25)aryl or a substituted or unsubstituted (5- to 25-membered) heteroaryl, for example, a substituted or unsubstituted phenyl or a substituted or unsubstituted dibenzofuranyl.

In one embodiment, the deuterium substitution rate in Formula 4 or 5 is preferably 20% to 100%, more preferably 20% to 95%, even more preferably 30% to 95%, and even more preferably 40% to 95% of the total number of hydrogens.

According to one embodiment, the deuterated compounds represented by Formula 4 or 5 can be more specifically exemplified by the compounds below, but are not limited thereto.

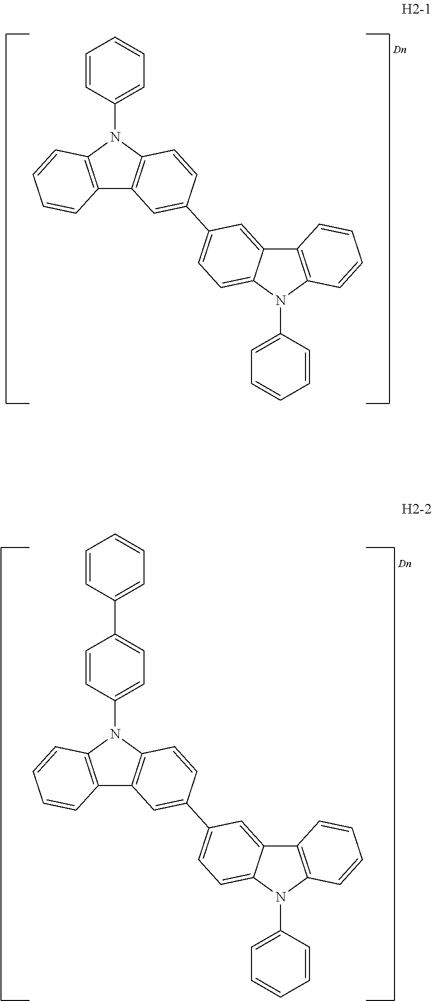

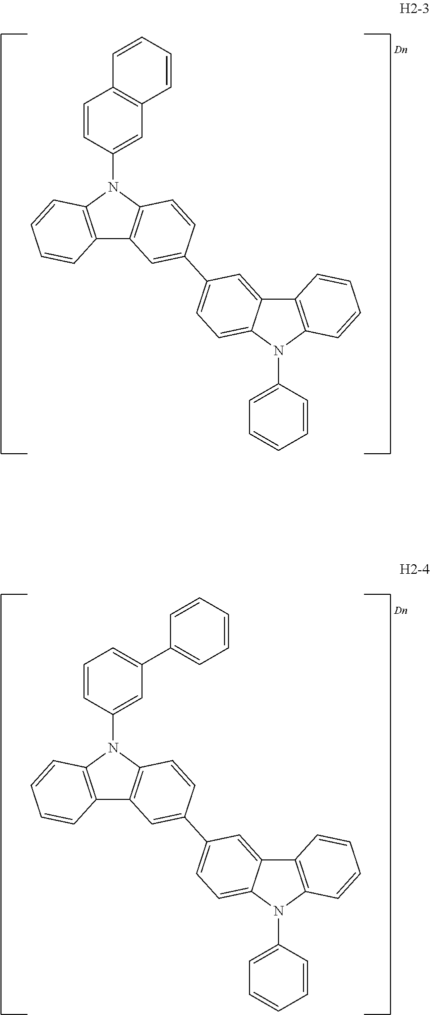

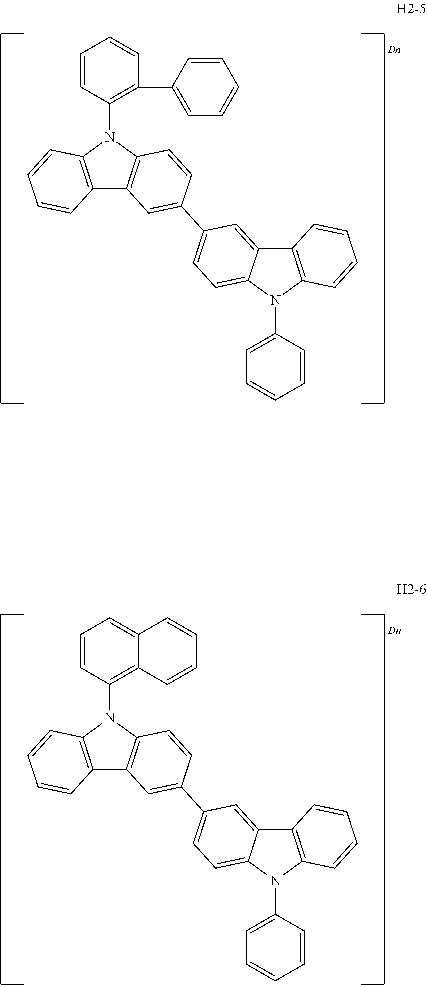

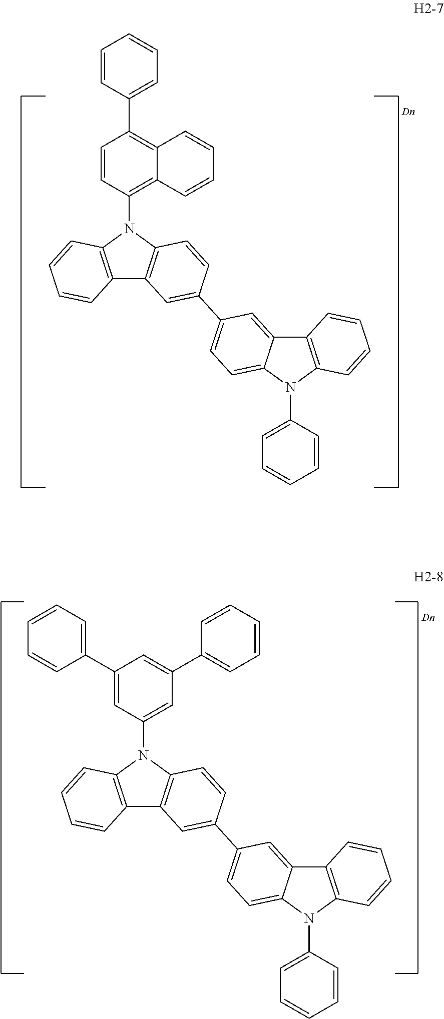

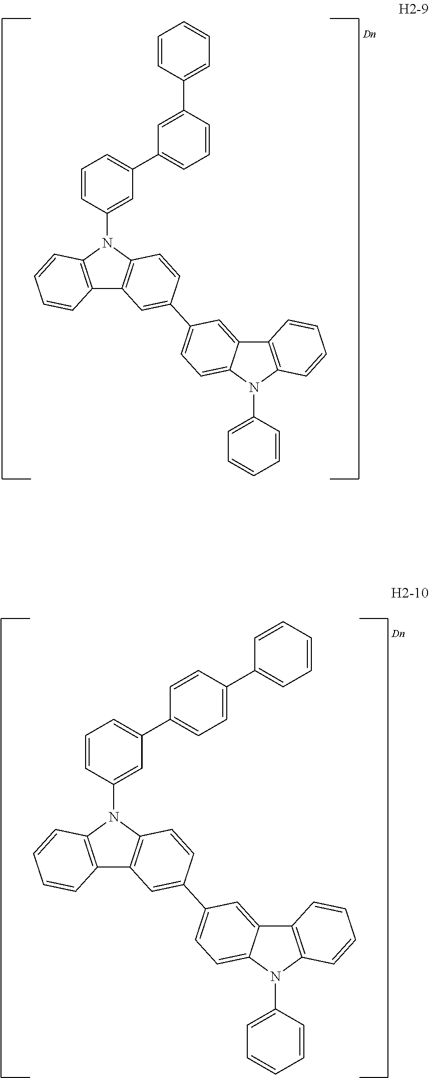

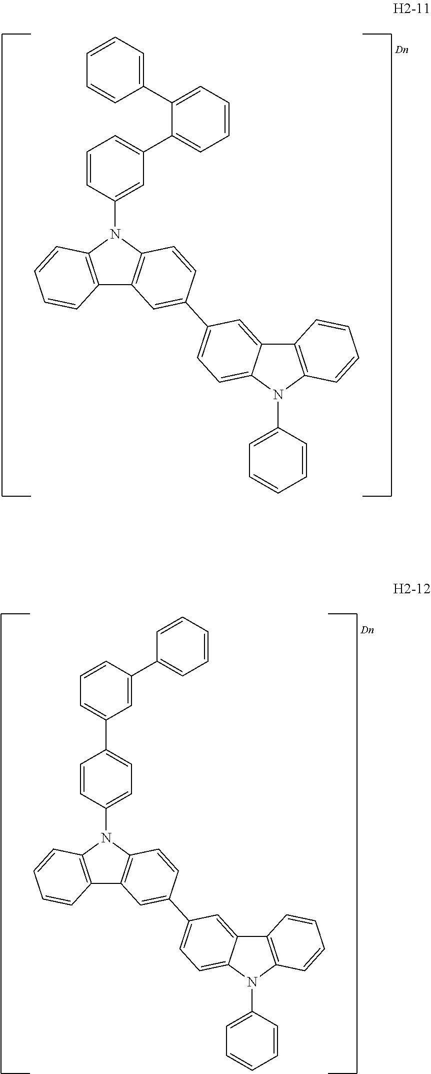

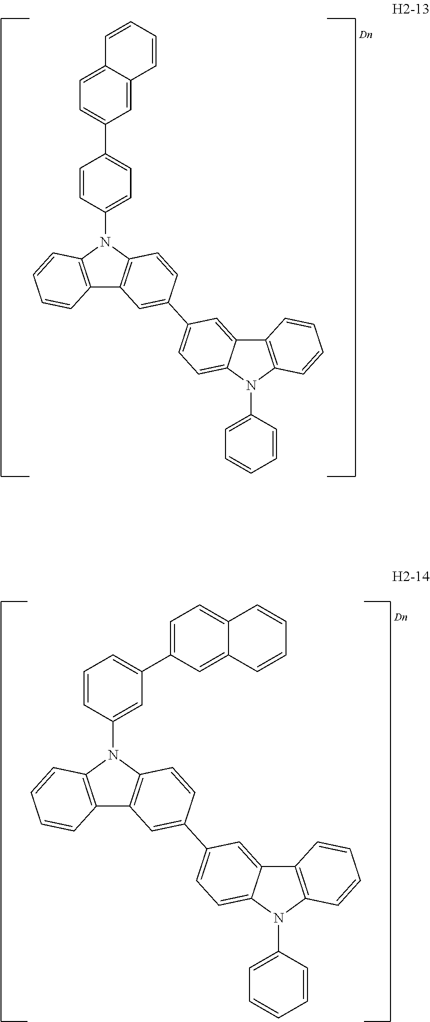

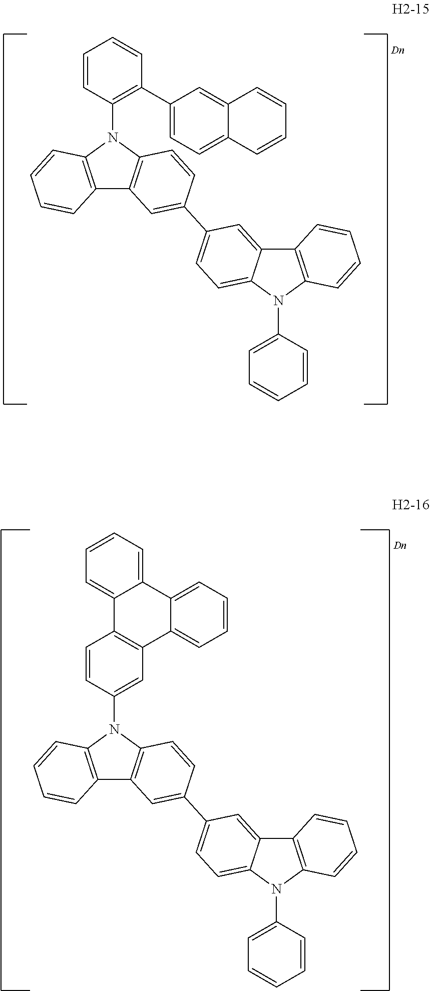

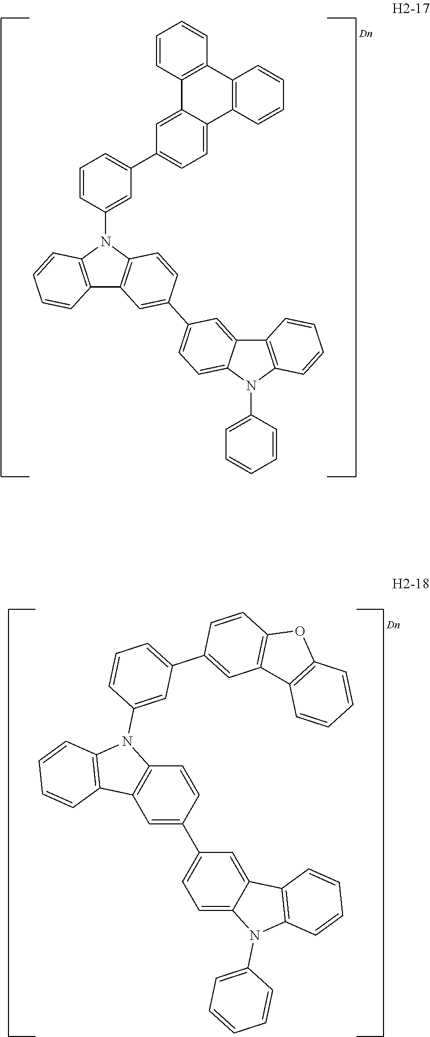

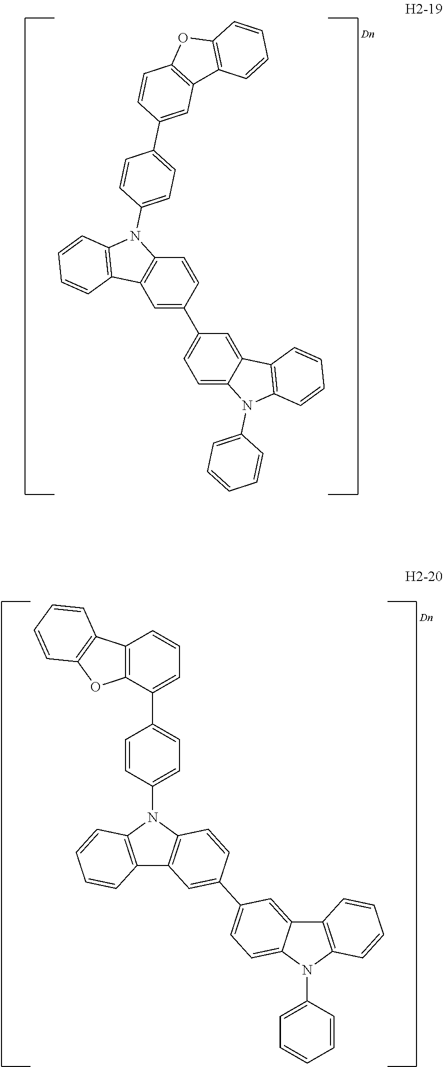

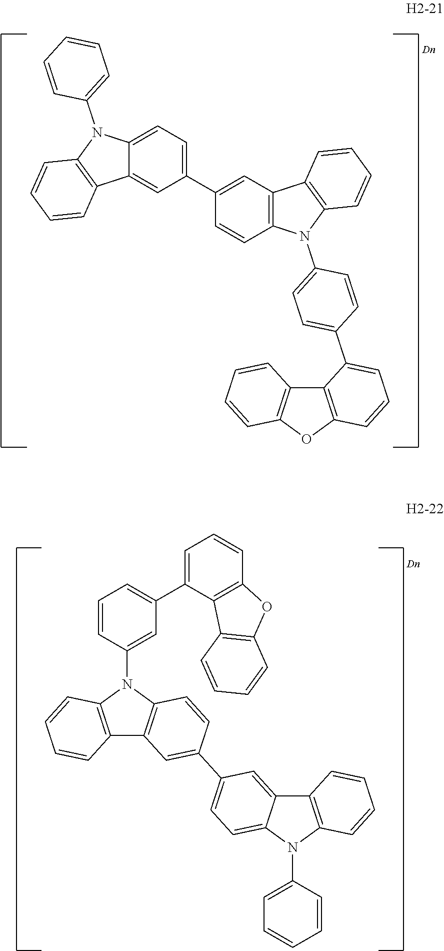

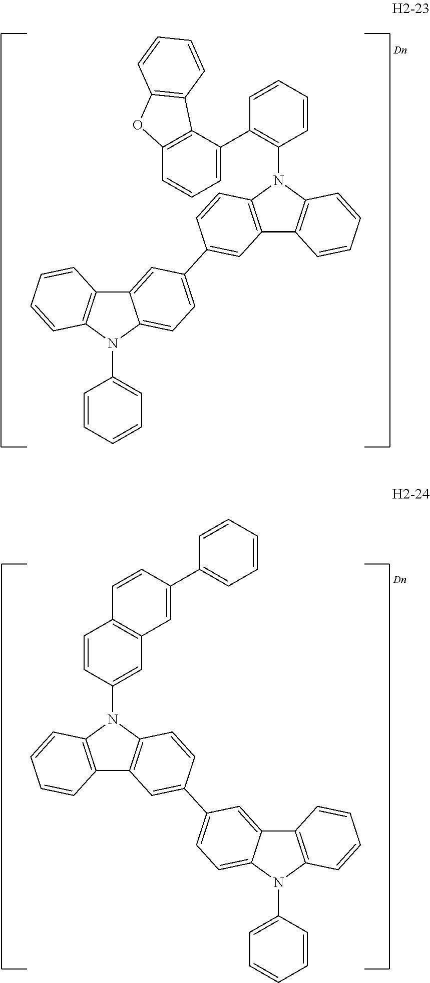

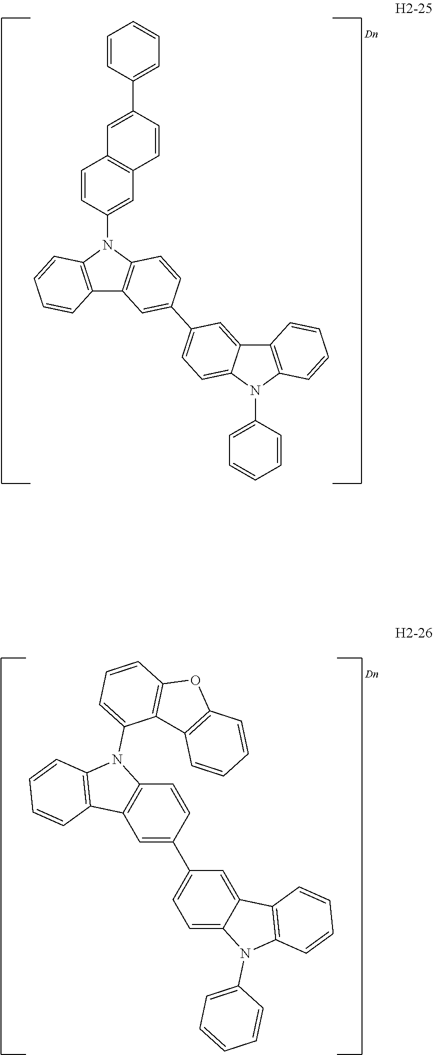

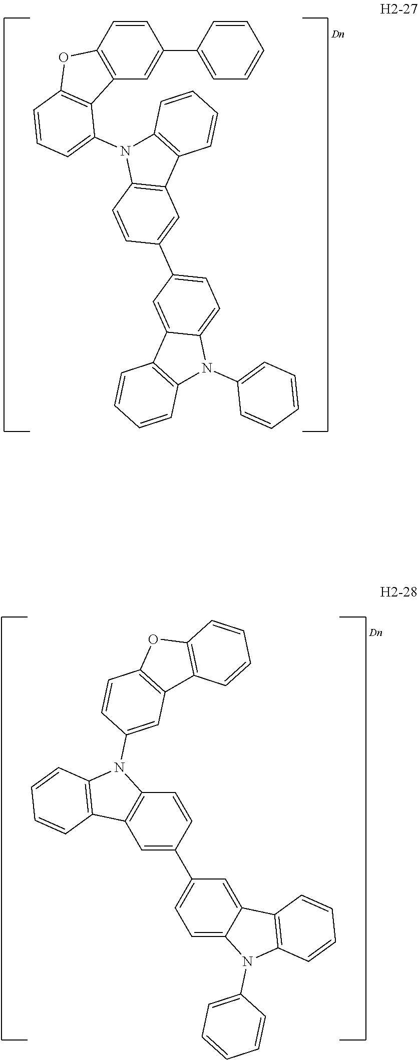

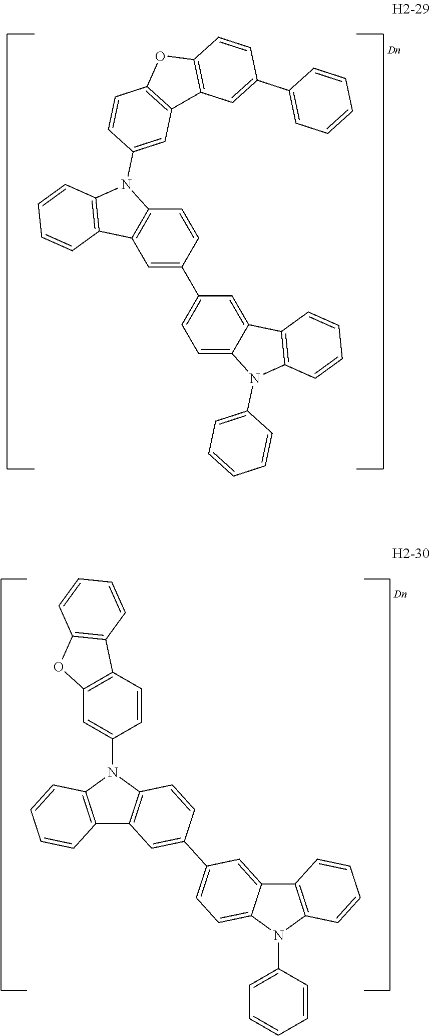

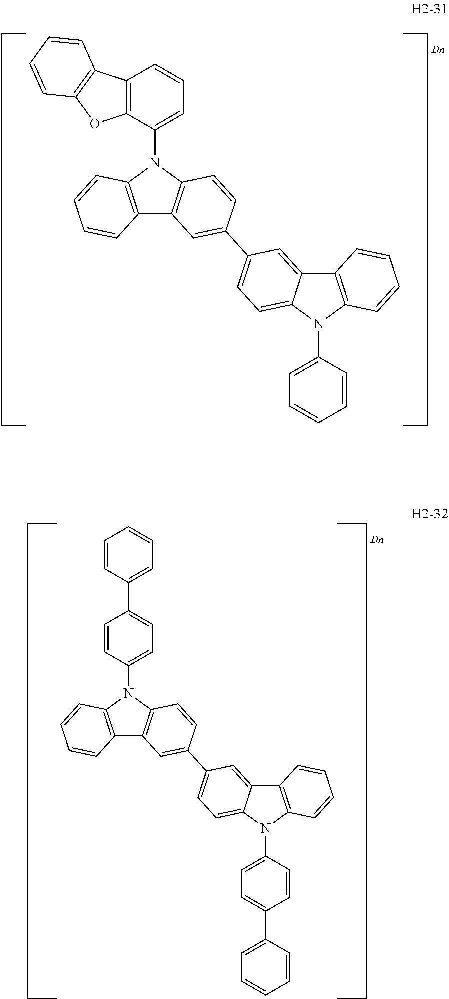

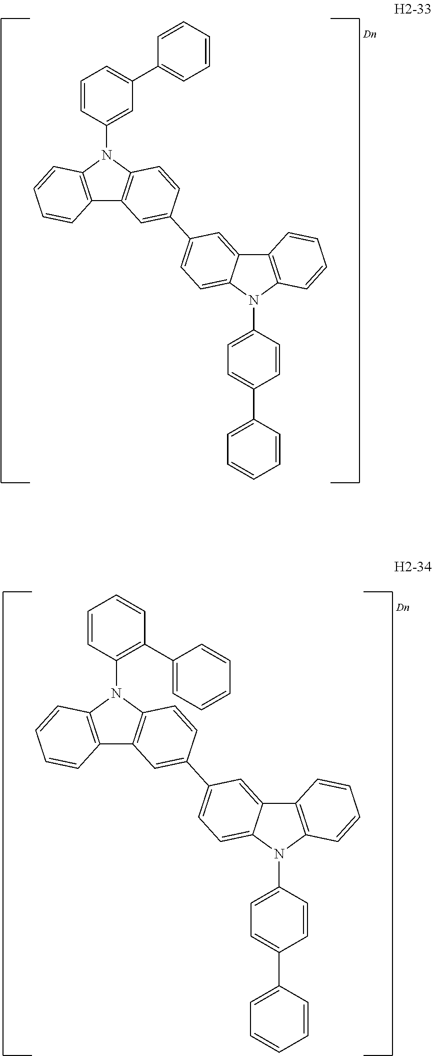

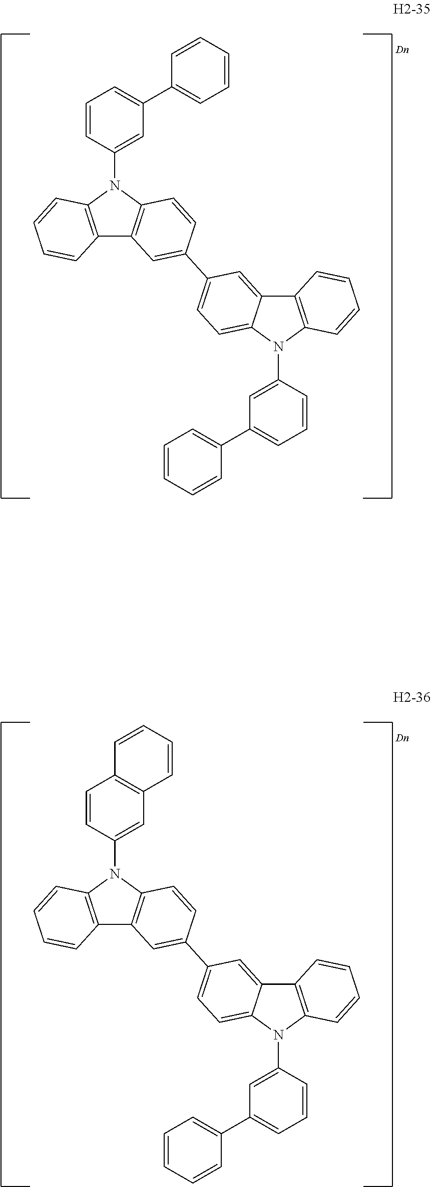

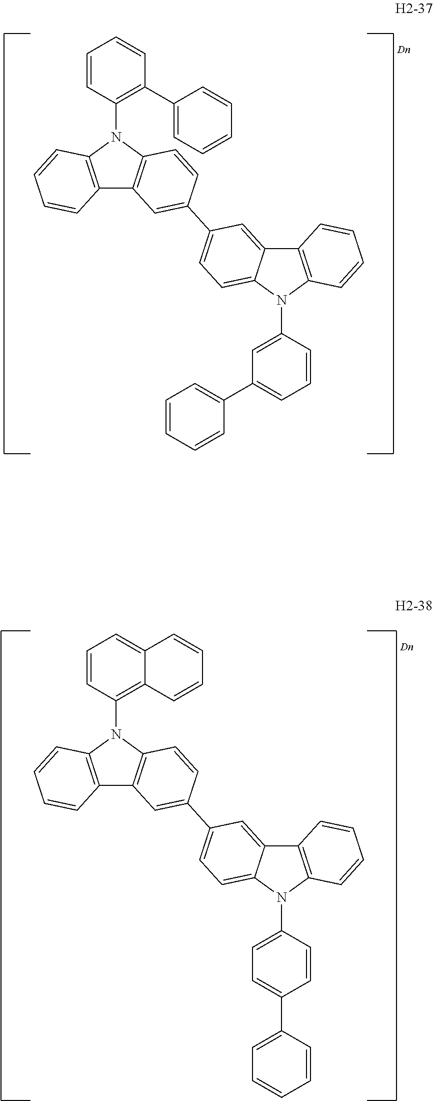

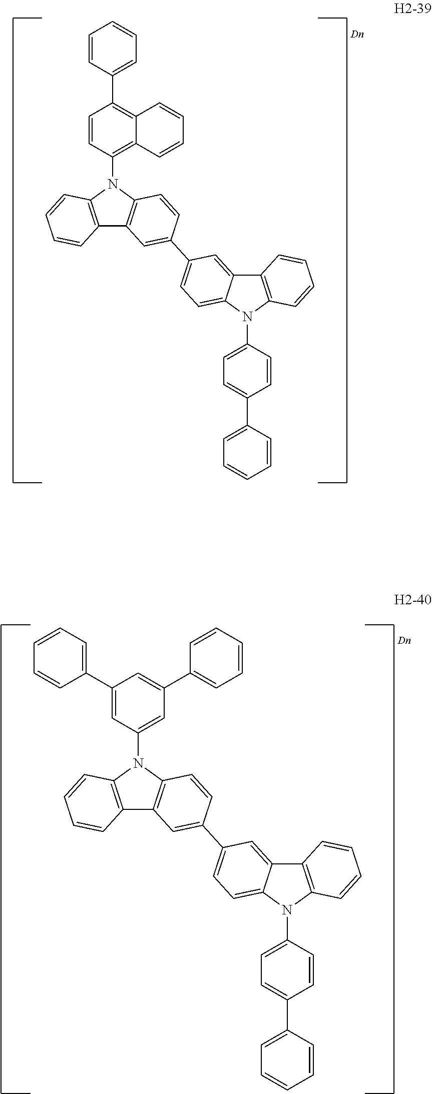

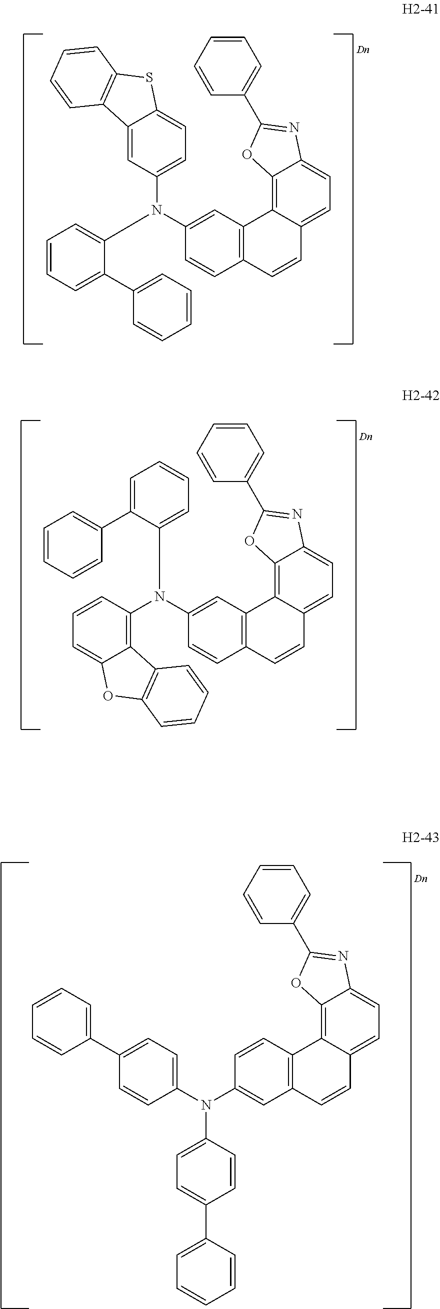

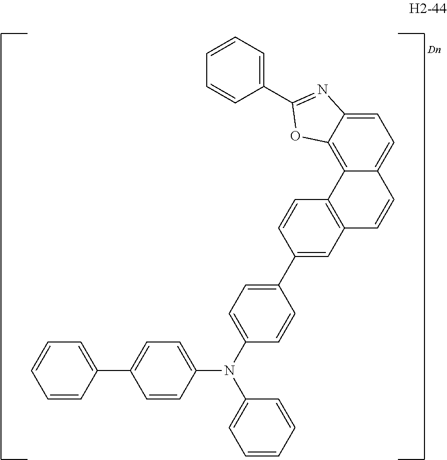

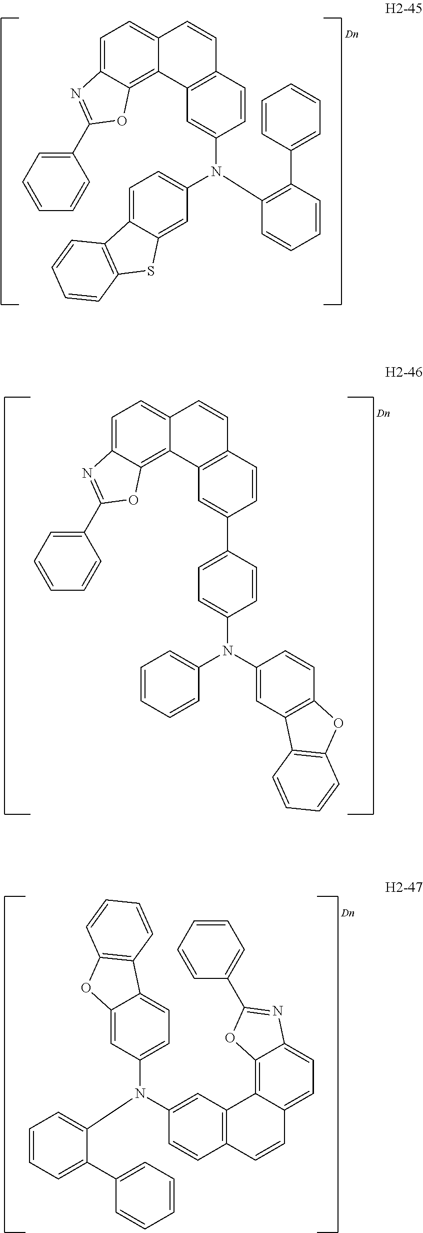

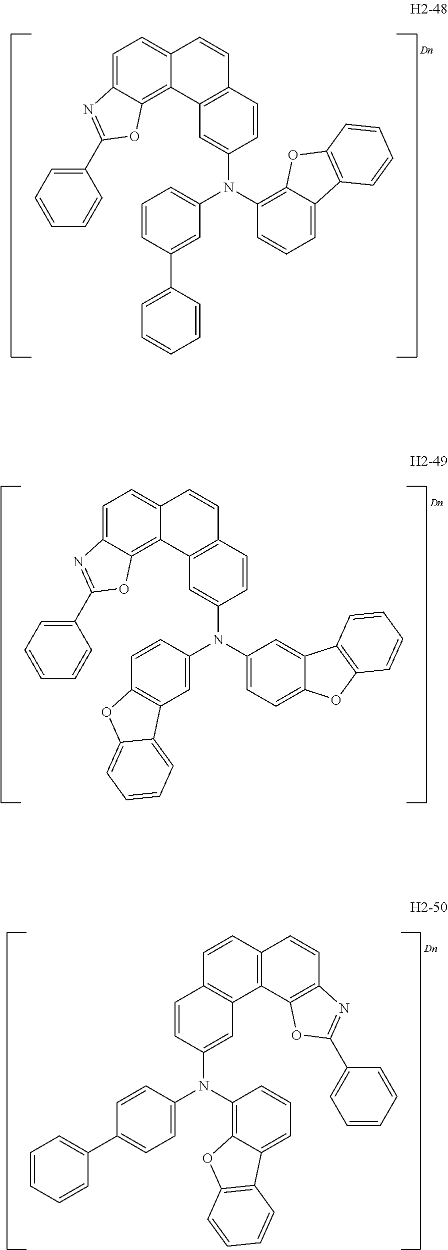

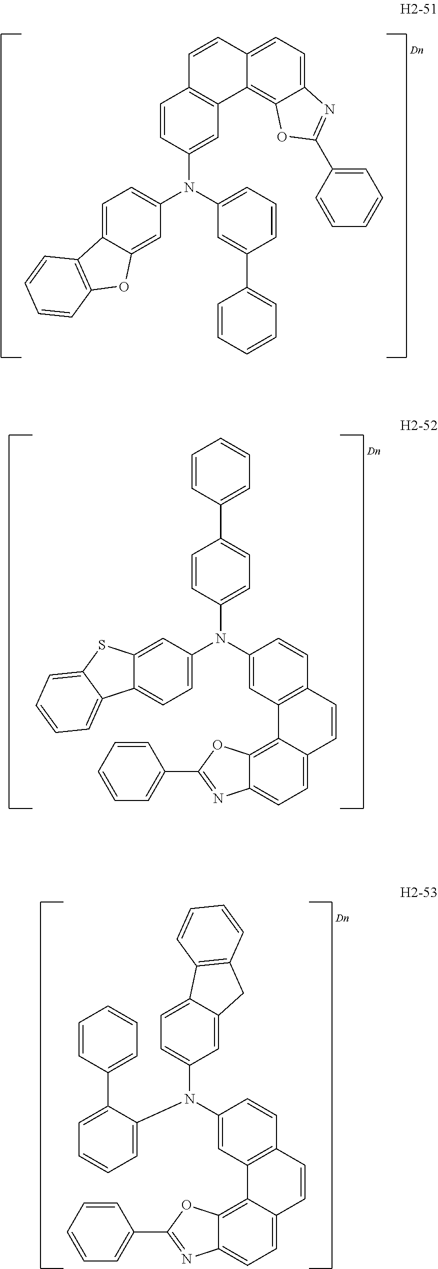

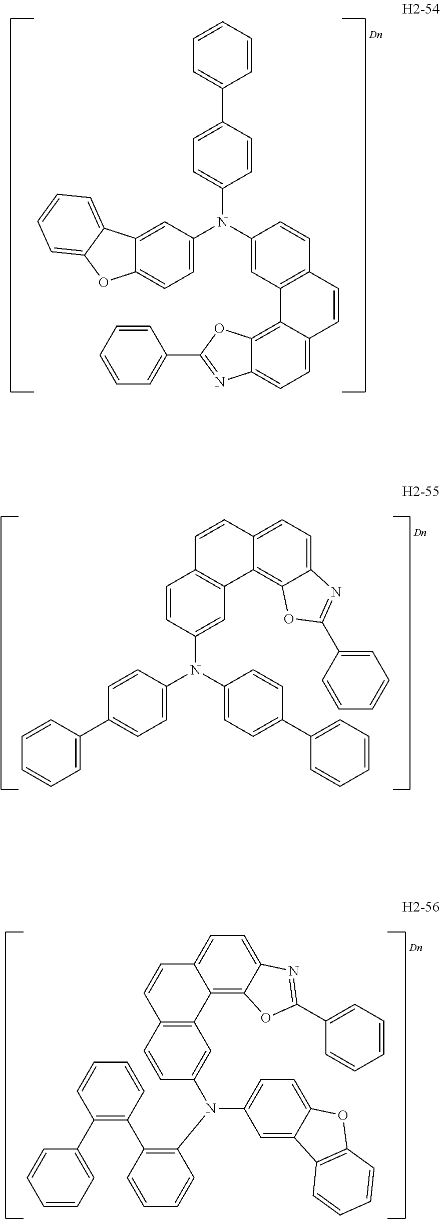

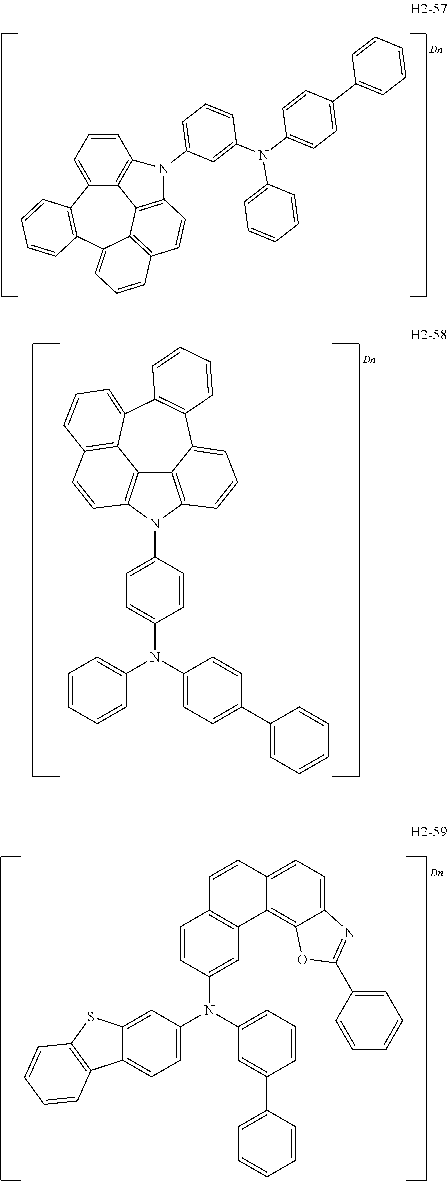

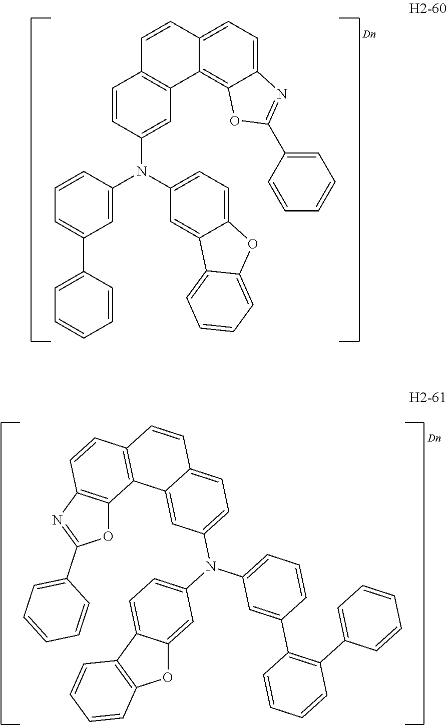

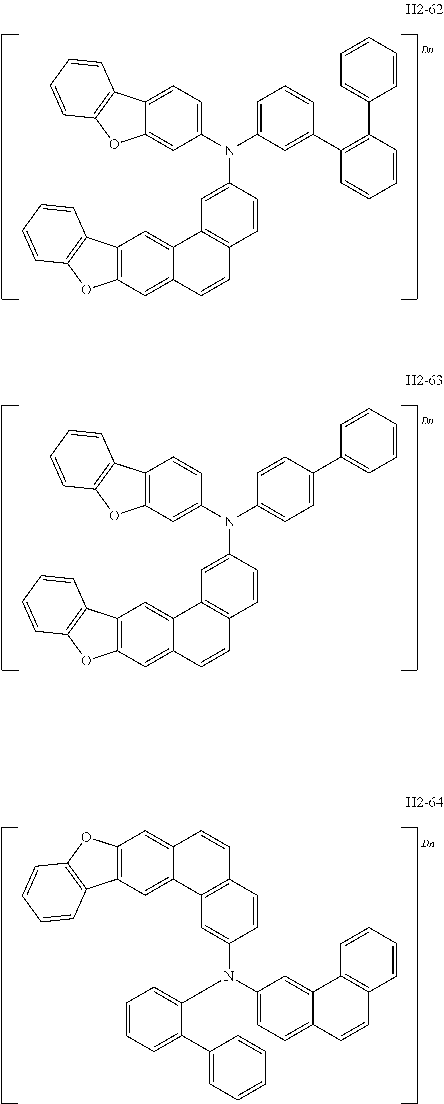

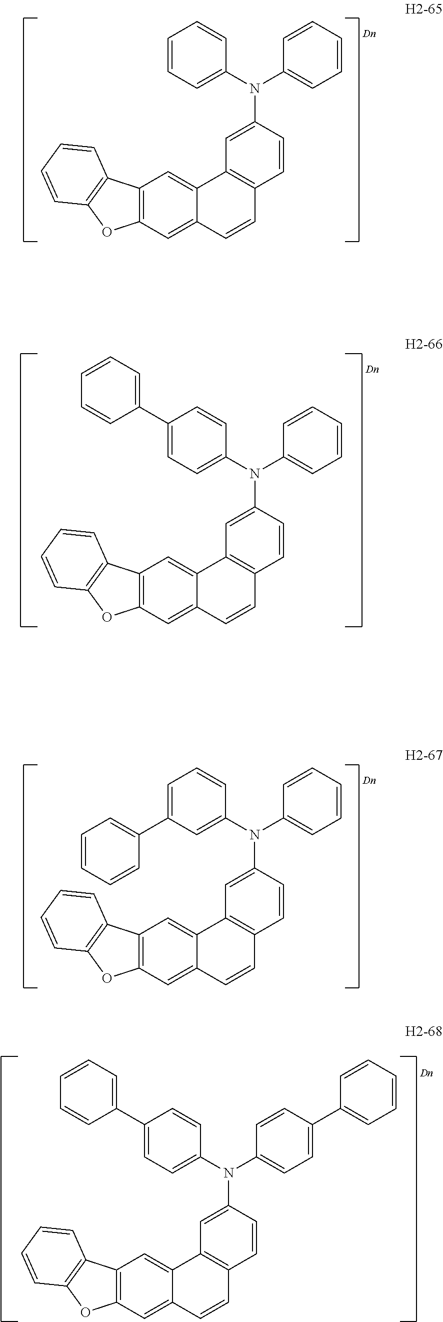

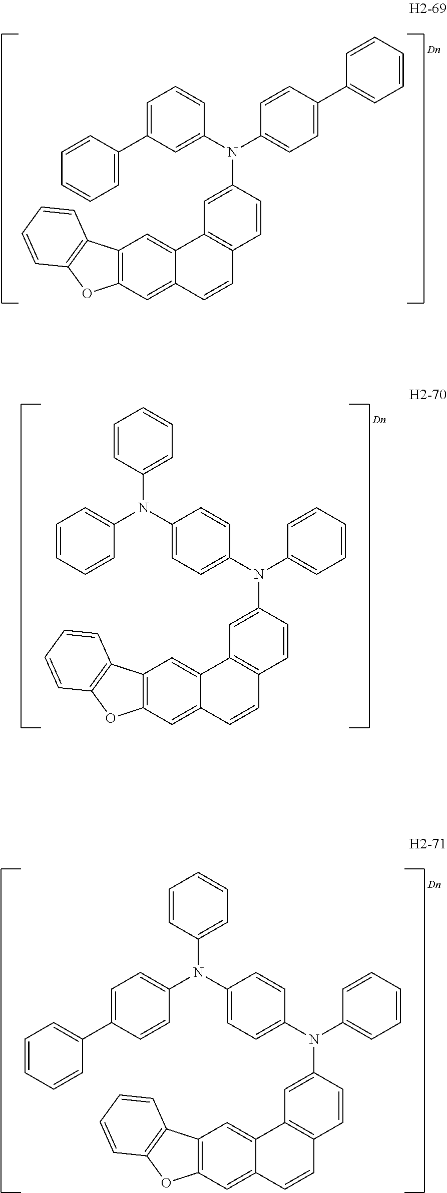

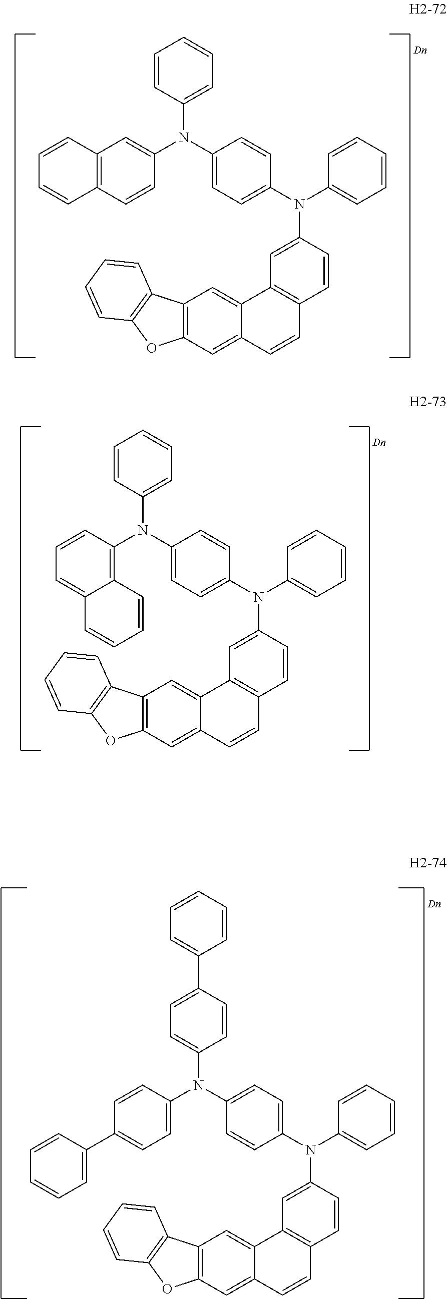

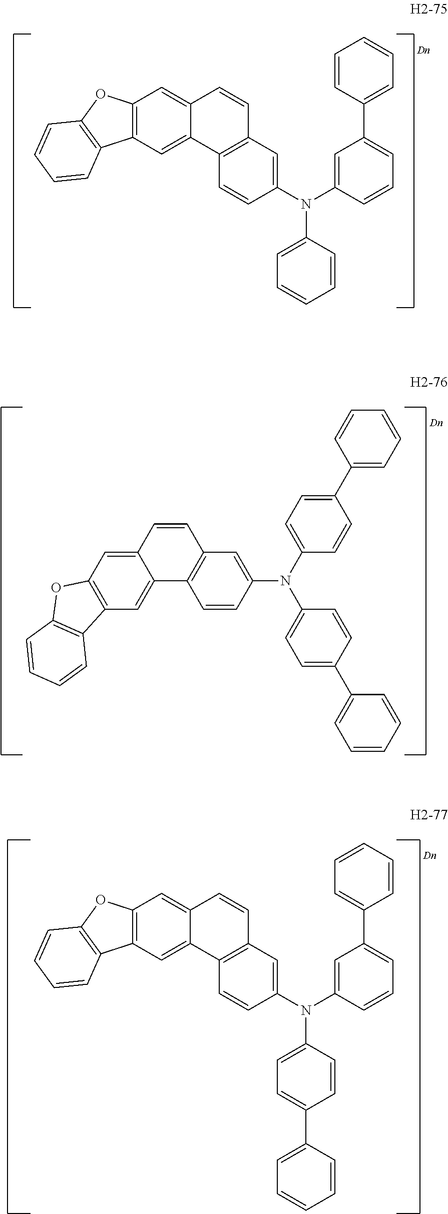

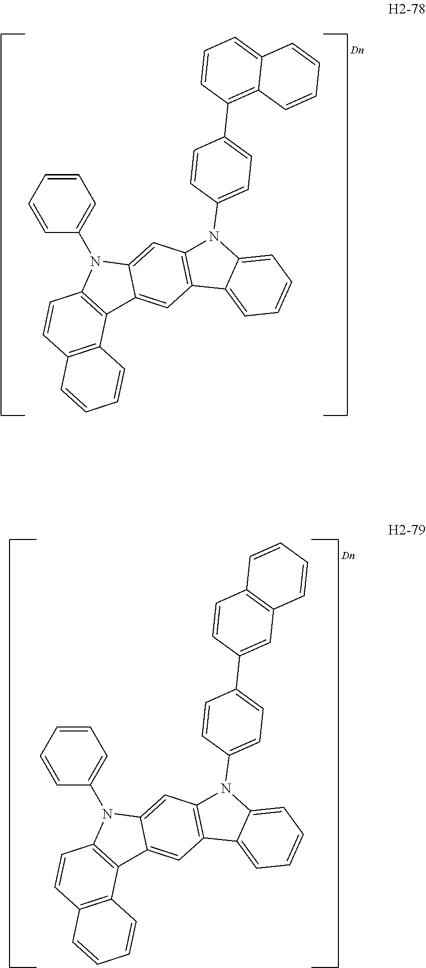

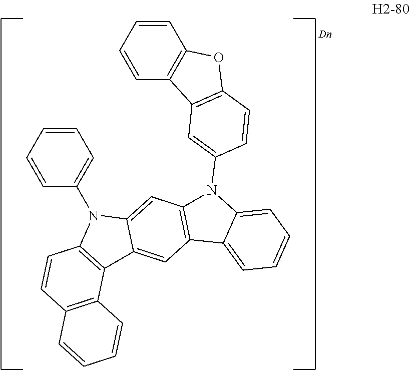

wherein Dₙ means that n number of hydrogens is replaced with deuterium, wherein n is an integer of 1 or more, and the upper limit of n is determined according to the number of hydrogens in the non-deuterated compound.

In another embodiment, the at least one light-emitting layer may comprise at least two compounds selected from compounds represented by the following Formula 6 or 7.

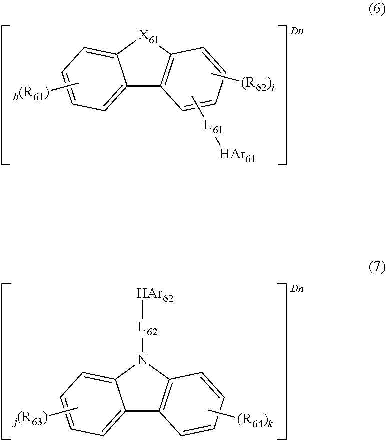

In Formulas 6 and 7,
X₆₁ represents —O— or —S—;
HAr₆₁ and HAr₆₂ each independently represent a substituted or unsubstituted (3- to 30-membered)heteroaryl containing at least one nitrogen atom;
L₆₁ and L₆₂ each independently represent a single bond, a substituted or unsubstituted (C6-C30)arylene, or a substituted or unsubstituted (3- to 30-membered)heteroarylene;
R₆₁ to R₆₄ each independently represent hydrogen, deuterium, a substituted or unsubstituted (C6-C30)aryl, or a substituted or unsubstituted (3- to 30-membered)heteroaryl; or may be linked to the adjacent substituents to form a substituted or unsubstituted indole ring, a substituted or unsubstituted benzofuran ring, a substituted or unsubstituted benzothiophene ring, a substituted or unsubstituted indene ring, or a substituted or unsubstituted benzene ring;
h to k each independently represent an integer of 1 to 4, when h to k are an integer of 2 or more, each of R₆₁ to each of R₆₄ may be the same as or different from each other; and
Dₙ means that n number of hydrogens is replaced with deuterium, wherein n is an integer of 1 or more, and the upper limit of n is determined according to the number of hydrogens in the non-deuterated compound.

In one embodiment, HAr₆₁ and HAr₆₂ each independently may be a substituted or unsubstituted (5- to 25-membered)heteroaryl containing at least two nitrogen atoms, preferably (5- to 18-membered)heteroaryl containing at least three nitrogen atoms and unsubstituted or substituted with (C6-C30)aryl or (5- to 30-membered)heteroaryl. For example, HAr₆₁ and HAr₆₂ each independently may be substituted triazinyl. Wherein, the substituent may be substituted with at least one, preferably at least two selected from a substituted or unsubstituted naphthyl, selected from a substituted or unsubstituted phenyl, a substituted or unsubstituted p-biphenyl, a substituted or unsubstituted m-biphenyl, a substituted or unsubstituted o-biphenyl, a substituted or unsubstituted m-terphenyl, naphthyl unsubstituted or substituted with at least one of phenyl; naphthyl; and dibenzofuranyl, or a substituted or unsubstituted dibenzofuranyl, which may be further substituted with at least one deuterium.

In one embodiment, L₆₁ and L₆₂ each independently may be a single bond, a substituted or unsubstituted (C6-C30)arylene, or a substituted or unsubstituted (5- to 30-membered)heteroarylene, preferably, a single bond, a substituted or unsubstituted (C6-C25)arylene, or a substituted or unsubstituted (5- to 25-membered)heteroaryl. For example, L₆₁ and L₆₂ each independently may be a single bond, a substituted or unsubstituted phenylene, a substituted or unsubstituted naphthylene, or a substituted or unsubstituted dibenzofuranylene, which may be further substituted with at least one deuterium.

In one embodiment, R₆₁ to R₆₄ each independently may be hydrogen, deuterium, a substituted or unsubstituted (C6-C30)aryl, or a substituted or unsubstituted (5- to 30-membered) heteroaryl; or may be linked to the adjacent substituents to form a ring(s), preferably, hydrogen, deuterium, a substituted or unsubstituted (C6-C18)aryl, or a substituted or unsubstituted (5- to 25-membered)heteroaryl; or may be linked to the adjacent substituents to form a ring(s). For example, R₆₁ to R₆₄ each independently may be hydrogen, deuterium, a substituted or unsubstituted naphthyl, a substituted or unsubstituted carbazolyl, a substituted or unsubstituted dibenzothiophenyl, or a substituted or unsubstituted dibenzofuranyl, or may be linked to the adjacent substituents to form an indole ring, a benzothiophene ring, or a benzene ring substituted with phenyl or biphenyl, which can be further substituted with at least one deuterium.

In one embodiment, the deuterium substitution rate in Formula 6 or 7 is preferably 20% to 100%, more preferably 20% to 95%, even more preferably 30% to 95%, and even more preferably 40% to 95% of the total number of hydrogens.

According to one embodiment, the deuterated compounds represented by Formula 6 or 7 can be more specifically exemplified by the compounds below, but are not limited thereto.

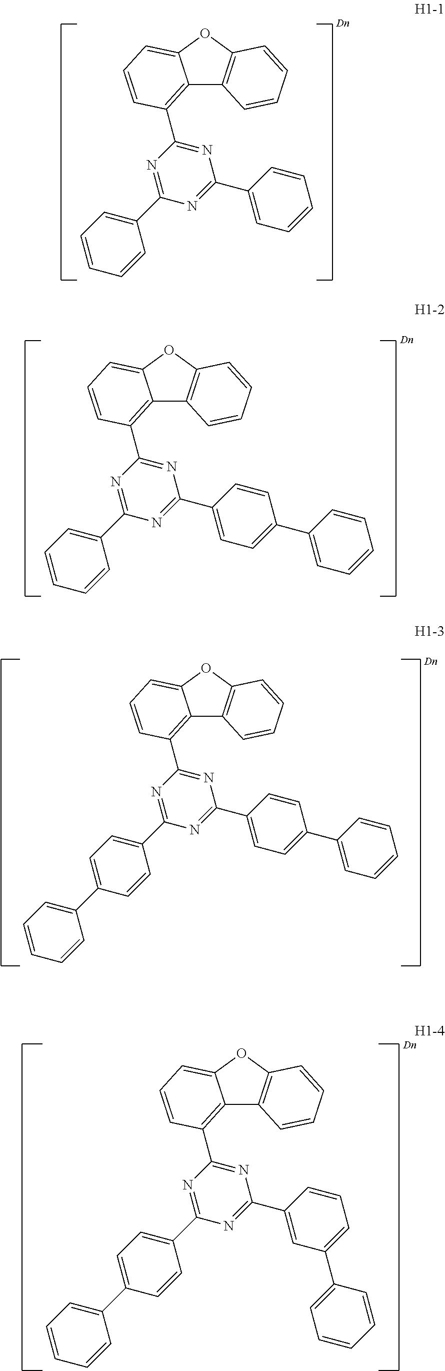

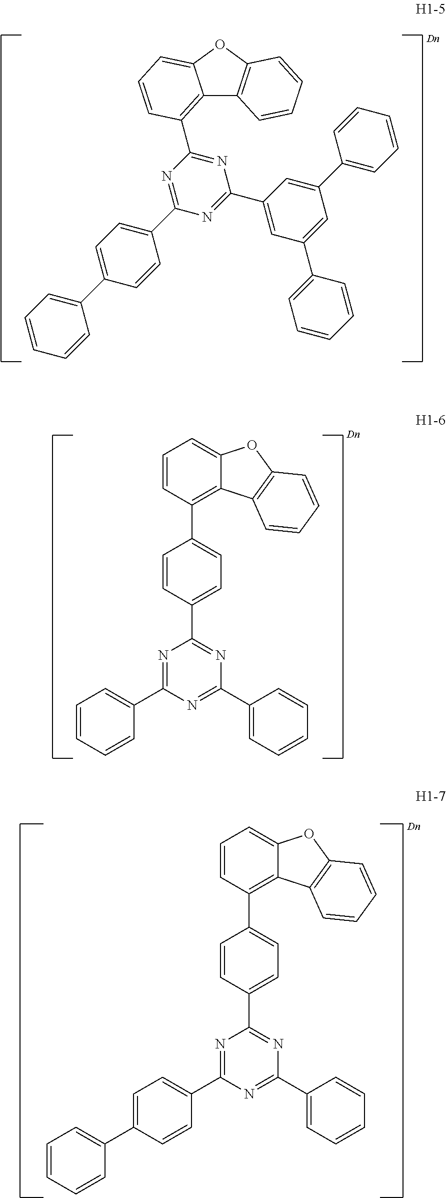

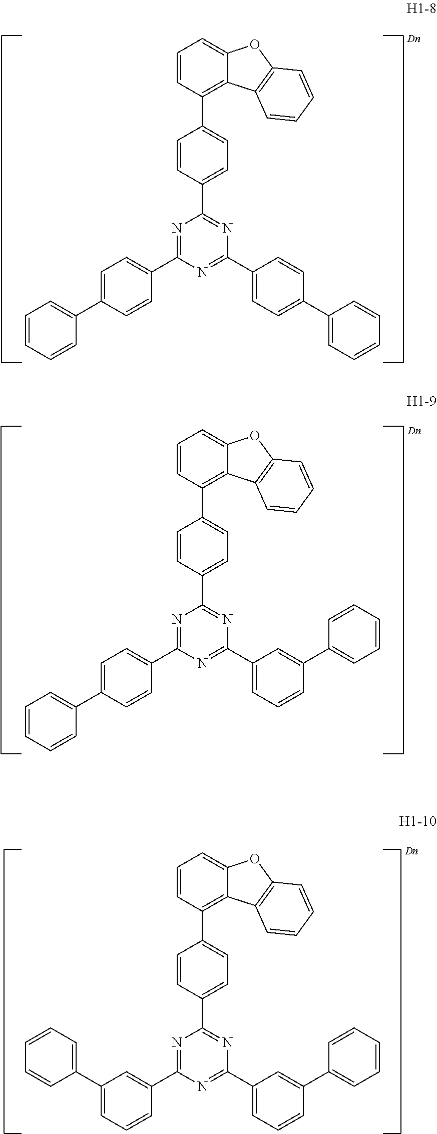

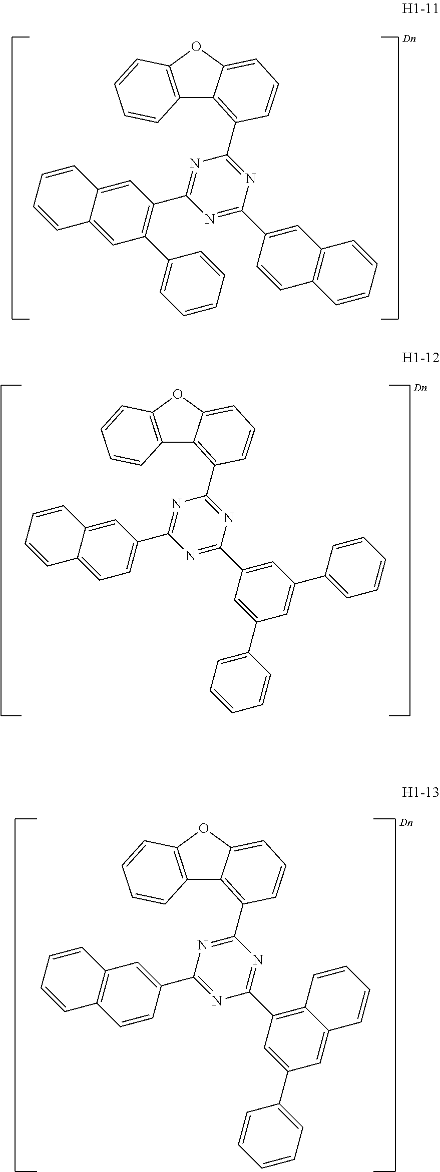

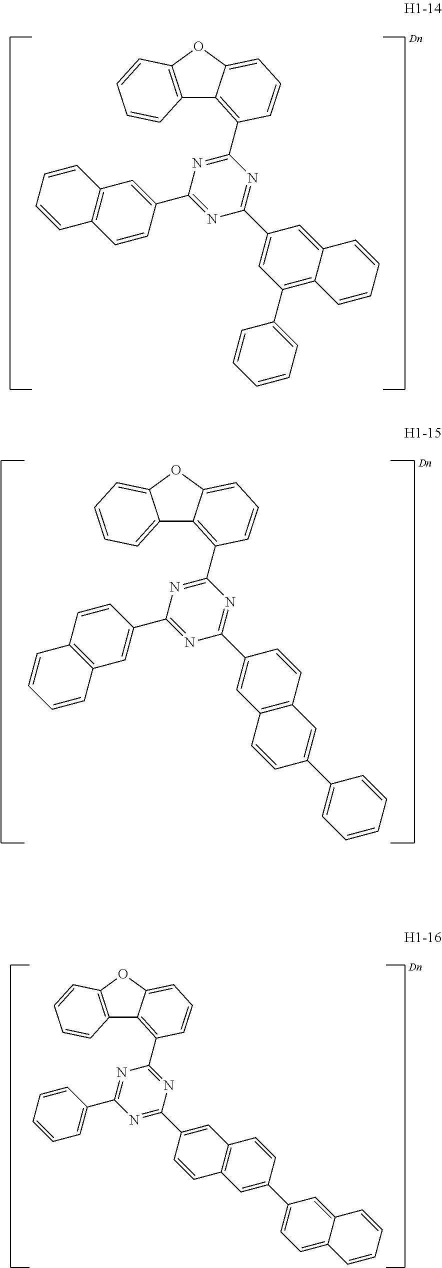

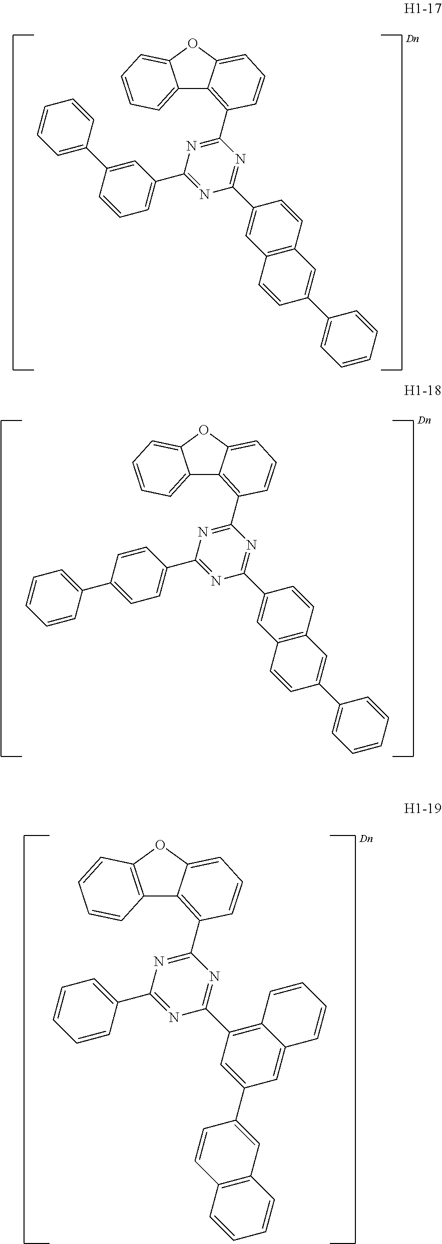

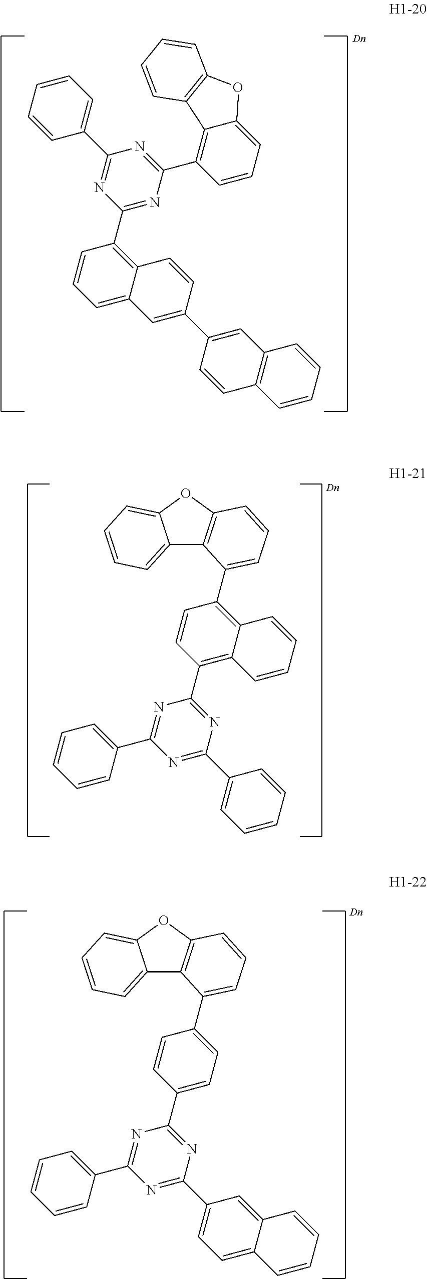

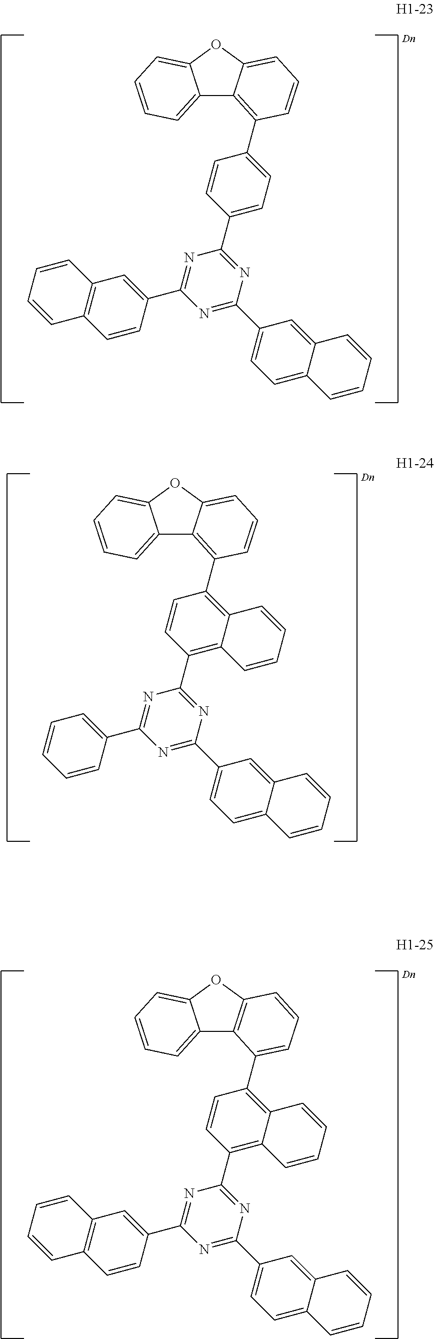

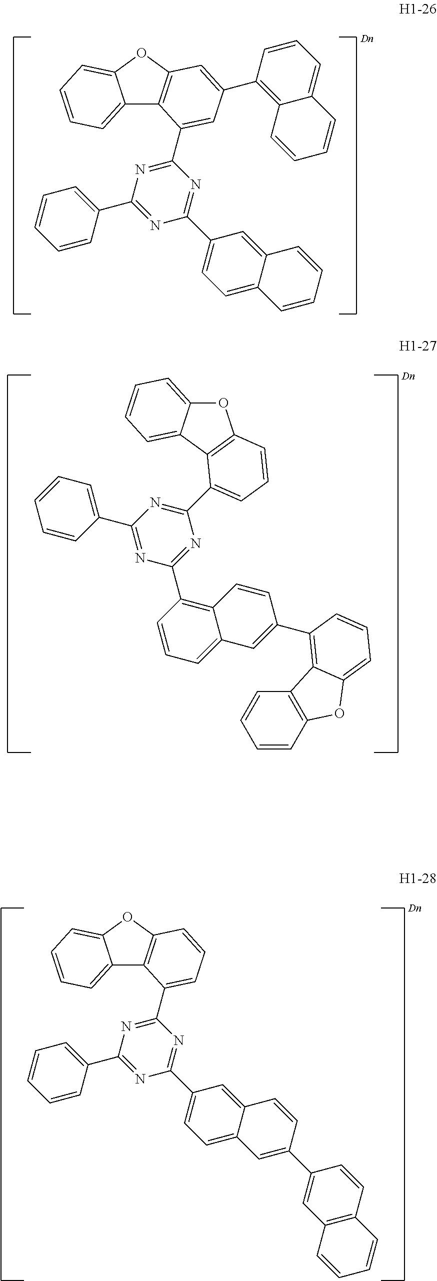

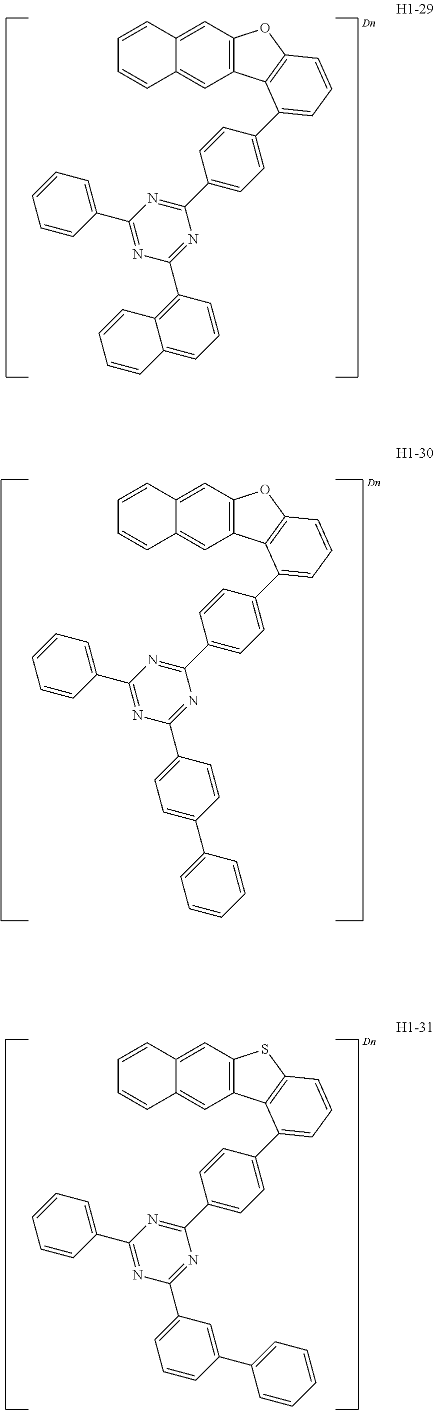

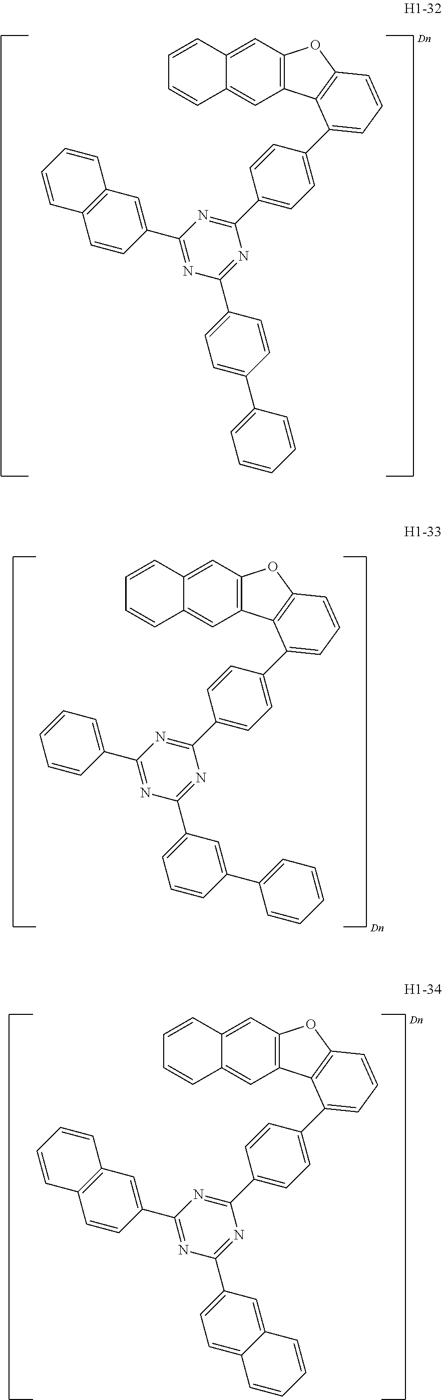

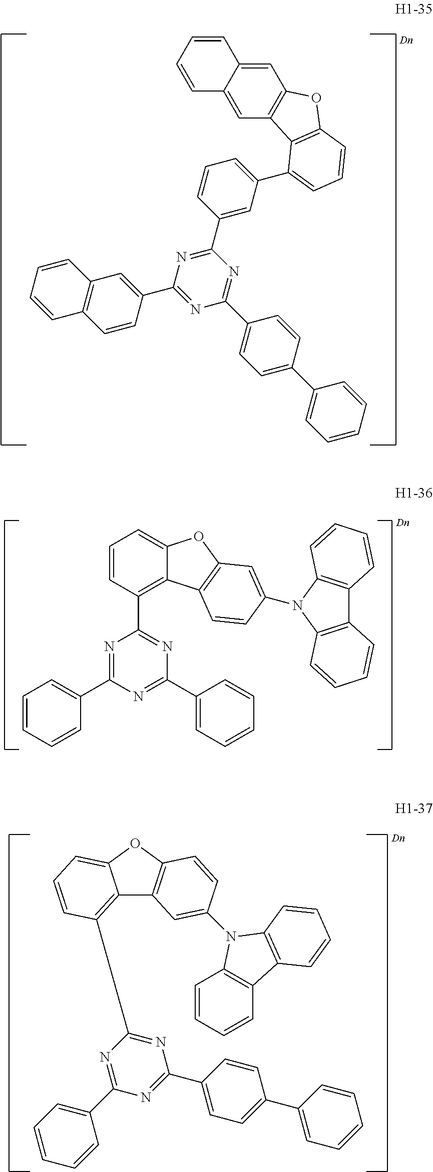

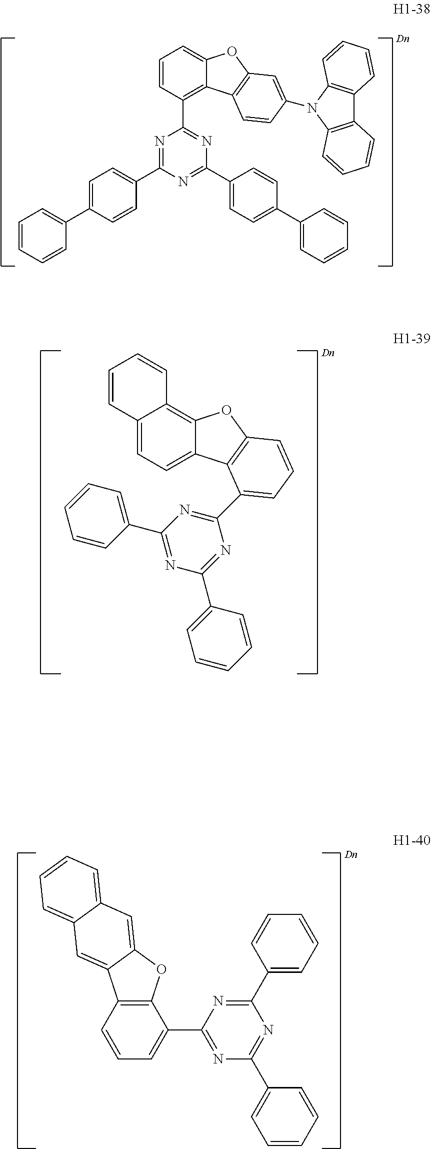

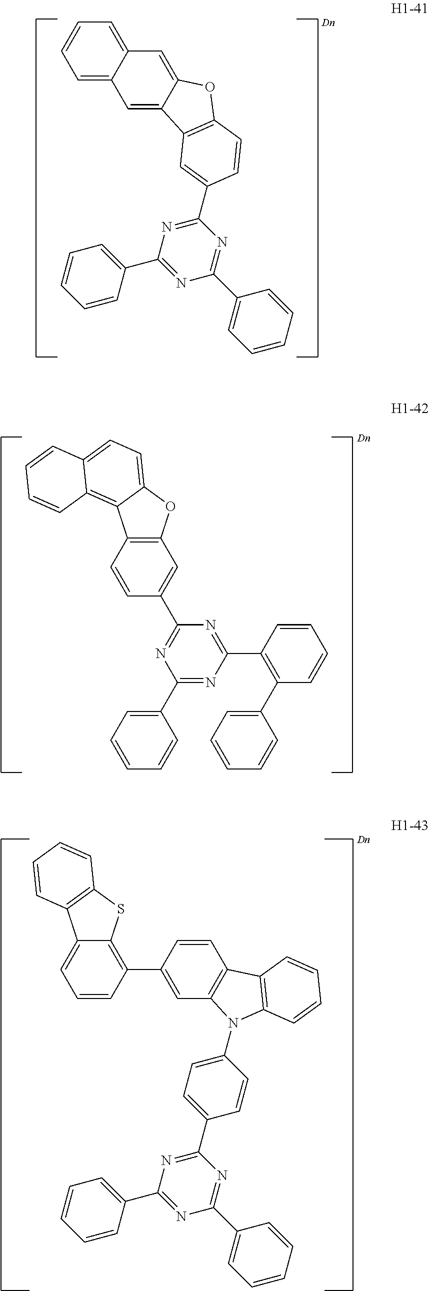

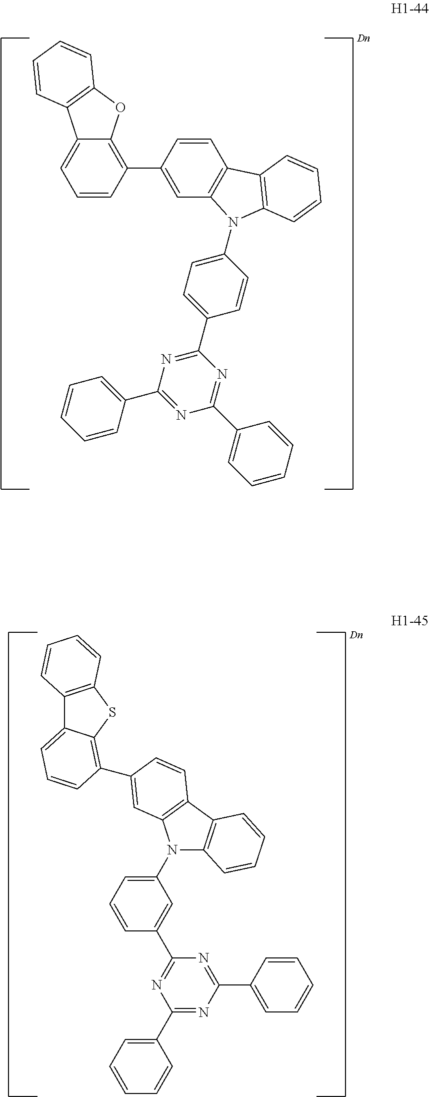

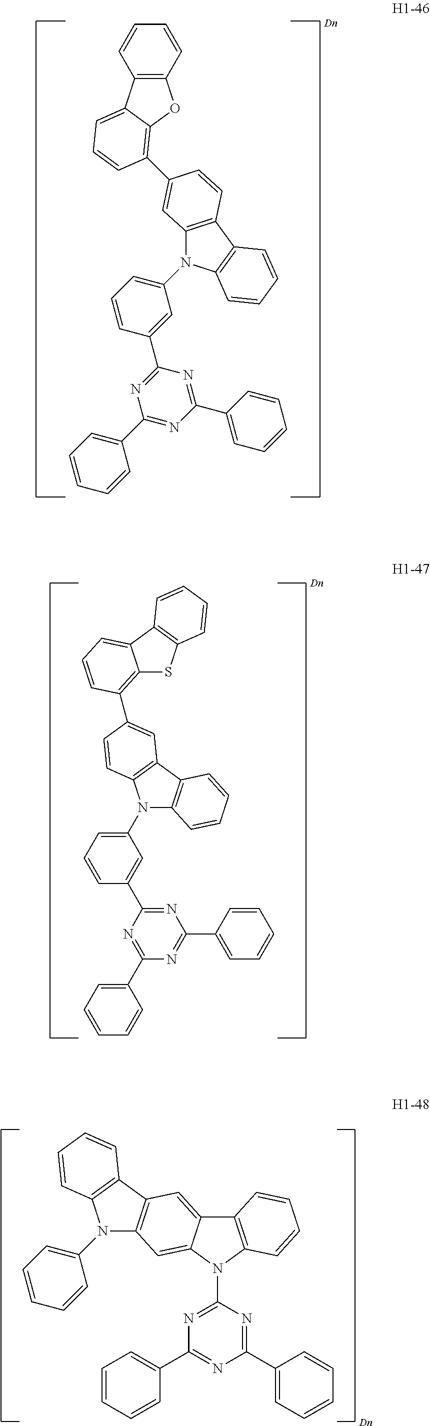

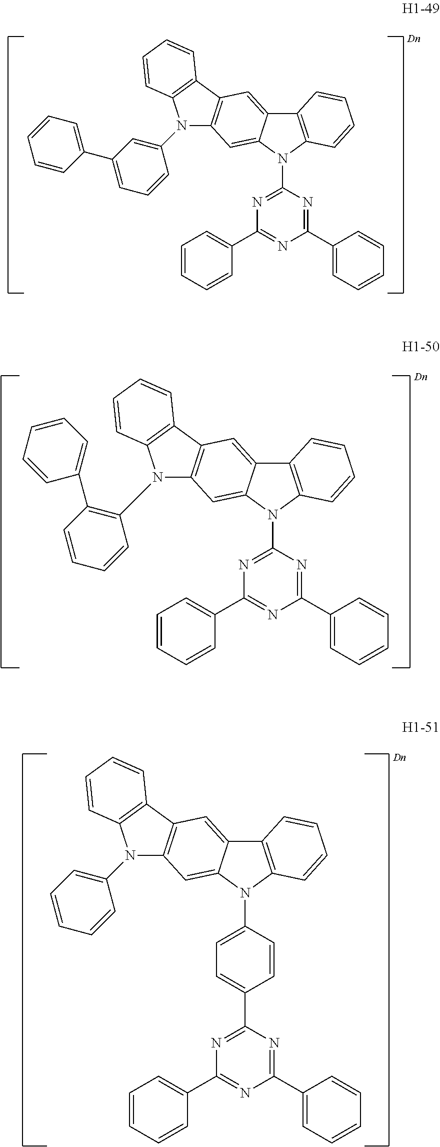

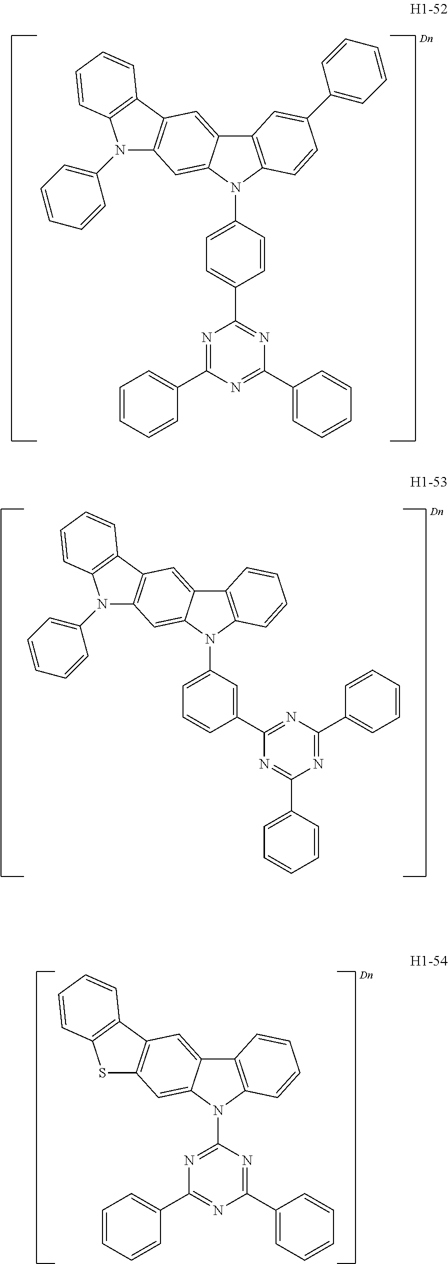

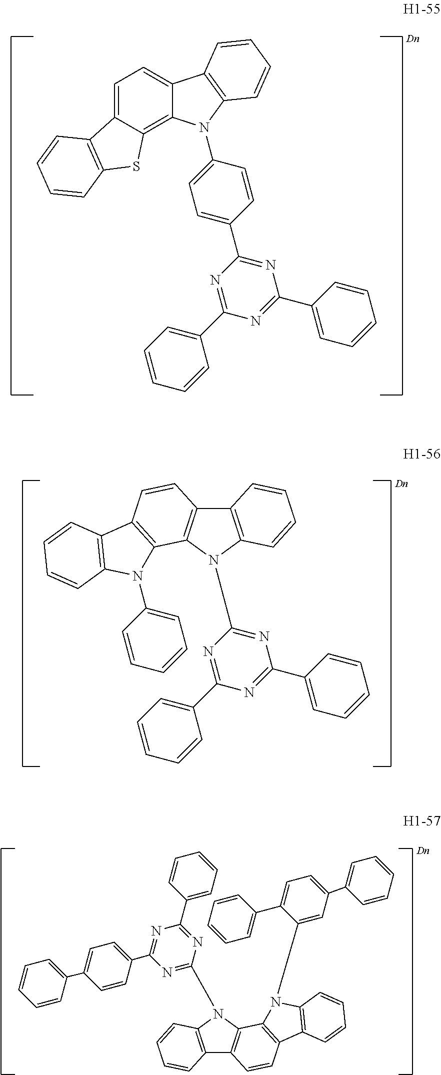

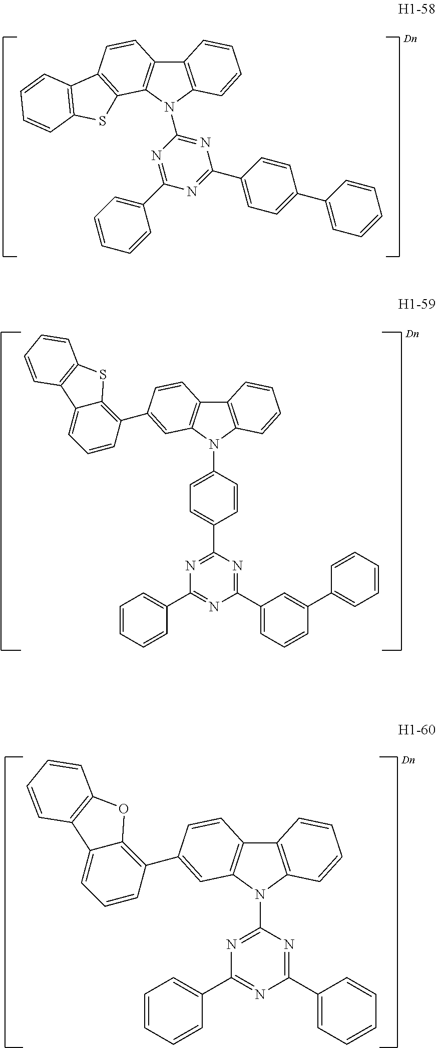

wherein Dₙ means that n number of hydrogens is replaced with deuterium, wherein n is an integer of 1 or more, and the upper limit of n is determined according to the number of hydrogens in the non-deuterated compound.

In one embodiment, at least one of the at least four compounds included in the light-emitting layer is a phosphorescent or fluorescent light-emitting compound, and the light-emitting compound comprises iridium (Ir), platinum (Pt), or boron (B) atoms, and preferably may comprise iridium atoms.

In another embodiment, the at least one light-emitting layer may comprise a compound represented by the following Formula 8.

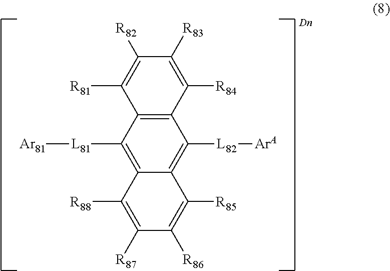

In Formula 8,
L₈₁ and L₈₂ each independently represent a single bond, a substituted or unsubstituted (C6-C30)arylene, or a substituted or unsubstituted (3- to 30-membered)heteroarylene;
Ar₈₁ represents a substituted or unsubstituted (C6-C30)aryl or a substituted or unsubstituted (3- to 30-membered)heteroaryl;
R₈₁ to R₈₈ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted a fused ring of (C3-C30) aliphatic ring and (C6-C30) aromatic ring;
Ar^{A} represents a substituted or unsubstituted (C6-C30)aryl, a substituted or unsubstituted (3- to 30-membered)heteroaryl, or is represented by the following Formula A-1; and
Dₙ means that n number of hydrogens is replaced with deuterium, wherein n is an integer of 1 or more, and the upper limit of n is determined according to the number of hydrogens in the non-deuterated compound.

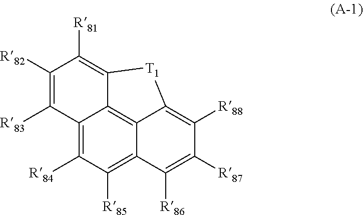

In Formula A-1,
T₁ represents —O—, —S—, or —CRᵢRₘ;
R′₈₁ to R′₈₈ each independently represent a site linked to L₈₂, or hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted a fused ring of (C3-C30) aliphatic ring and (C6-C30) aromatic ring, or -L₈₃-N(Ar₈₃)(Ar₈₄);
Rₗ and Rₘ each independently represent a substituted or unsubstituted (C1-C30)alkyl, or a substituted or unsubstituted (C6-C30)aryl; may be linked to each other to form a ring(s);
L₈₃ represents a single bond, a substituted or unsubstituted (C6-C30)arylene or a substituted or unsubstituted (3- to 30-membered)heteroarylene; and
Ar₈₃ and Ar₈₄ each independently represent a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl.

In one embodiment, Ar₈ₗ may be a substituted or unsubstituted (C6-C30)aryl, preferably, a substituted or unsubstituted (C6-C25)aryl, more preferably a substituted or unsubstituted (C6-C18)aryl. For example, Ar₈₁ may be phenyl unsubstituted or substituted with naphthyl, a substituted or unsubstituted naphthyl, or a substituted or unsubstituted biphenyl, which may be further substituted with at least one deuterium.

In one embodiment, R₈₁ to R₈₈ each independently may be hydrogen or deuterium.

In one embodiment, Ar^{A} may be a substituted or unsubstituted (C6-C25)aryl or a substituted or unsubstituted (5- to 30-membered)heteroaryl, or may be represented by the Formula A-1, preferabley, a substituted or unsubstituted (C6-C18)aryl, or a substituted or unsubstituted (5- to 25-membered)heteroaryl, or may be represented by Formula A-1. For example, Ar^{A} may be a substituted or unsubstituted phenyl, a substituted or unsubstituted naphthyl, a substituted or unsubstituted benzofluorenyl, a substituted or unsubstituted dibenzofuranyl, a substituted or unsubstituted benzonaphthofuranyl, or may be represented by Formula A-1. Wherein the substituents may be substituted with at least one selected from deuterium, methyl, phenyl, naphthyl, and dibenzofuranyl.

In one embodiment, T₁ may be —O—.

In one embodiment, R′₈₁ to R′₈₈ each independently may be a site linked to L₈₂, or may be hydrogen, deuterium, a halogen, a cyano, or a substituted or unsubstituted (C6-C30)aryl, preferably, may be a site linked to L₈₂, or hydrogen, deuterium, or unsubstituted (C6-C25)aryl. For example, R′₈₁ to R′₈₈ each independently may be a site linked to L₈₂, or hydrogen, deuterium, or a substituted or unsubstituted phenyl, which may be further substituted with at least one deuterium.

In one embodiment, L₈₁ to L₈₃ each independently may be a single bond or a substituted or unsubstituted (C6-C30)arylene, preferably, a single bond or a substituted or unsubstituted (C6-C18)arylene. For example, L₈₁ to L₈₃ each independently may be a single bond, a substituted or unsubstituted phenylene, a substituted or unsubstituted naphthylene, or a substituted or unsubstituted phenanthrenylene, which may be further substituted with at least one deuterium.

In one embodiment, the deuterium substitution rate in Formula 8 is preferably 20% to 100%, more preferably 20% to 95%, even more preferably 30% to 95%, and even more preferably 40% to 95% of the total number of hydrogens.

According to one embodiment, the deuterated compounds represented by Formula 8 can be more specifically exemplified by the compounds below, but are not limited thereto.

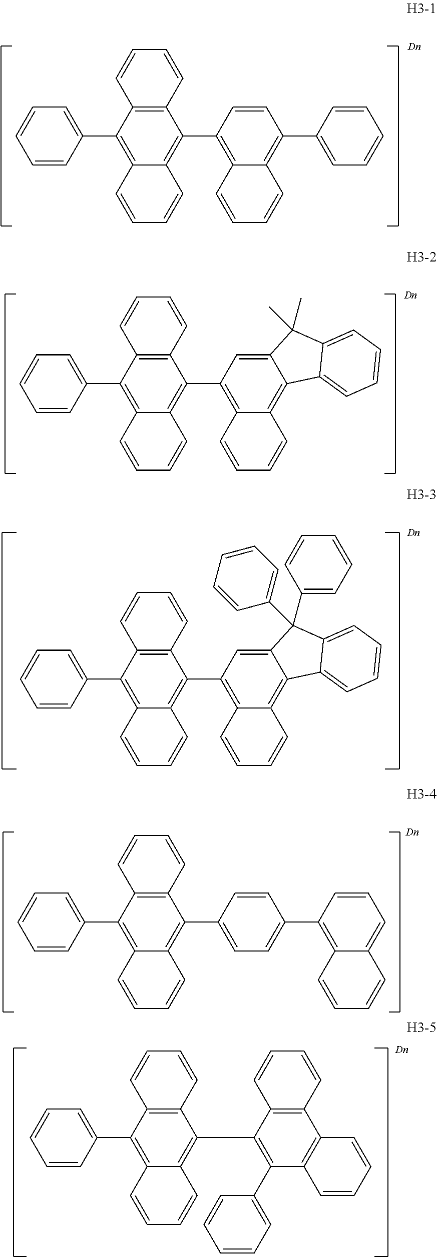

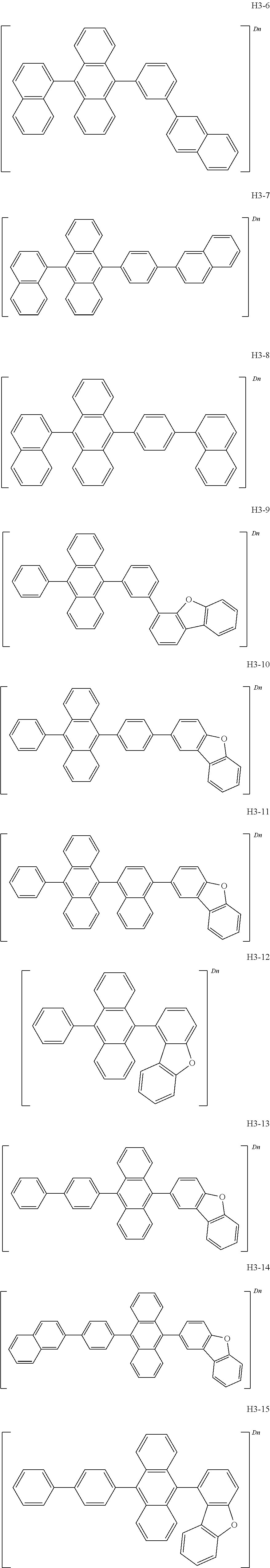

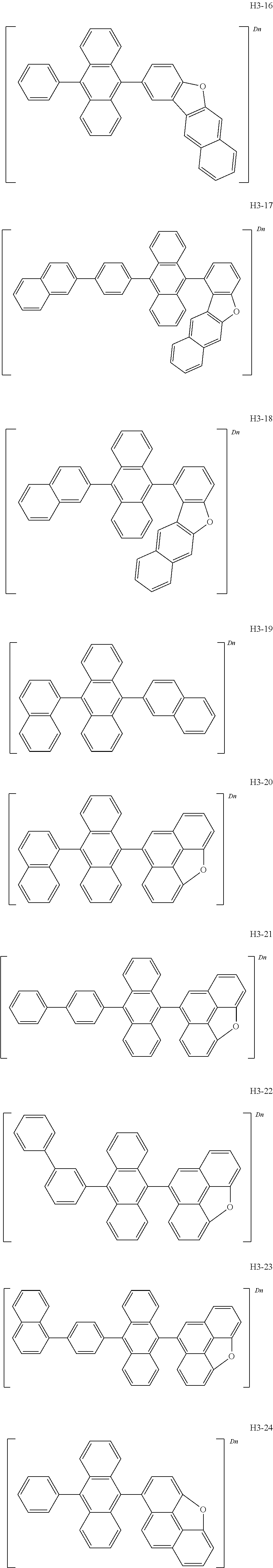

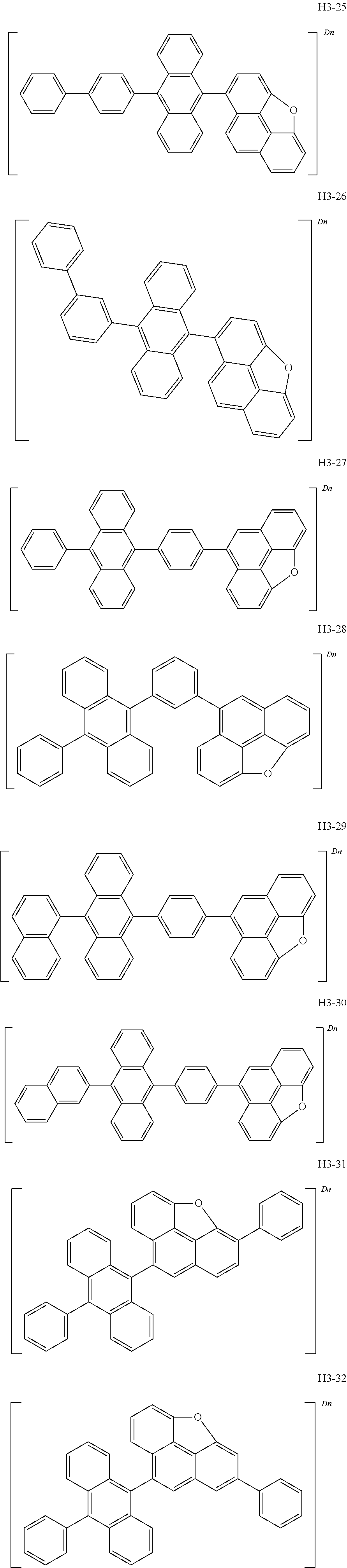

wherein Dₙ means that n number of hydrogens is replaced with deuterium, wherein n is an integer of 1 or more, and the upper limit of n is determined according to the number of hydrogens in the non-deuterated compound.

An electron transport zone according to one embodiment is positioned on the light-emitting layer, and is configured by sequentially stacking at least one layer of an electron buffer layer and a hole blocking layer, at least one electron transport layer, and an electron injection layer, wherein at least one layer of the electron buffer layer, the hole blocking layer, the electron transport layer, and the electron injection layer comprises a deuterated compound.

In one embodiment, the electron transport zone may comprise a compound represented by the following Formula 2 or 3.

The compound represented by Formula 2 included in the electron transport zone according to one embodiment is as follows.

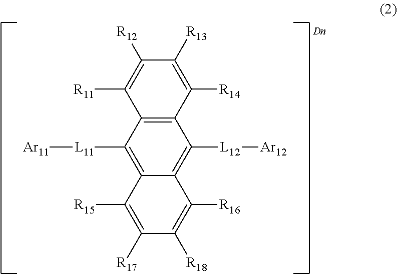

In Formula 2,
L₁₁ and L₁₂ each independently represent a single bond, a substituted or unsubstituted (C6-C30)arylene, or a substituted or unsubstituted (3- to 30-membered)heteroarylene;
Ar₁₁ and Ar₁₂ each independently represent a substituted or unsubstituted (C6-C30)aryl or a substituted or unsubstituted (3- to 30-membered)heteroaryl;
R₁₁ to R₁₈ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino;
at least one of R₁₁ and R₁₄ to R₁₆ is deuterium; and
Dₙ means that n number of hydrogens is replaced with deuterium, wherein n is an integer of 1 or more, and the upper limit of n is determined according to the number of hydrogens in the non-deuterated compound.

In one embodiment, L₁₁ and L₁₂ each independently may be a single bond or a substituted or unsubstituted (C6-C30)arylene, preferably a single bond or a substituted or unsubstituted (C6-C25)arylene, more preferably a single bond or a substituted or unsubstituted (C6-C18)arylene. For example, L₁₁ and L₁₂ each independently may be a single bond, a substituted or unsubstituted phenylene, or a substituted or unsubstituted naphthalene.

In one embodiment, Ar₁₁ and Ar₁₂ each independently may be a substituted or unsubstituted (C6-C30)aryl or a substituted or unsubstituted (5- to 30-membered)heteroaryl, preferably, a substituted or unsubstituted (C6-C25)aryl or a substituted or unsubstituted (5- to 25-membered)heteroaryl, more preferably, a substituted or unsubstituted (C6-C18)aryl or a substituted or unsubstituted (5- to 18-membered)heteroaryl. For example, Ar₁₁ and Ar₁₂ each independently may be a substituted or unsubstituted phenyl, a substituted or unsubstituted naphthyl, a substituted or unsubstituted m-biphenyl, a substituted or unsubstituted p-biphenyl, a substituted or unsubstituted triazinyl, or a substituted or unsubstituted benzimidazolyl represented by the following Formula 2-1 or 2-2.

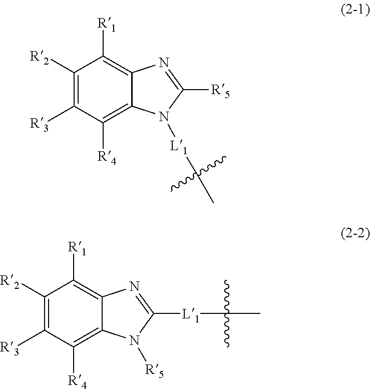

In Formulas 2-1 and 2-2,
L′₁ represents a single bond, a substituted or unsubstituted (C6-C30)arylene, or a substituted or unsubstituted (3- to 30-membered)heteroarylene;
R′₁ to R′₅ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; and
[symbol] represents a site linked to L₁₁ and L₁₂ in Formula 2.

In one embodiment, L′₁ may be a single bond or a substituted or unsubstituted (C6-C30)arylene, preferably a single bond or a substituted or unsubstituted (C6-C25)arylene, more preferably a single bond or a substituted or unsubstituted (C6-C18)arylene. For example, L′₁ may be a single bond or phenylene.

In one embodiment, R′₁ to R′₄ each independently may be hydrogen or deuterium.

In one embodiment, R′₅ may be a substituted or unsubstituted (C1-C30)alkyl or a substituted or unsubstituted (C6-C30)aryl, preferably a substituted or unsubstituted (C1-C10)alkyl or a substituted or unsubstituted (C6-C25)aryl, more preferably a substituted or unsubstituted (C1-C4)alkyl or a substituted or unsubstituted (C6-C18)aryl. For example, R′₅ may be a substituted or unsubstituted ethyl, a substituted or unsubstituted phenyl, a substituted or unsubstituted naphthyl, or a substituted or unsubstituted biphenyl.

In one embodiment, R₁₁ to R₁₈ each independently may be hydrogen, deuterium, or a substituted or unsubstituted benzimidazolyl represented by Formula 2-1 or 2-2.

In one embodiment, at least one of R₁₁ to R₁₈, Ar₁₁, and Ar₁₂ may be a substituted or unsubstituted benzimidazolyl represented by Formula 2-1 or 2-2.

The compound represented by Formula 3 included in the electron transfer zone according to one embodiment is as follows.

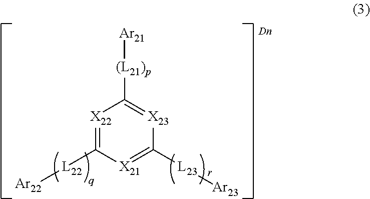

In Formula 3,
X₂₁ to X₂₃ each independently represent CR′ or N; provided that at least two of X₂₁ to X₂₃ are N;
R′ represents hydrogen or deuterium;
L₂₁ to L₂₃ each independently represent a single bond, a substituted or unsubstituted (C6-C30)arylene, or a substituted or unsubstituted (3- to 30-membered)heteroarylene;
Ar₂₁ to Ar₂₃ each independently represent a substituted or unsubstituted (C6-C30)aryl or a substituted or unsubstituted (3- to 30-membered)heteroaryl; provided that at least one of Ar₂₁ to Ar₂₃ comprises deuterium;
p, q, and r each independently represent an integer of 1 to 3, when p, q, and r are an integer of 2 or more, each of L₂₁ to each of L₂₃ may be the same as or different from each other; and
Dₙ means that n number of hydrogens is replaced with deuterium, wherein n is an integer of 1 or more, and the upper limit of n is determined according to the number of hydrogens in the non-deuterated compound.

In one embodiment, all of X₂₁ to X₂₃ are N, or at least two of X₂₁ to X₂₃ may be N, and the orther one of X₂₁ to X₂₃ may be CR′.

In one embodiment, R′ may be hydrogen or deuterium.

In one embodiment, L₂₁ to L₂₃ each independently may be a single bond, a substituted or unsubstituted (C6-C25)arylene, a substituted or unsubstituted (3- to 25-membered)heteroarylene, preferably a single bond, a substituted or unsubstituted (C6-C25)arylene, a substituted or unsubstituted (3- to 20-membered)heteroarylene. For example, L₂₁ to L₂₃ each independently may be a single bond, a substituted or unsubstituted phenylene, a substituted or unsubstituted naphthylene, a substituted or unsubstituted p-biphenylene, a substituted or unsubstituted m-biphenylene, or a substituted or unsubstituted o-terphenylene, a substituted or unsubstituted p-terphenylene, a substituted or unsubstituted o-quaterphenylene, a substituted or unsubstituted dibenzofuranylene, a substituted or unsubstituted quinolene, a substituted or unsubstituted pyridazylene. Wherein, the substituents may be further substituted with at least one selected from deuterium, phenyl unsubstituted or substituted with cyano, naphthyl, phenanthrenyl, pyridyl unsubstituted or substituted with at least one methyl or phenyl, a cyano and quinolinyl.

In one embodiment, Ar₂₁ to Ar₂₃ each independently may be a substituted or unsubstituted (C6-C30)aryl or a substituted or unsubstituted (5- to 30-membered)heteroaryl, preferably a substituted or unsubstituted (C6-C25)aryl or a substituted or unsubstituted (5- to 26-membered)heteroaryl, more preferably a substituted or unsubstituted (C6-C18)aryl or a substituted or unsubstituted (5- to 26-membered)heteroaryl. Preferably, at least one of Ar₂₁ to Ar₂₃ may be a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl, provided that at least one of Ar₂₁ to Ar₂₃ may comprise deuterium. For example, Ar₂₁ to Ar₂₃ each independently may be a substituted or unsubstituted phenyl, a substituted or unsubstituted naphthyl, a substituted or unsubstituted p-biphenyl, a substituted or unsubstituted m-biphenyl, a substituted or unsubstituted phenanthrenyl, a substituted or unsubstituted anthracenyl, a substituted or unsubstituted fluorenyl, a substituted or unsubstituted tetralin, a substituted or unsubstituted dibenzofuranyl, a substituted or unsubstituted carbazolyl, a substituted or unsubstituted dibenzothiophenyl, a substituted or unsubstituted benzoxazolyl, a substituted or unsubstituted dibenz[c,h]acridinyl, a substituted or unsubstituted pyridyl, a substituted or unsubstituted pyridazyl, a substituted or unsubstituted pyrazinyl, a substituted or unsubstituted triazinyl, a substituted or unsubstituted pyrimidinyl, a substituted or unsubstituted quinolinyl, a substituted or unsubstituted spiro[fluorene-9,9′-xanthene]yl, a substituted or unsubstituted spiro[fluorene-9,9′-thioxanthene]yl, a substituted or unsubstituted triphenylene, or a 22-membered heteroaryl, wherein the substituents may be further substituted with at least one selected from deuterium, a cyano, methyl, phenyl unsubstituted or substituted with cyano, biphenyl, naphthyl, and dibenzofuranyl.

In one embodiment, the deuterium substitution rate in Formula 2 or 3 is preferably 20% to 100%, more preferably 20% to 95%, even more preferably 30% to 95%, and even more preferably 40% to 95% of the total number of hydrogens.

According to one embodiment, the deuterated compounds represented by Formula 2 or 3 can be more specifically exemplified by the compounds below, but are not limited thereto.

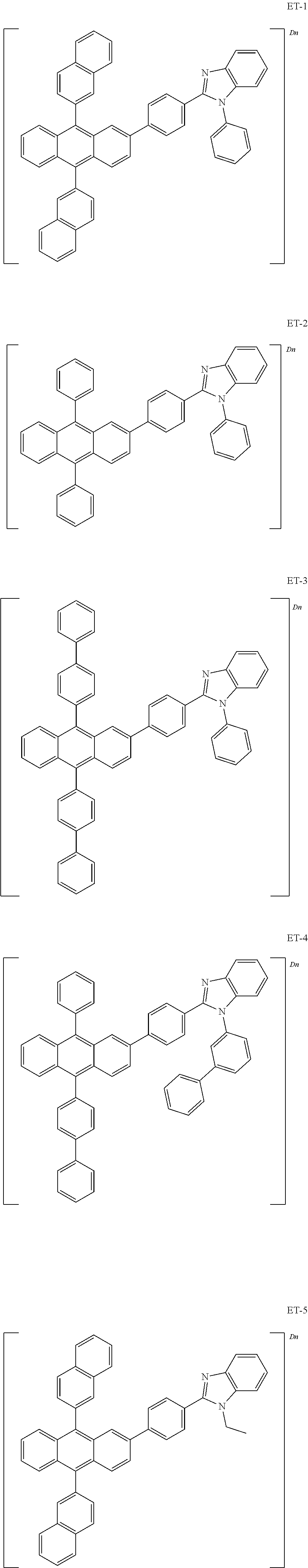

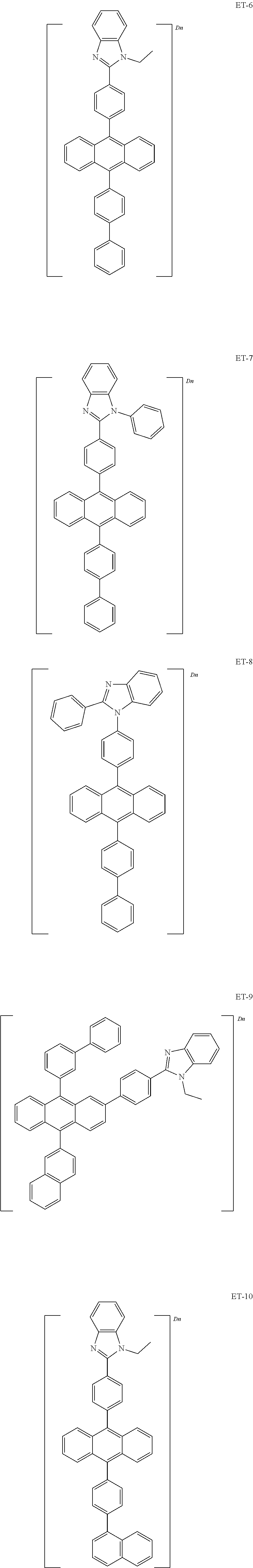

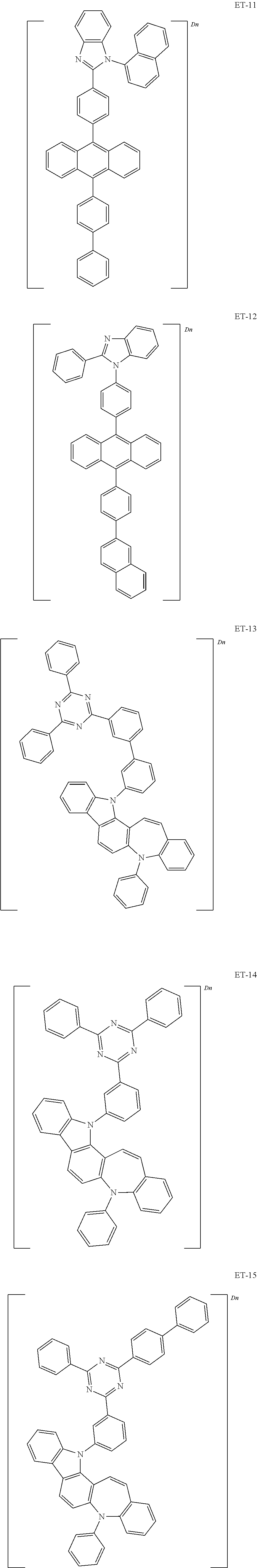

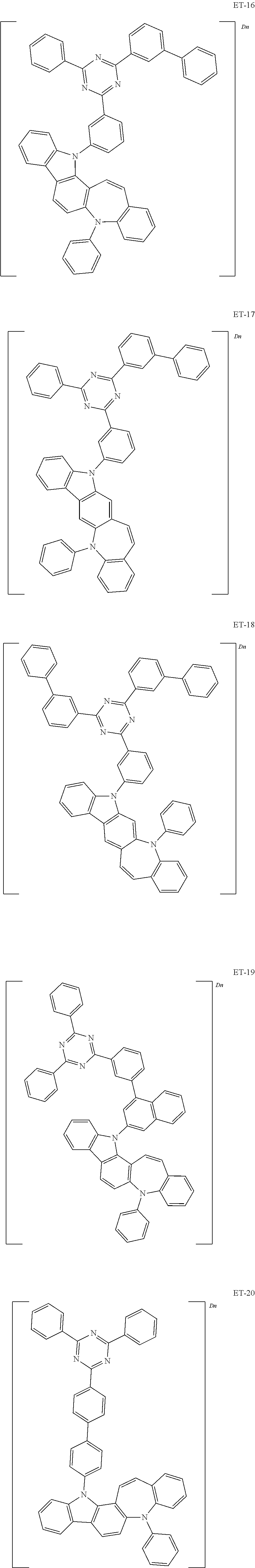

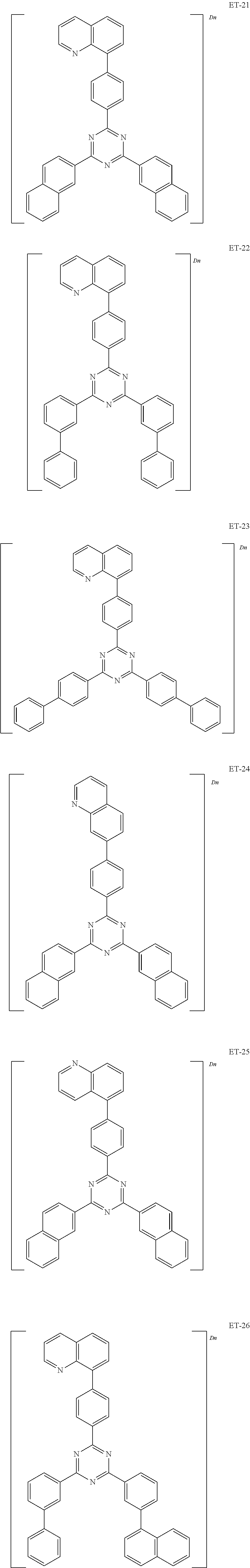

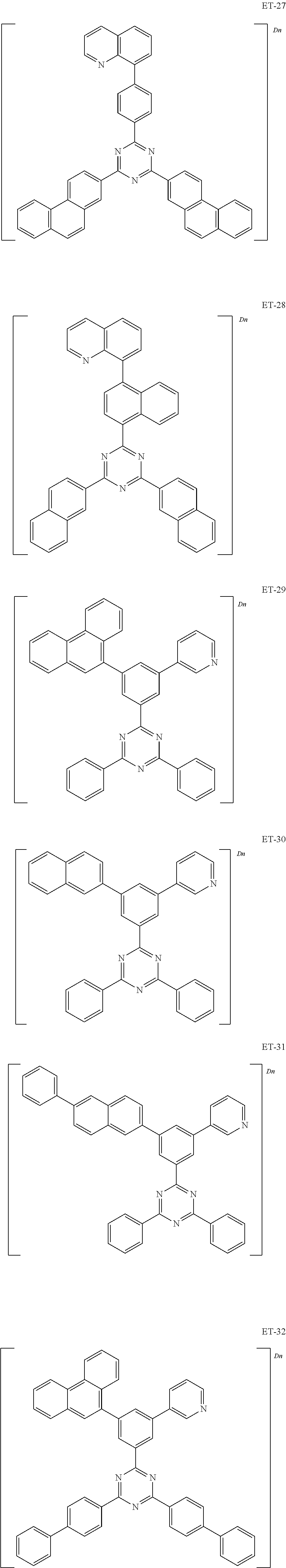

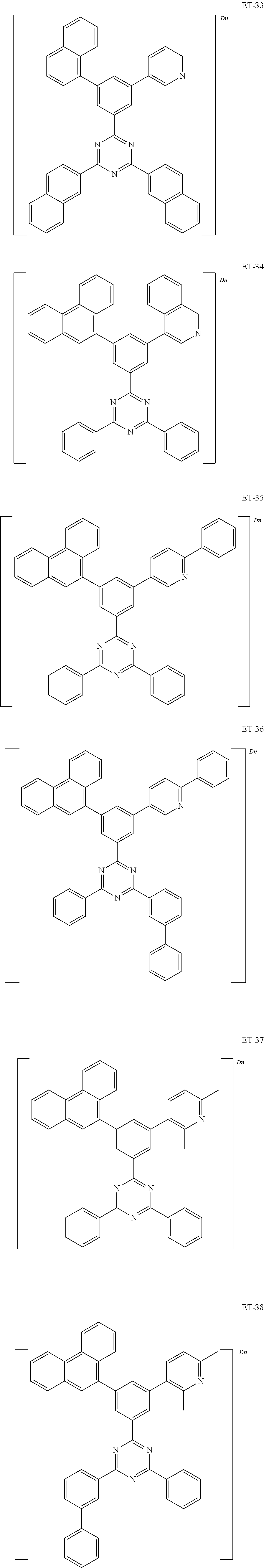

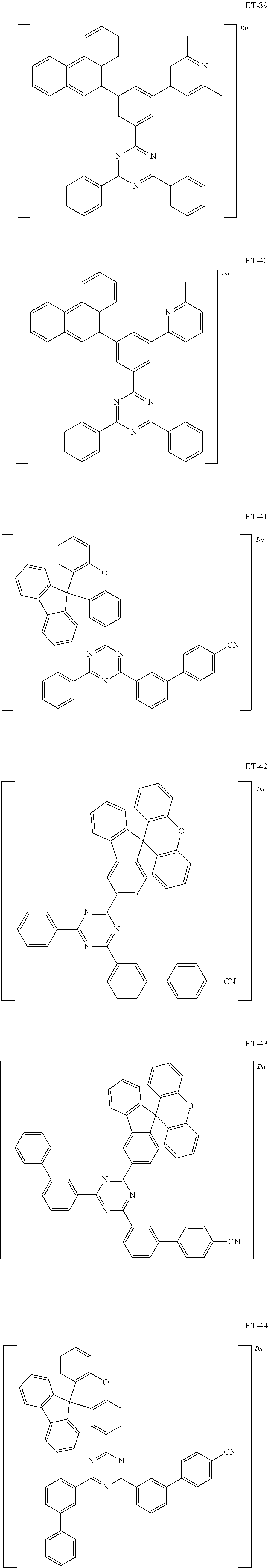

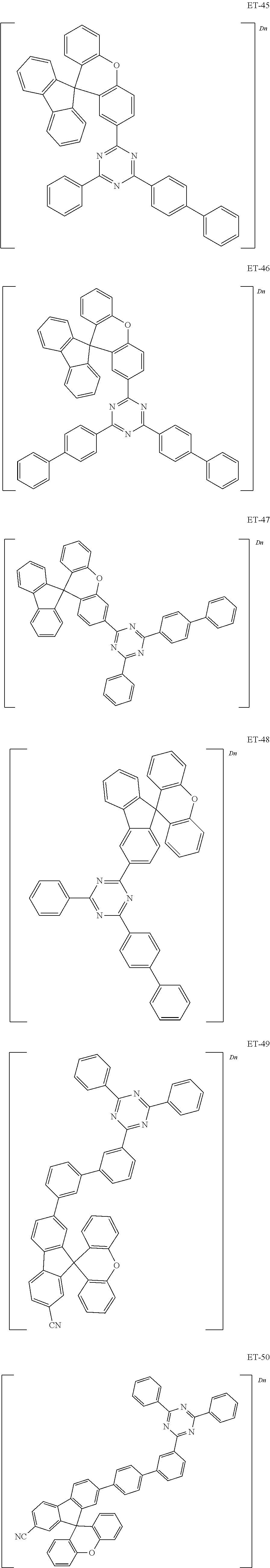

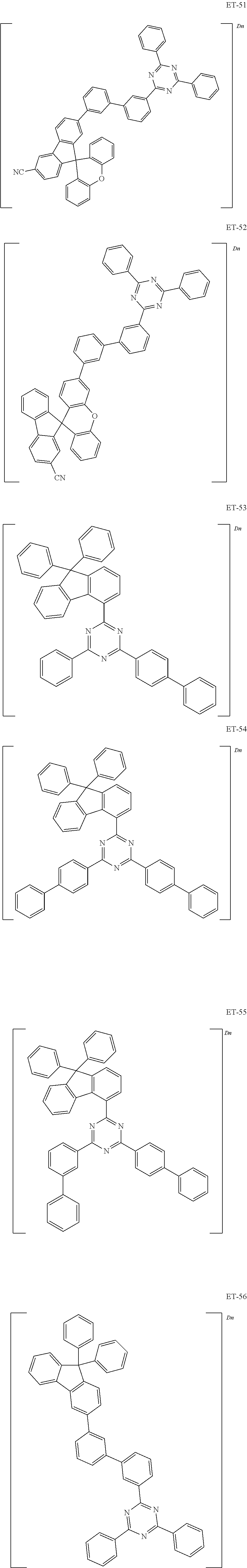

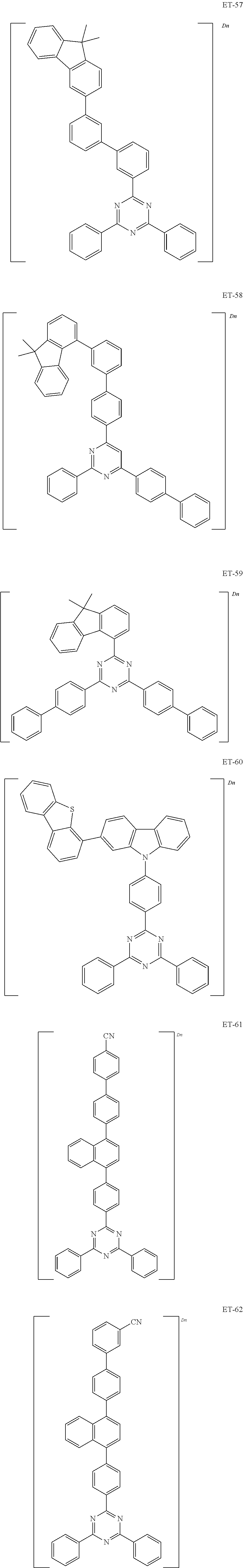

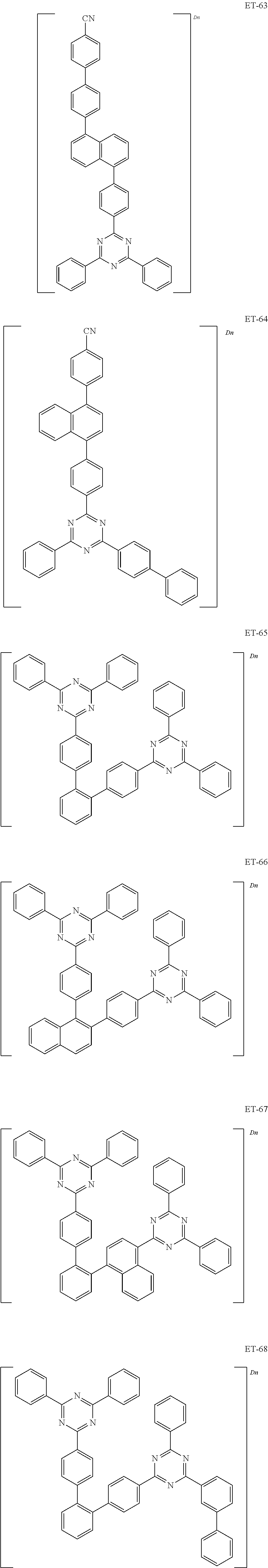

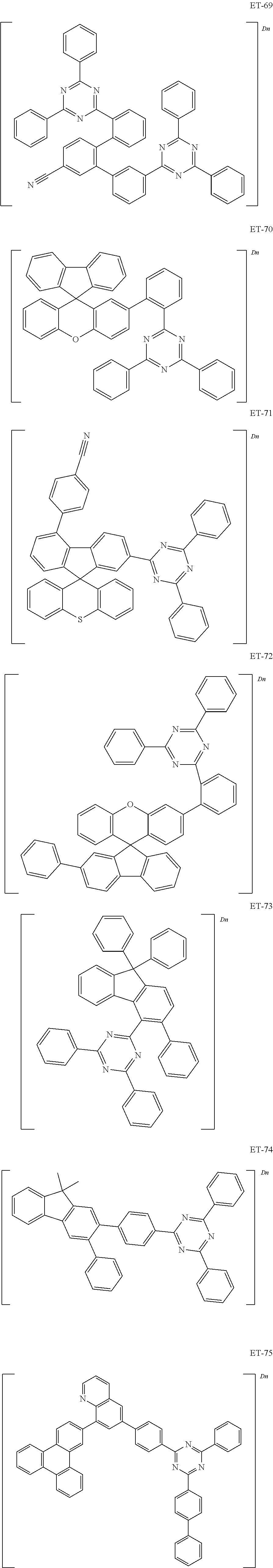

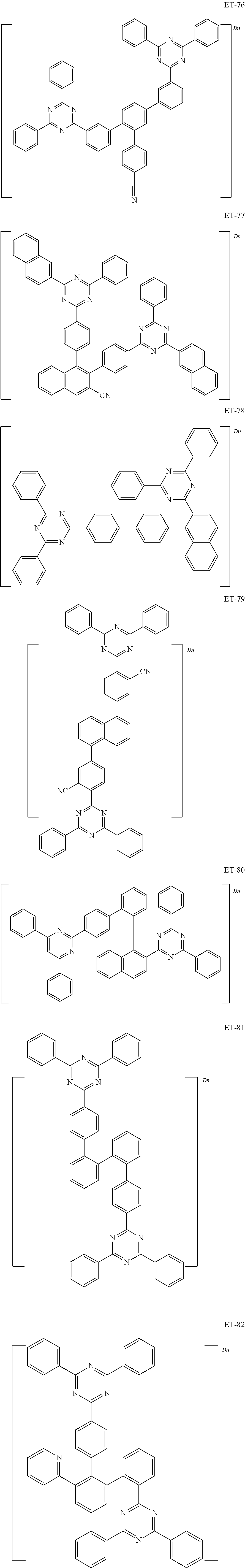

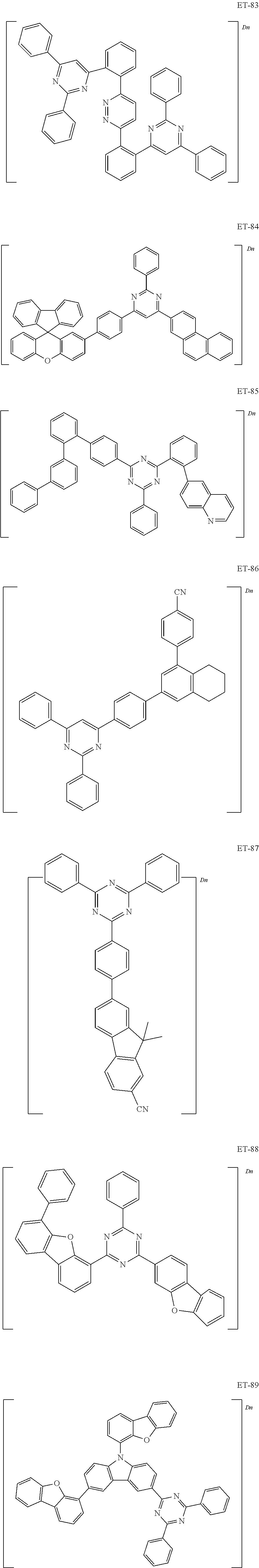

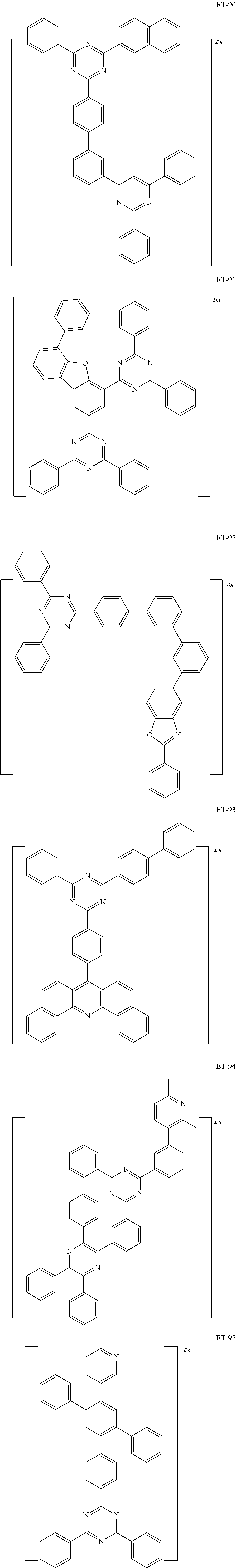

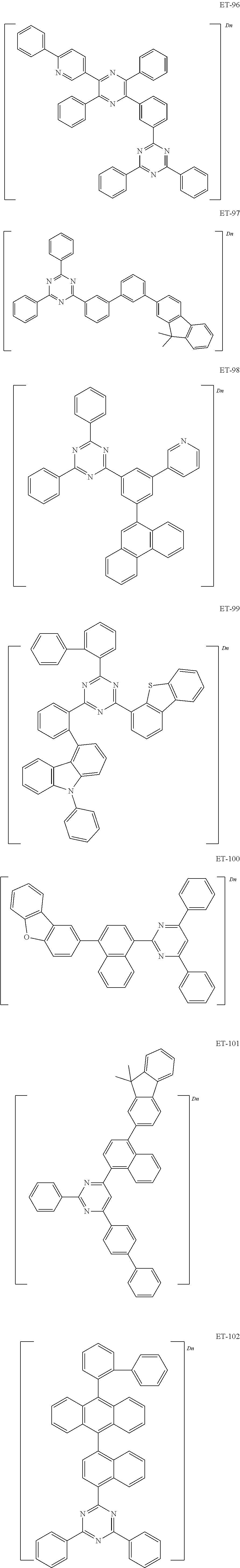

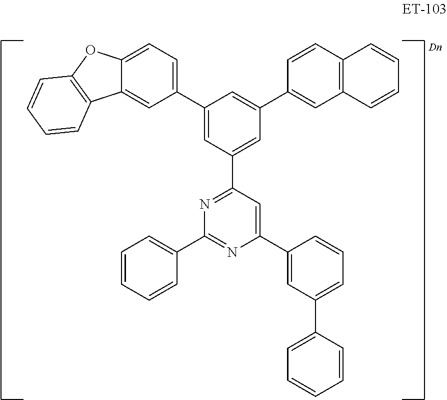

wherein Dₙ means that n number of hydrogens is replaced with deuterium, wherein n is an integer of 1 or more, and the upper limit of n is determined according to the number of hydrogens in the non-deuterated compound.

Hereinafter, an organic electroluminescent device including the aforementioned deuterated compound will be described.

Specifically, an organic electroluminescent device according to one embodiment may have a structure in which a first electrode; a hole transport zone disposed on the first electrode; at least one light-emitting layer disposed on the hole transport zone; an electron transport zone disposed on the light-emitting layer; and a second electrode disposed on the electron transport zone are sequentially stacked.

According to one embodiment, the first electrode may be an anode and the second electrode may be a cathode. Wherein, the first electrode and the second electrode may each be formed of a transparent conductive material or formed of a semi-transparent or reflective conductive material, respectively. The organic electroluminescent device may be a top emission type, a bottom emission type, or a both-sides emission type depending on the kinds of the material forming the first electrode and the second electrode.

The hole transport zone comprises a deuterated compound represented by Formula 1. Specifically, the hole transport zone may comprise at least one hole transport layer, preferably at least two hole transport layers, more preferably at least three hole transport layers. The at least one hole transport layer may comprise at least two compounds represented by Formula 1, and each of the compounds may be included in different hole transport layers.

The at least one light-emitting layer may comprise at least four deuterated compounds, preferably may comprises at least one deuterated compound, and at least three different host compounds and one dopant compound. The light-emitting layer may comprise a compound represented by Formula 4 or 5 as a first host compound, a compound represented by Formula 6 or 7 as a second host compound, and a compound represented by Formula 6 or 7 as a third host compound, respectively. Wherein, the first host compound of the plurality of host materials may be in an amount of about 5 to about 90 wt. %, preferably about 10 to about 90 wt. %, more preferably about 10 to about 80 wt. %, more preferably about 15 to about 70 wt. %, even more preferably about 30 to about 70 wt. %, even more preferably about 20 to about 60 wt. %, and even more preferably about 30 to about 60 wt. %. The second host compound of the plurality of host materials of the present disclosure may be in an amount of about 5 to about 90 wt. %, preferably about 10 to about 90 wt. %, more preferably about 10 to about 80 wt. %, more preferably about 15 to about 70 wt. %, even more preferably about 30 to about 70 wt. %, even more preferably about 20 to about 60 wt. %, and even more preferably about 30 to about 60 wt. %. The third host compound of the plurality of host materials of the present disclosure may be in an amount of about 5 to about 90 wt %, preferably about 10 to about 90 wt %, more preferably about 10 to about 80 wt %, more preferably about 15 to about 70 wt %, even more preferably about 30 to about 70 wt %, even more preferably about 20 to about 60 wt %, and even more preferably about 30 to about 60 wt %. For example, the plurality of host materials may comprise about 5 to about 70 wt % of the first host material, about 5 to about 70 wt % of the second host material, and about 10 to about 90 wt % of the third host material.

The electron transport zone comprises a deuterated compound represented by Formula 2 or 3. Specifically, the electron transport layer may comprise a compound represented by Formula 2 or 3.

The electron blocking layer is arranged in contact with the light-emitting layer to prevent electrons injected from the cathode from being transferred to the anode without being recombined in the light-emitting layer, thereby improving the efficiency of the organic electroluminescent device. In addition, it can prevent leakage of light by blocking the overflow of electrons from the light-emitting layer and confining excitons within the light-emitting layer.

The hole injection layer may be used in multiple layers for the purpose of lowering the hole injection barrier (or hole injection voltage) from the anode to the hole transport layer or electron blocking layer, and two compounds may be used simultaneously in each layer. In addition, the hole injection layer may be doped with a p-type dopant.

According to one embodiment, the hole transport layer may be used in multi-layers, and multiple compounds may be used in each layer.

The hole auxiliary layer is located between the hole transport layer and the electron blocking layer (or the light-emitting layer), and can exhibit the effect of facilitating or blocking the hole transport speed (or injection speed), thereby controlling the charge balance to effectively lower the driving voltage of the organic electroluminescent device. When the organic electroluminescent device comprises two or more hole transport layers, the additionally included hole transport layer can also be used as the hole auxiliary layer or the electron blocking layer.

The electron buffer layer may be multi-layers in order to control the injection of the electron and improve the interfacial properties between the light-emitting layer and the electron injection layer, wherein each of the multi-layers may use two compounds simultaneously.

The hole-blocking layer may be placed between the electron transport layer (or electron injection layer) and the light-emitting layer, and blocks the arrival of holes to the cathode, thereby improving the probability of recombination of electrons and holes in the light-emitting layer. The hole-blocking layer or the electron transport layer may also be multi-layers, wherein each layer may use a plurality of compounds. Also, the electron injection layer may be doped as an n-dopant.

The organic electroluminescent device of the present disclosure may further comprise the light-emitting auxiliary layer placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. The light-emitting auxiliary layer, the hole auxiliary layer, or the electron blocking layer may have an effect of improving the efficiency and/or the lifespan of the organic electroluminescent device.

The organic electroluminescent material according to one embodiment may be used as light-emitting materials for a white organic light-emitting device. The white organic light-emitting device has various suggested structures such as a parallel side-by-side arrangement method, a stacking arrangement method, or a CCM (color conversion material) method, etc., depending on the arrangement of R (red), G (green), YG (yellowish green), or B (blue) light-emitting units. In addition, the compound or the organic electroluminescent material according to one embodiment may also be applied to the organic electroluminescent device comprising a QD (quantum dot).

In the organic electroluminescent device of the present disclosure, preferably at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiO_{X}(1≤X≤2), AlO_{X}(1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

The organic electroluminescent device according to one embodiment of the present disclosure may be an organic electroluminescent device having a tandem structure. In the case of a tandem organic electroluminescent device according to one embodiment, a single light-emitting unit (light-emitting unit) may be formed in a structure in which two or more units are connected by a charge generation layer. The organic electroluminescent device may comprise a plurality of two or more light-emitting units, for example, a plurality of three or more light-emitting units, having first and second electrodes opposed to each other on a substrate and a light-emitting layer that is stacked between the first and second electrodes and emits light in a specific wavelength range. According to one embodiment, the organic electroluminescent device may comprise a plurality of light-emitting units, and each of the light-emitting units may comprise a hole transport zone, a light-emitting layer, and an electron transport zone, and the hole transport zone may comprise a hole injection layer and a hole transport layer, and the electron transport zone may comprise an electron transport layer and an electron injection layer. According to one embodiment, three or more light-emitting layers may be included in the light-emitting unit. A plurality of light-emitting units may emit the same color or different colors. Additionally, one light-emitting unit may comprise one or more light-emitting layers, and the plurality of light-emitting layers may be light-emitting layers of the same or different colors. This may comprise one or more charge generation layers located between each light-emitting unit. The charge generation layer refers to the layer in which holes and electrons are generated when voltage is applied. When there are three or more light-emitting units, a charge generation layer may be located between each light-emitting unit. Here, the plurality of charge generation layers may be the same as or different from each other. By disposing the charge generation layer between light-emitting units, current efficiency is increased in each light-emitting unit, and charges can be smoothly distributed. Specifically, the charge generation layer is provided between two adjacent stacks and can serve to drive a tandem organic electroluminescent device using only a pair of anode and cathode without a separate internal electrode located between the stacks.

The charge generation layer may be composed of an n-type charge generation layer and a p-type charge generation layer, and the n-type charge generation layer may be doped with an alkali metal, an alkaline earth metal, or a compound of an alkali metal and an alkaline earth metal. The alkali metal may comprise one selected from the group consisting of Li, Na, K, Rb, Cs, Fr, Yb, and combinations thereof, and the alkaline earth metal may comprise one selected from the group consisting of Be, Mg, Ca, Sr, Ba, Ra, and combinations thereof. The p-type charge generation layer may be made of a metal or an organic material doped with a p-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the p-type dopant and host materials used in the p-type doped organic material.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation; thus, it becomes easier to inject and transport holes from the mixed region to the electroluminescent medium. Preferably, the oxidative dopant comprises various Lewis acids and acceptor compounds, and the reductive dopant comprises alkali metals, alkali metal compounds, alkaline earth metals, rare earth metals, and mixtures thereof. Also, a reductive dopant layer may be employed as a charge generating layer to prepare an organic electroluminescent device having two or more light-emitting layers and emitting white light.

As the dopant included in the light-emitting layer, at least one phosphorescent or fluorescent light-emitting compound may be used as a dopant, and the light-emitting compound may comprise iridium (Ir), platinum (Pt), or boron (B) atoms. For example, as the dopant included in the light-emitting layer, a phosphorescent dopant may be used. The phosphorescent dopant material applied to the organic electroluminescent device of the present disclosure is not particularly limited, but may preferably be a metallated complex compound(s) of a metal atom(s) selected from iridium (Ir), osmium (Os), copper (Cu), and platinum (Pt), more preferably an ortho-metallated complex compound(s) of a metal atom(s) selected from iridium (Ir), osmium (Os), copper (Cu), and platinum (Pt), and even more preferably ortho-metallated iridium complex compound(s).

The organic electroluminescent device of the present disclosure can be manufactured by forming a first electrode or a second electrode on a substrate, and then forming an organic layer using any one of a dry deposition method such as vacuum deposition, sputtering, plasma, or ion plating, or a wet deposition method such as ink jet printing, nozzle printing, slot coating, spin coating, dip coating, or flow coating, and then forming a second electrode or a first electrode thereon. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a layer by the organic electroluminescent material according to one embodiment, the layer can be formed by the above-listed methods, and can often be formed by co-deposition or mixture-deposition. The co-deposition is a mixed deposition method in which two or more materials are put into respective individual crucible sources, and a current is applied to both cells simultaneously to evaporate the materials; and the mixture-deposition is a mixed deposition method in which two or more materials are mixed in one crucible source before deposition, and then a current is applied to one cell to evaporate the materials.

According to one embodiment, the present disclosure can provide a display device comprising a deuterated compound as an organic electroluminescent material. In addition, the organic electroluminescent device of the present disclosure can be used for the manufacture of display devices such as smartphones, tablets, notebooks, PCs, TVs, or display devices for vehicles, or lighting devices such as outdoor or indoor lighting.

Hereinafter, for a detailed understanding of the present disclosure, the preparation method of the compound according to the present disclosure will be explained with reference to the synthesis methods of the representative compounds or intermediate compounds of the present disclosure.

### [Example 1] Preparation of Compound HT-47

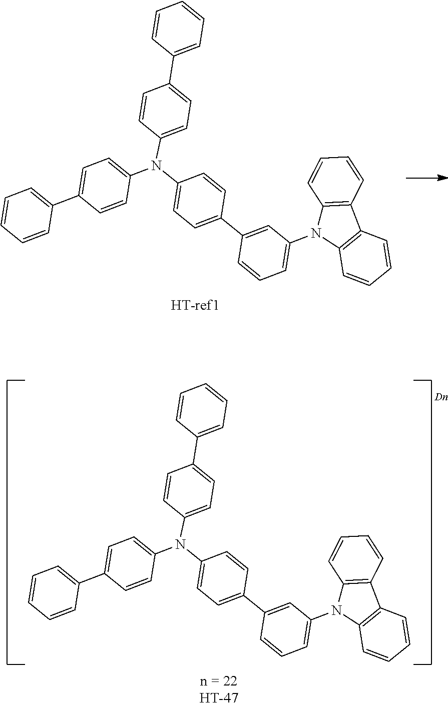

Compound HT-refl was synthesized by selecting the deuterium methods disclosed in Korean Patent Nos. 10-2283849, 10-1427457, etc., and compound HT-47 (17 g, yield: 65%) was obtained.

| | MW | M.P. |
|---|---|---|
| HT-47 | 660 | 200° C. |

### [Example 2] Preparation of Compound H1-55

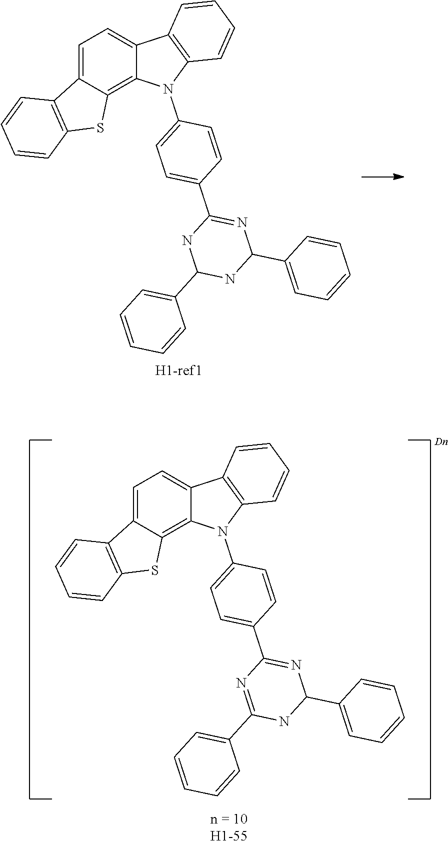

Compound H1-ref1 was synthesized by selecting the deuterium methods disclosed in Korean Patent Nos. 10-2283849, 10-1427457, etc., and compound H1-55 (53 g, yield: 84%) was obtained.

| | MW | M.P. |
|---|---|---|
| H1-55 | 590 | 335° C. |

### [Example 3] Preparation of Compound H2-35

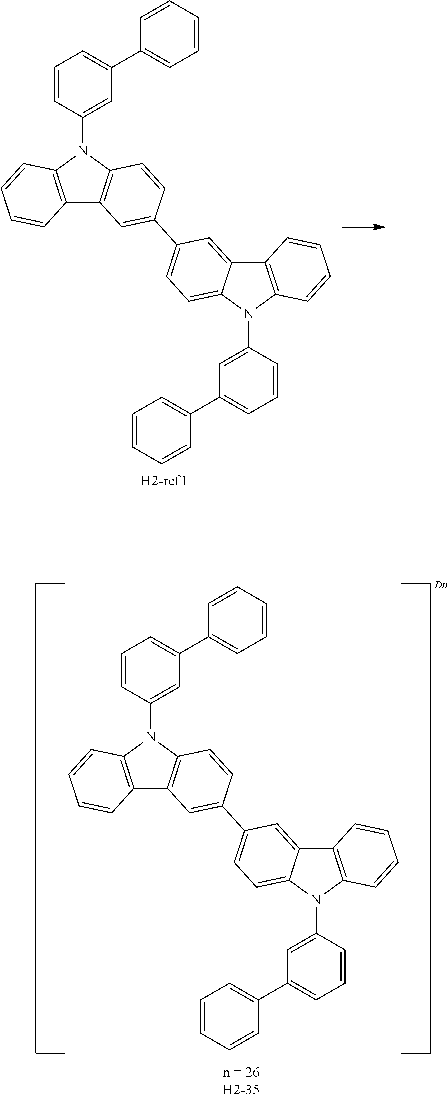

Compound H2-refl was synthesized by selecting the deuterium methods disclosed in Korean Patent Nos. 10-2283849, 10-1427457, etc., and compound H2-35 (66 g, yield: 91%) was obtained.

| | MW | M.P. |
|---|---|---|
| H2-35 | 662 | 200° C. |

### [Example 4] Preparation of Compound ET-60

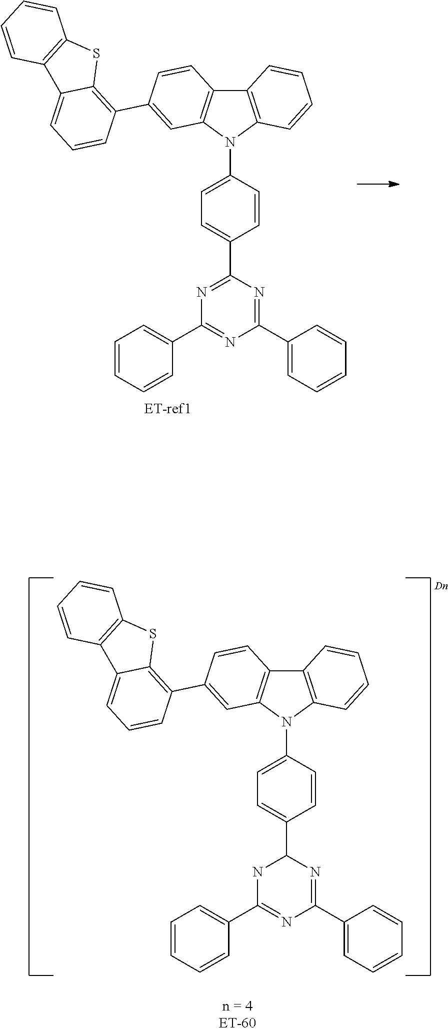

Compound ET-ref1 was synthesized by selecting the deuterium methods disclosed in Korean Patent Nos. 10-2283849, 10-1427457, etc., and compound ET-60 (12 g, yield: 87%) was obtained.

| | MW | M.P. |
|---|---|---|
| ET-60 | 660 | 281° C. |

### [Example 5] Preparation of Compound HT-39

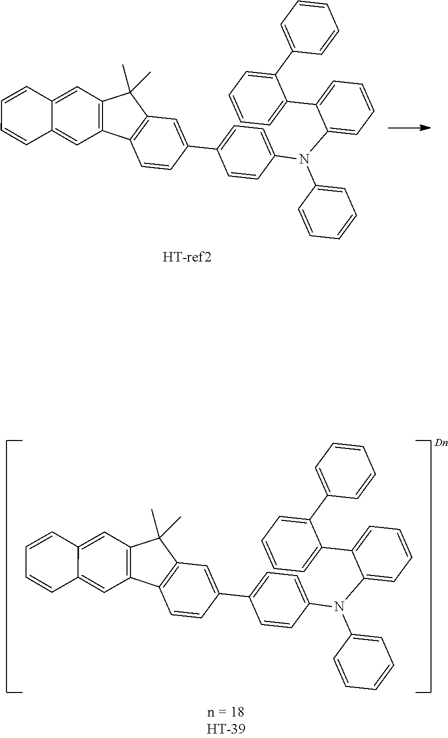

Compound HT-ref2 was synthesized by selecting the deuterium methods disclosed in Korean Patent Nos. 10-2283849, 10-1427457, etc., and compound HT-39 (7.6 g, yield: 63%) was obtained.

| | MW | M.P. |
|---|---|---|
| HT-39 | 657 | 221° C. |

### [Example 6] Preparation of Compound H2-61

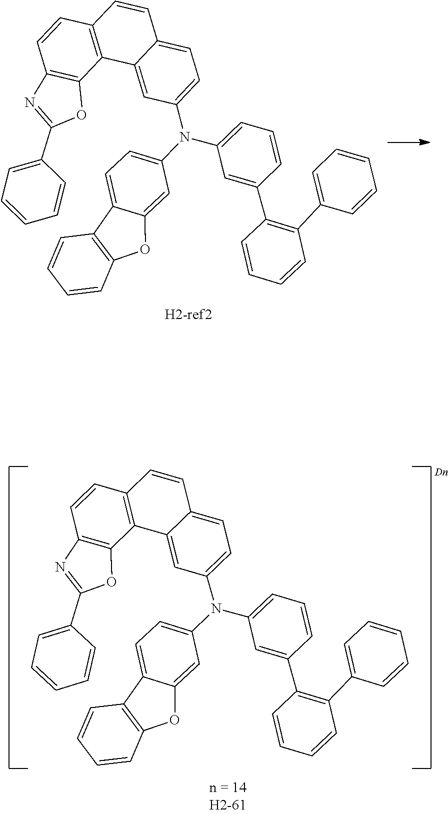

Compound H2-ref2 was synthesized by selecting the deuterium methods disclosed in Korean Patent Nos. 10-2283849, 10-1427457, etc., and compound H2-61 (8.1 g, yield: 75%) was obtained.

| | MW | M.P. |
|---|---|---|
| H2-61 | 718 | 244° C. |

### [Example 7] Preparation of Compound H1-15

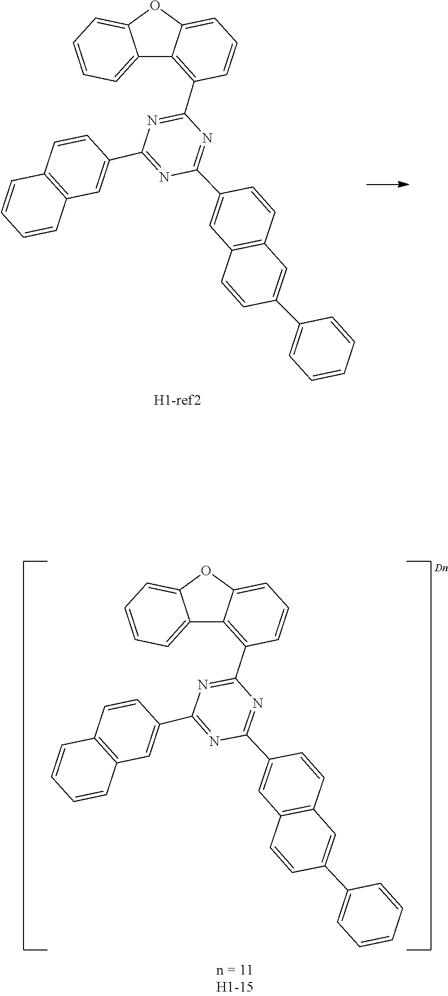

Compound H2-ref2 was synthesized by selecting the deuterium methods disclosed in Korean Patent Nos. 10-2283849, 10-1427457, etc., and compound H1-15 (32 g, yield: 84%) was obtained.

| | MW | M.P. |
|---|---|---|
| H1-15 | 586 | 242° C. |

### [Example 8] Preparation of Compound ET-1

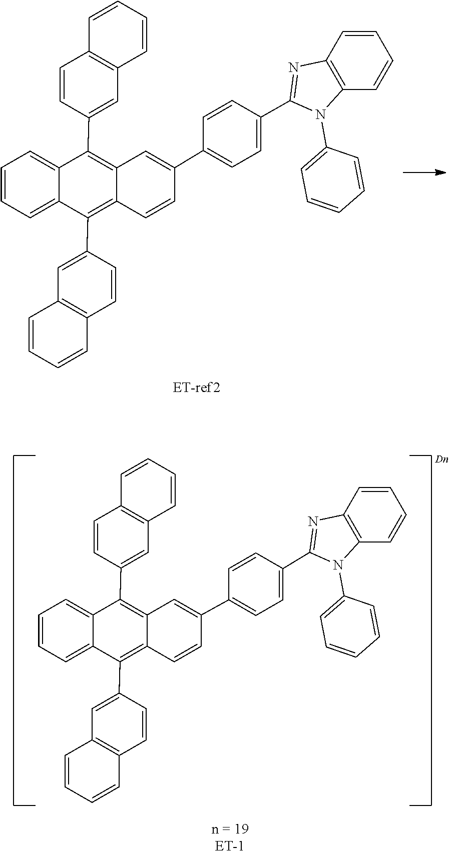

Compound ET-ref2 was synthesized by selecting the deuterium methods disclosed in Korean Patent Nos. 10-2283849, 10-1427457, etc., and compound ET-1 (5 g, yield: 88%) was obtained.

| | MW | M.P. |
|---|---|---|
| ET-1 | 717 | 360° C. |

### [Example 9] Preparation of Compound H3-7

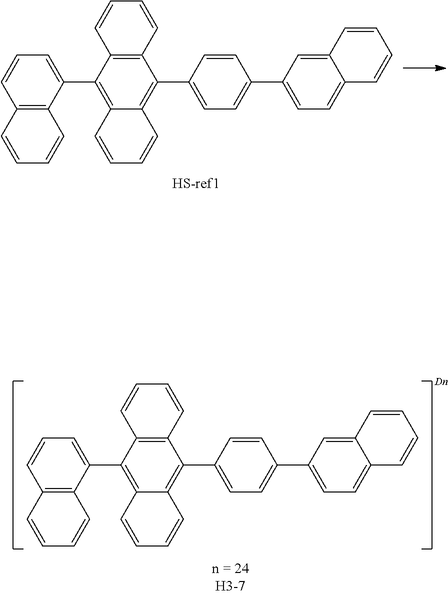

Compound H3-ref1 was synthesized by selecting the deuterium methods disclosed in Korean Patent Nos. 10-2283849, 10-1427457, etc., and compound H3-7 (12 g, yield: 77%) was obtained.

| | MW | M.P. |
|---|---|---|
| H3-7 | 530 | 275° C. |

### [Example 10] Preparation of Compound H3-20

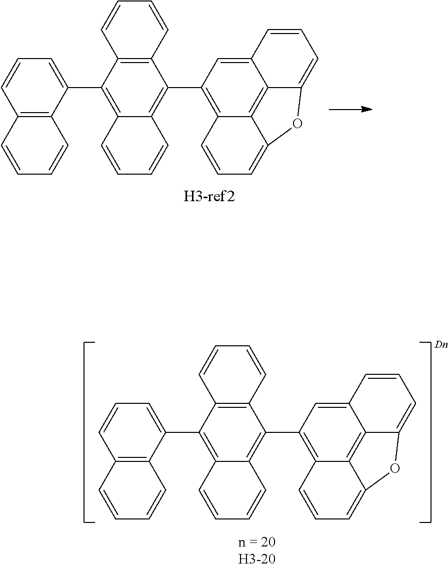

Compound H3-ref2 was synthesized by selecting the deuterium methods disclosed in Korean Patent Nos. 10-2283849, 10-1427457, etc., and compound H3-20 (14 g, yield: 79%) was obtained.

| | MW | M.P. |
|---|---|---|
| H3-20 | 514 | 330° C. |

### [Example 11] Preparation of Compound HT-13

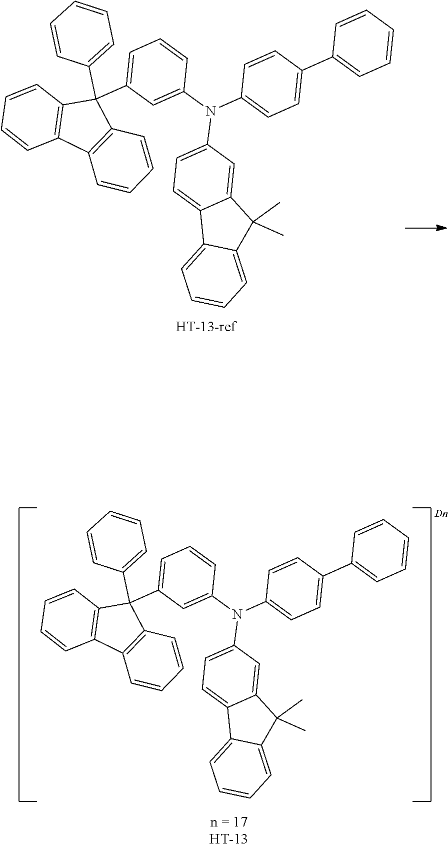

Compound HT-13-ref was synthesized by selecting the deuterium methods disclosed in Korean Patent Nos. 10-2283849, 10-1427457, etc., and compound HT-13 (9.9 g, yield: 94%) was obtained.

| | MW |
|---|---|
| HT-13 | 694 |

### [Example 12] Preparation of Compound H2-2

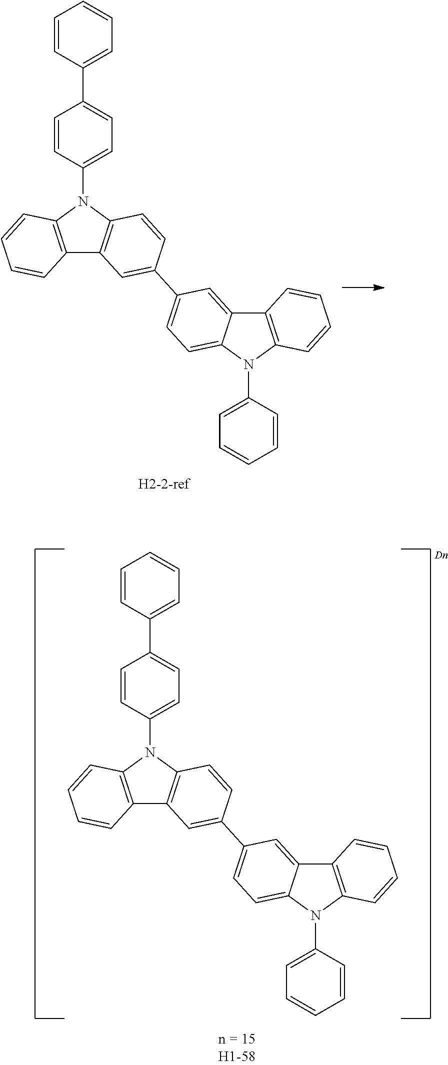

Compound H2-2-ref was synthesized by selecting the deuterium methods disclosed in Korean Patent Nos. 10-2283849, 10-1427457, etc., and compound H2-2 (79 g, yield: 93%) was obtained.

| | MW |
|---|---|
| H2-2 | 581 |

### [Example 13] Preparation of Compound H1-58

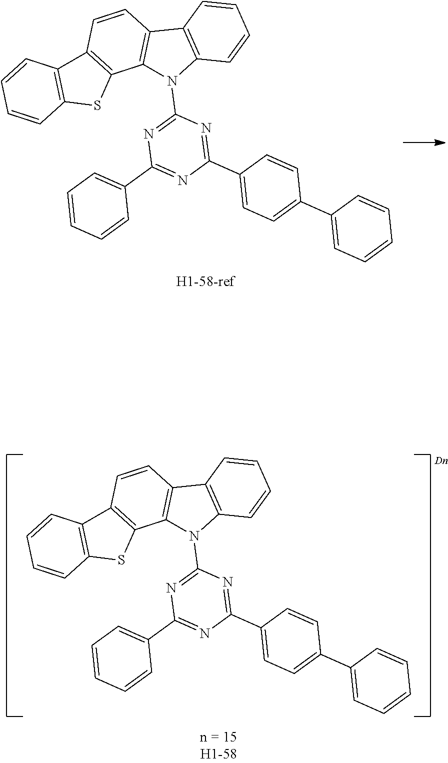

Compound H1-58-ref was synthesized by selecting the deuterium methods disclosed in Korean Patent Nos. 10-2283849, 10-1427457, etc., and compound H1-58 (18 g, yield: 90%) was obtained.

| | MW |
|---|---|
| H1-58 | 595 |

### [Example 14] Preparation of Compound HT-33

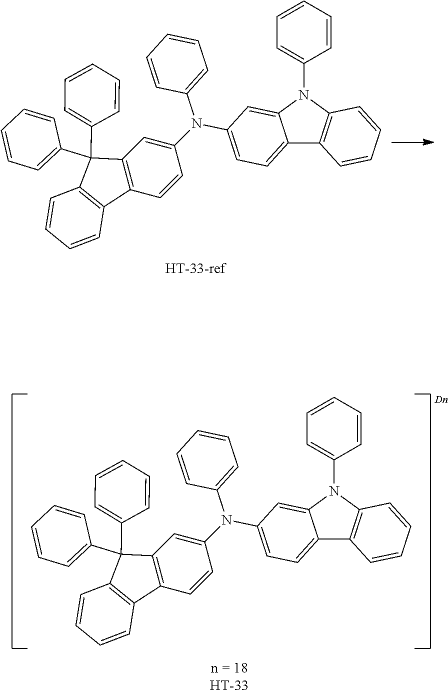

Compound HT-33-ref was synthesized by selecting the deuterium methods disclosed in Korean Patent Nos. 10-2283849, 10-1427457, etc., and compound HT-33 (16 g, yield: 86%) was obtained.

| | MW |
|---|---|
| HT-33 | 668 |

### [Example 15] Preparation of Compound H2-62

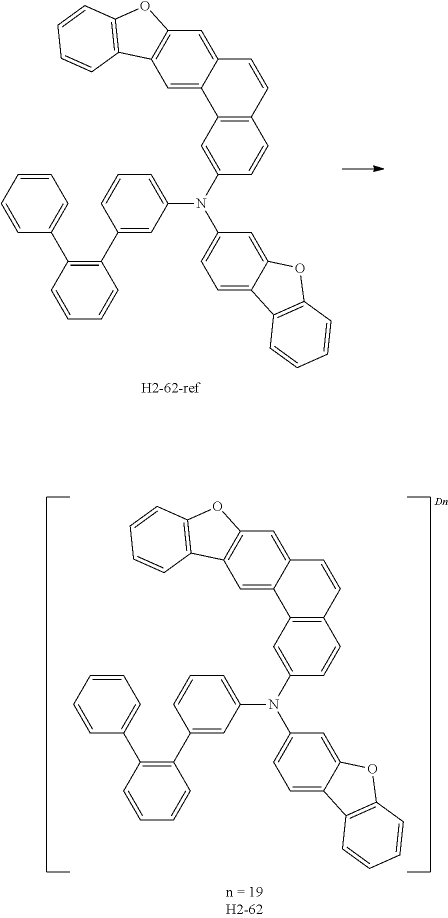

Compound H2-62-ref was synthesized by selecting the deuterium methods disclosed in Korean Patent Nos. 10-2283849, 10-1427457, etc., and compound H2-62 (56 g, yield: 92%) was obtained.

| | MW |
|---|---|
| H2-62 | 696 |

### [Example 16] Preparation of Compound ET-66

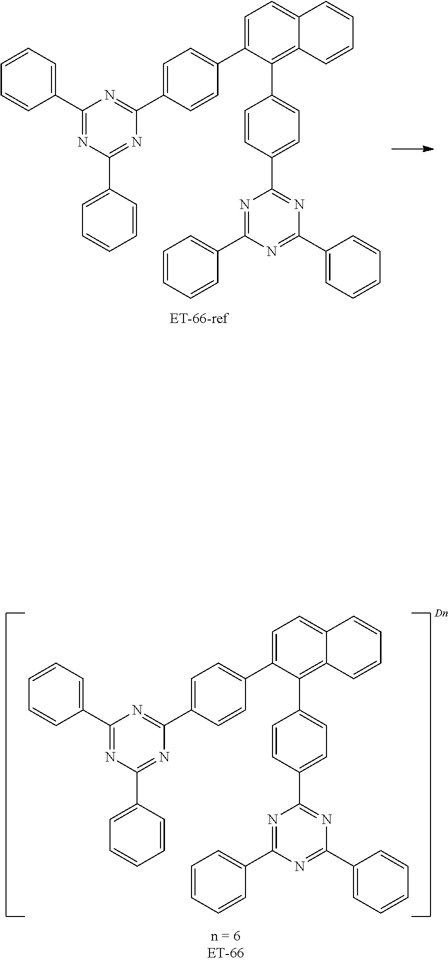

Compound ET-66-ref was synthesized by selecting the deuterium methods disclosed in Korean Patent Nos. 10-2283849, 10-1427457, etc. and compound ET-66 (5 g, yield: 68%) was obtained.

| | MW |
|---|---|
| ET-66 | 748 |

Hereinafter, for a detailed understanding of the present disclosure, the preparation method of an organic electroluminescent device comprising the deuterated compound according to the present disclosure and the organic electroluminescent material comprising the same and the device properties thereof will be explained.

### [Device Examples 1 to 3] Preparation of Green OLEDs Comprising a Deuterated Compound According to the Present Disclosure

OLEDs according to the present disclosure were produced. A transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropyl alcohol. The ITO substrate was then mounted on a substrate holder of a vacuum vapor deposition apparatus. Compound HI-1 was introduced into a cell of the vacuum vapor deposition apparatus, and compound HTL-1 was introduced into another cell of the vacuum vapor deposition apparatus. The two materials were evaporated at different rates, and compound HI-1 was deposited in a doping amount of 3 wt % based on the total amount of compound HI-1 and compound HTL-1 to form a hole injection layer having a thickness of 10 nm on the ITO substrate. Next, compound HTL-1 was deposited on the hole injection layer to form a first hole transport layer having a thickness of 80 nm. The compound shown in Table 1 below was then introduced into another cell of the vacuum vapor deposition apparatus and was evaporated by applying an electric current to the cell, thereby forming a second hole transport layer having a thickness of 25 nm on the first hole transport layer. Compound HTL-3 was then introduced into another cell of the vacuum vapor deposition apparatus and was evaporated by applying an electric current to the cell, thereby forming a third hole transport layer having a thickness of 5 nm on the second hole transport layer. After forming the hole injection layer and the hole transport layers, a light-emitting layer was formed thereon as follows: The first host compound, the second host compound, and and the third host compound shown in Table 1 below were introduced into three cells of the vacuum vapor deposition apparatus as hosts, and compound GD was introduced into another cell as a dopant. The three host materials were evaporated at a rate of 2:0.5:0.5 (the first host: the second host; the third host) and the dopant material was simultaneously evaporated at a different rate, and the dopant was deposited in a doping amount of 10 wt % based on the total amount of the hosts and the dopant to form a light-emitting layer having a thickness of 40 nm on the third hole transport layer. Thereafter, compound HBL-1 was evaporated to deposit a hole blocking layer having a thickness of 5 nm on the light-emitting layer. Thereafter, the compound shown in the following Table 1 and compound EIL-1 were evaporated in a weight ratio of 50:50 as electron transport layer materials to deposit an electron transport layer having a thickness of 30 nm. After depositing compound EIL-1 as an electron injection layer having a thickness of 2 nm on the electron transport layer, an Al cathode having a thickness of 80 nm was deposited on the electron injection layer by another vacuum vapor deposition apparatus. Thus, an OLED was produced. All the materials used for producing the OLED were purified by vacuum sublimation at 10⁻⁶ torr.

### [Comparative Example 1] Preparation of of a Green OLED Including a Comparative Compound

An OLED was fabricated in the same manner as Device Example 1, except that the protium materials described in Table 1 below were used as the second hole transport layer, the host material of the light-emitting layer, and the electron transport layer.

The driving voltage, the luminous efficiency, the luminous color at a luminance of 1,000 nit, and the time taken for luminance to decrease from 100% to 95% at a luminance of 20,000 nit (lifespan: T₉₅) of the OLEDs of Device Examples 1 to 3 and Comparative Example 1 prepared as described above were measured, and the results thereof are shown in Table 1 below.

TABLE 1

| | Second | | | | | | | | |
|---|---|---|---|---|---|---|---|---|---|
| | Hole | | | | Electron | Driving | Luminous | | |
| | Transport | First | Second | Third | Transport | Voltage | Efficiency | Luminous | Lifespan |
| | Layer | Host | Host | Host | Layer | (V) | (cd/A) | Color | (T95, hr) |
| Device | HT-13 | H2-2 | H1-57- | H1-58 | ET-66-ref | 3.1 | 105.5 | Green | 360.8 |
| Example 1 | | | ref | | | | | | |
| Device | HT-13-ref | H2-2 | H1-57- | H1-58 | ET-66 | 3.1 | 105.9 | Green | 399.4 |
| Example 2 | | | ref | | | | | | |
| Device | HT-13 | H2-2 | H1-57- | H1-58 | ET-66 | 3.1 | 105.6 | Green | 427.2 |
| Example 3 | | | ref | | | | | | |
| Comparative | HT-13-ref | H2-2- | H1-57- | H1-58- | ET-66-ref | 3.2 | 106.3 | Green | 262.5 |
| Example 1 | | ref | ref | ref | | | | | |

From Table 1 above, it can be confirmed that the organic electroluminescent device including the deuterated compound according to the present disclosure in at least one of the hole transport zone, the light-emitting layer, and the electron transport zone exhibits significantly improved long lifespan characteristics compared to the conventional organic electroluminescent device.

The compounds used in the Device Examples and the Comparative Example are specifically shown in Table 2 below.

TABLE 2

| | |
|---|---|
| Hole Injection Layer/Hole Transport Layer | 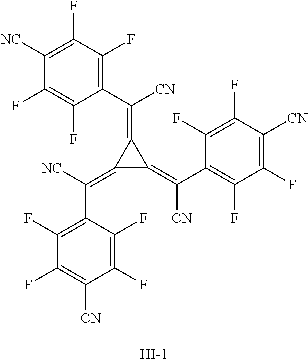 |
| | 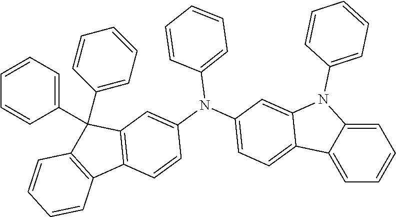 HTL-1 |
| | 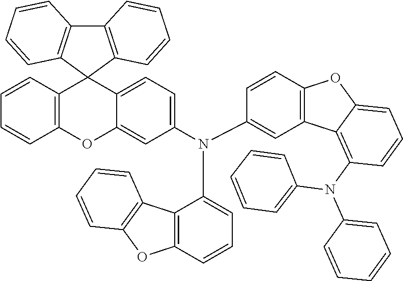 HTL-3 |
| | 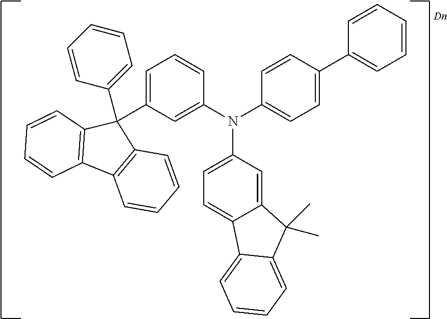 n = 17 HT-13 |
| | 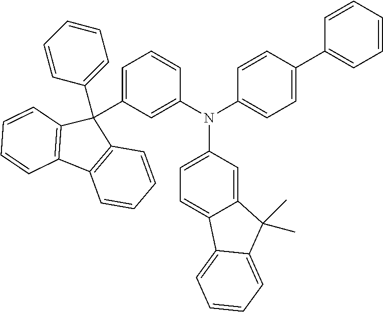 HT-13-ref |
| Light- Emitting Layer | 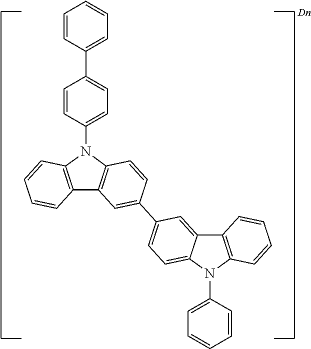 n = 21 H2-2 |
| | 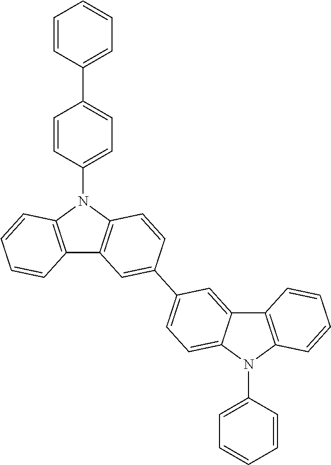 H2-2-ref |
| | 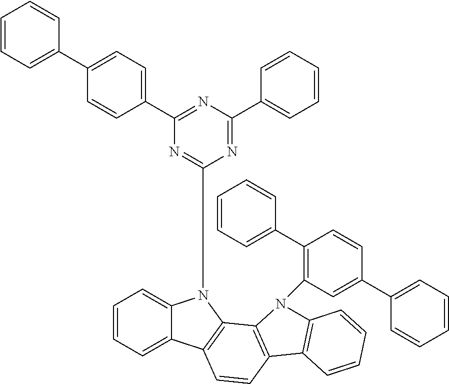 H1-57-ref |
| | 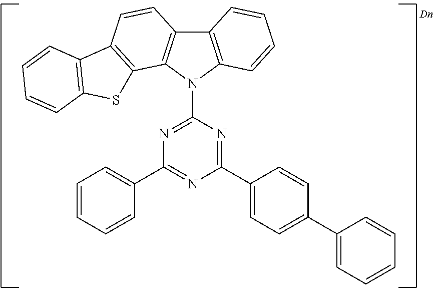 n = 15 H1-58 |
| | 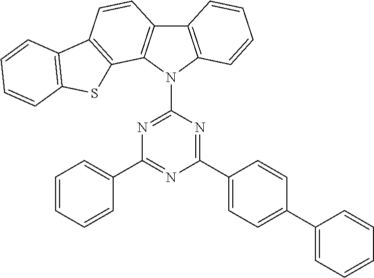 H1-58-ref |
| | 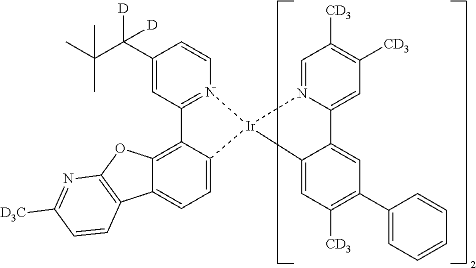 GD |
| Hole Blocking Layer | 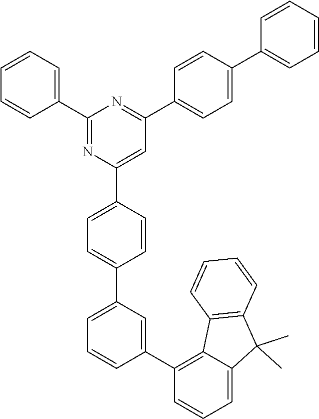 HBL-1 |
| Electron Transport Layer/ Electron Injection Layer | 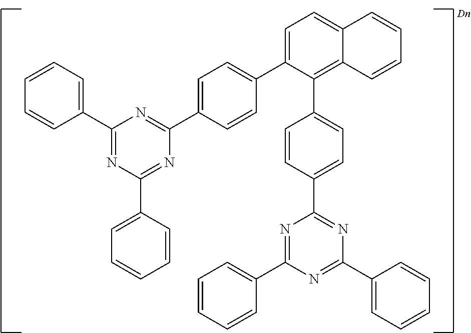 n = 6 ET-66 |
| | 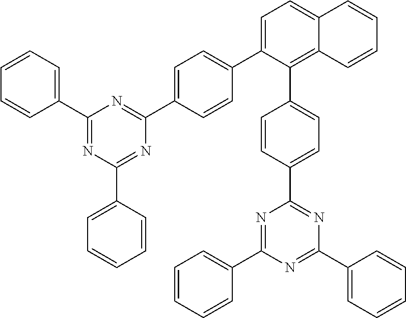 ET-66-ref |
| | 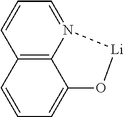 EIL-1 |

### [Device Examples 4 and 5] Preparation of Red OLEDs Comprising a Deuterated Compound According to the Present Disclosure

OLEDs according to the present disclosure were produced. A transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropyl alcohol. The ITO substrate was then mounted on a substrate holder of a vacuum vapor deposition apparatus. Compound HI-1 was introduced into a cell of the vacuum vapor deposition apparatus, and compound HTL-1 was introduced into another cell of the vacuum vapor deposition apparatus. The two materials were evaporated at different rates, and compound HI-1 was deposited in a doping amount of 3 wt % based on the total amount of compound HI-1 and compound HTL-1 to form a first hole injection layer having a thickness of 10 nm on the ITO substrate. Next, compound HTL-1 was deposited on the first hole injection layer to form a first hole transport layer having a thickness of 80 nm. Compound HTL-2 was then introduced into another cell of the vacuum vapor deposition apparatus and was evaporated by applying an electric current to the cell, thereby forming a second hole transport layer having a thickness of 55 nm on the first hole transport layer. The compound shown in the following Table 3 was then introduced into another cell of the vacuum vapor deposition apparatus and was evaporated by applying an electric current to the cell, thereby forming an electron blocking layer having a thickness of 5 nm on the second hole transport layer. After forming the hole injection layer, the hole transport layers and the electron blocking layer, a light-emitting layer was formed thereon as follows: The first host compound, the second host compound, and and the third host compound shown in Table 3 below were introduced into three cells of the vacuum vapor deposition apparatus as hosts, and compound RD-1 was introduced into another cell as a dopant. The three host materials were evaporated at a rate of 0.25:0.25:0.5 (the first host: the second host; the third host) and the dopant material was simultaneously evaporated at a different rate, and the dopant was deposited in a doping amount of 3 wt % based on the total amount of the hosts and the dopant to form a light-emitting layer having a thickness of 40 nm on the electron blocking layer. Thereafter, compound HB-1 was evaporated to deposit a hole blocking layer having a thickness of 5 nm on the light-emitting layer. Thereafter, the compound shown in the following Table 3 and compound EIL-1 were evaporated in a weight ratio of 50:50 as electron transport layer materials to deposit an electron transport layer having a thickness of 30 nm. After depositing compound EIL-1 as an electron injection layer having a thickness of 2 nm on the electron transport layer, an Al cathode having a thickness of 80 nm was deposited on the electron injection layer by another vacuum vapor deposition apparatus. Thus, an OLED was produced. All the materials used for producing the OLED were purified by vacuum sublimation at 10⁻⁶ torr.

### [Comparative Example 2] Preparation of of an OLED Including a Comparative Compound

An OLED was fabricated in the same manner as Device Example 3, except that the compounds described in Table 3 below were used as the electron blocking layer material, the host material of the light-emitting layer, and the electron transport layer material.

The luminous color, and the time taken for luminance to decrease from 100% to 95% at a luminance of 10,000 nit (lifespan: T₉₅) of the OLEDs produced in Device Examples 4 and 5 and Comparative Example 2 were measured, and the results thereof are shown in Table 1 below.

TABLE 3

| | Electron | | | | Electron | | |
|---|---|---|---|---|---|---|---|
| | Blocking | First | Second | Third | Transport | Luminous | Lifespan |
| | Layer | Host | Host | Host | Layer | Color | T95(hr) |
| Device | HT-47 | H2-61 | H2-62 | H1-15 | ET-66-ref | Red | 401 |
| Example 4 | | | | | | | |
| Device | HT-ref1 | H2-61 | H2-62 | H1-15 | ET-66 | Red | 412 |
| Example 5 | | | | | | | |
| Comparative | HT-ref1 | H2-ref2 | H2-62-ref | H1-ref2 | ET-66-ref | Red | 294 |
| Example 2 | | | | | | | |

From Table 3 above, it can be confirmed that the organic electroluminescent device including the deuterated compound according to the present disclosure in at least one of the hole transport zone, the light-emitting layer, and the electron transport zone exhibits significantly improved long lifespan characteristics compared to the conventional organic electroluminescent device.

The compounds used in the Device Examples and the Comparative Example are specifically shown in Table 4 below.

TABLE 4

| | |
|---|---|
| Hole Injection Layer/Hole Transport Layer/ Electron Blocking Layer | 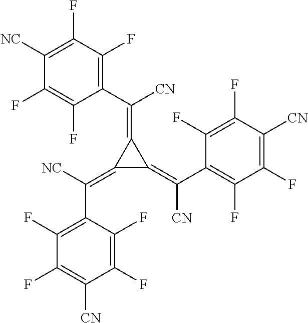 HI-1 |
| | 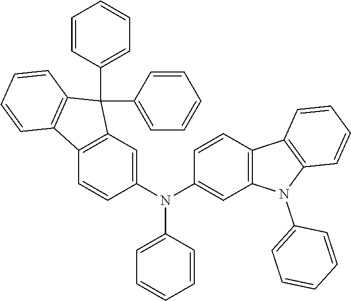 HTL-1 |
| | 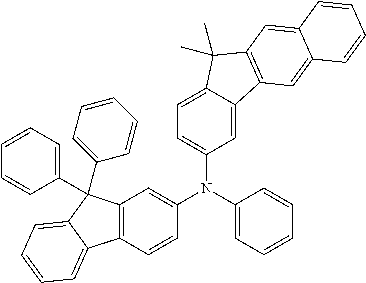 HTL-2 |
| | 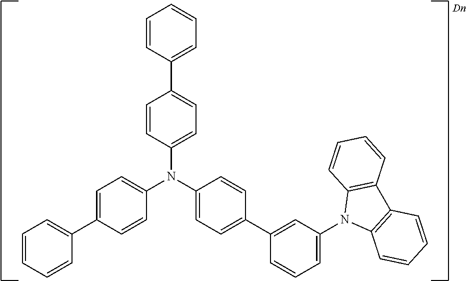 n = 22 HT-47 |
| | 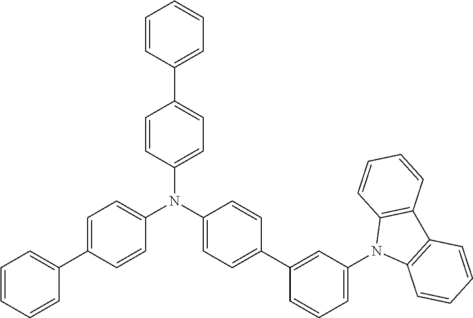 HT-ref1 |
| Light- Emitting Layer | 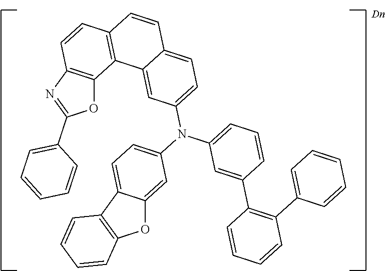 n = 14 H2-61 |
| | 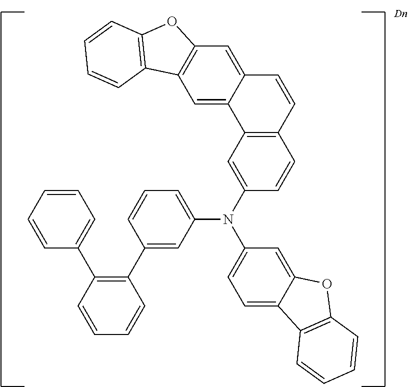 n = 19 H2-62 |
| | 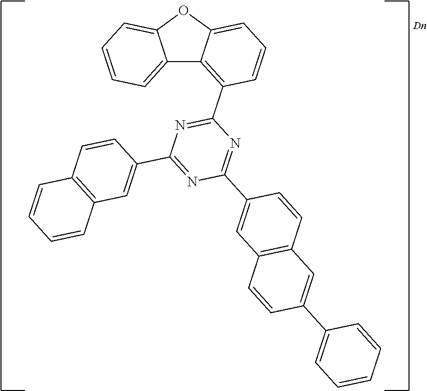 n = 11 H1-15 |
| | 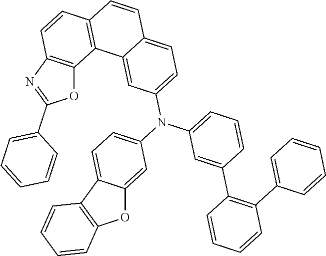 H2-ref2 |
| | 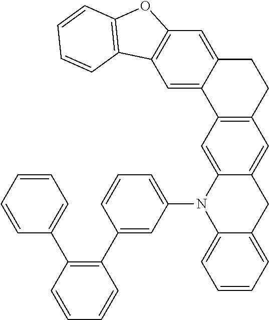 H2-62-ref |
| | 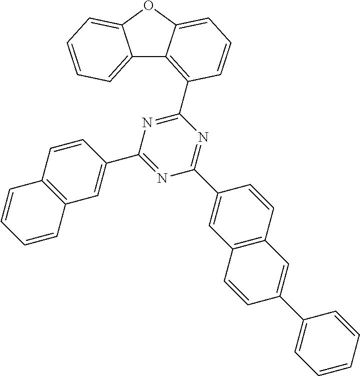 H1-ref2 |
| | 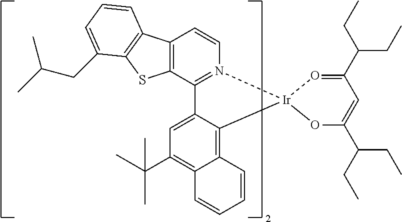 RD-1 |
| Hole Blocking Layer/ Electron Transport Layer/ Electron Injection Layer | 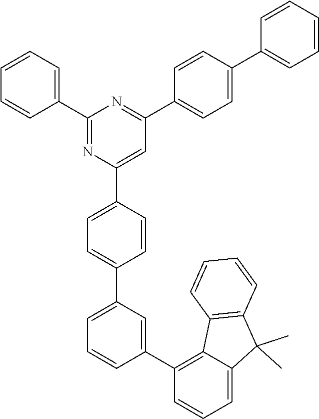 HB-1 |
| | 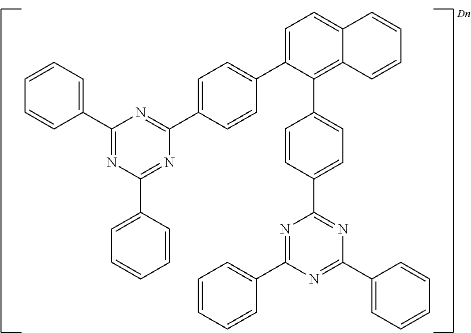 n = 6 ET-66 |
| | 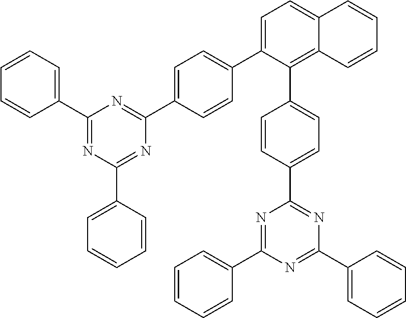 ET-66-ref |
| | 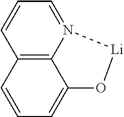 EIL-1 |

1. An organic electroluminescent device comprising a first electrode; a second electrode;
and a hole transport zone, at least one light-emitting layer, and an electron transport zone positioned between the first electrode and the second electrode,
wherein the light-emitting layer comprises at least one deuterated compound and at least four different compounds, and
at least one zone of the hole transport zone and the electron transport zone comprises at least one deuterated compound.

2. The organic electroluminescent device according to claim 1, wherein the hole transport zone is positioned on the first electrode and is configured by sequentially stacking a hole injection layer, at least one hole transport layer, and at least one layer of a hole auxiliary layer and an electron blocking layer, and wherein at least one layer of the hole injection layer, the hole transport layer, the hole auxiliary layer, and the electron blocking layer comprises a deuterated compound.

3. The organic electroluminescent device according to claim 1, wherein the electron transport zone is positioned on the light-emitting layer and is configured by sequentially stacking at least one layer of an electron buffer layer and a hole blocking layer, at least one electron transport layer, and an electron injection layer, and at least one layer of the electron buffer layer, the hole blocking layer, the electron transport layer, and the electron injection layer comprises a deuterated compound.

4. The organic electroluminescent device according to claim 1, wherein the light-emitting layer comprises at least one deuterated compound and at least three different host compounds and one dopant compound.

5. The organic electroluminescent device according to claim 1, wherein the light-emitting layer comprises at least one deuterated compound and comprises at least two different host compounds and at least two different dopant compounds.

6. The organic electroluminescent device according to claim 1, wherein at least one of the at least four compounds included in the light-emitting layer is a phosphorescent or fluorescent light-emitting compound, and the light-emitting compound contains iridium (Ir), platinum (Pt), or boron (B) atoms.

7. The organic electroluminescent device according to claim 1, wherein the hole transfer zone comprises a compound represented by the following Formula 1. 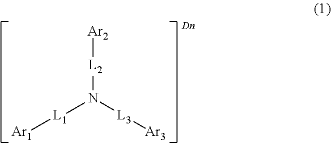
wherein,
L₁ to L₃ each independently represent a single bond, a substituted or unsubstituted (C6-C30)arylene, or a substituted or unsubstituted (3- to 30-membered)heteroarylene;
Ar₁ to Ar₃ each independently represent hydrogen, deuterium, a halogen, a cyano, a substituted or unsubstituted (C1-C30)alkyl, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted (C6-C30)aryl, a substituted or unsubstituted (3- to 30-membered)heteroaryl, a substituted or unsubstituted mono- or di-(C6-C30)arylamino, a substituted or unsubstituted mono- or di-(C1-C30)alkylamino, a substituted or unsubstituted mono- or di-(C2-C30)alkenylamino, a substituted or unsubstituted (C1-C30)alkyl(C6-C30)arylamino, a substituted or unsubstituted mono- or di-(3- to 30-membered)heteroarylamino, or a substituted or unsubstituted (C6-C30)aryl(3- to 30-membered)heteroarylamino;
provided that at least one of Ar₁ to Ar₃ comprises deuterium and is a substituted or unsubstituted (C6-C30)aryl or a substituted or unsubstituted (3- to 30-membered)heteroaryl; and
Dₙ means that n number of hydrogens is replaced with deuterium, wherein n is an integer of 1 or more, and the upper limit of n is determined according to the number of hydrogens in the non-deuterated compound.

8. The organic electroluminescent device according to claim 7, wherein at least one of Ar₁ to Ar₃ is, a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenyleneyl, a substituted or unsubstituted dibenzofuranyl, or a substituted or unsubstituted dibenzothiophenyl.

9. The organic electroluminescent device according to claim 1, wherein the electron transfer zone comprises a compound represented by the following Formula 2 or 3: 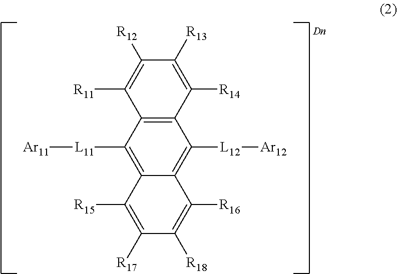
wherein
L₁₁ and L₁₂ each independently represent a single bond, a substituted or unsubstituted (C6-C30)arylene, or a substituted or unsubstituted (3- to 30-membered)heteroarylene;
Ar₁₁ and Ar₁₂ each independently represent a substituted or unsubstituted (C6-C30)aryl or a substituted or unsubstituted (3- to 30-membered)heteroaryl;
R₁₁ to R₁₈ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino;
provided that at least one of R₁₁ and R₁₄ to R₁₆ is deuterium; and
Dₙ means that n number of hydrogens is replaced with deuterium, wherein n is an integer of 1 or more, and the upper limit of n is determined according to the number of hydrogens in the non-deuterated compound; 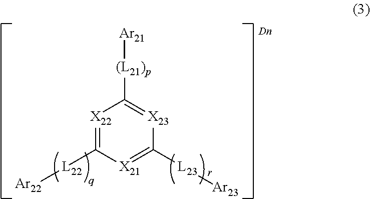
wherein,
X₂₁ to X₂₃ each independently represent CR′ or N; provided that at least two of X₂₁ to X₂₃ are N;
R′ represents hydrogen or deuterium;
L₂₁ to L₂₃ each independently represent a single bond, a substituted or unsubstituted (C6-C30)arylene, or a substituted or unsubstituted (3- to 30-membered)heteroarylene;
Ar₂₁ to Ar₂₃ each independently represent a substituted or unsubstituted (C6-C30)aryl or a substituted or unsubstituted (3- to 30-membered)heteroaryl; provided that at least one of Ar₂₁ to Ar₂₃ comprises deuterium;
p, q, and r each independently represent an integer of 1 to 3, when p, q, and r are an integer of 2 or more, each of L₂₁ to each of L₂₃ may be the same as or different from each other; and
Dₙ means that n number of hydrogens is replaced with deuterium, wherein n is an integer of 1 or more, and the upper limit of n is determined according to the number of hydrogens in the non-deuterated compound.

10. The organic electroluminescent device according to claim 9, wherein at least one of Ar₁₁ and Ar₁₂ is represented by the following Formula 2-1 or 2-2. 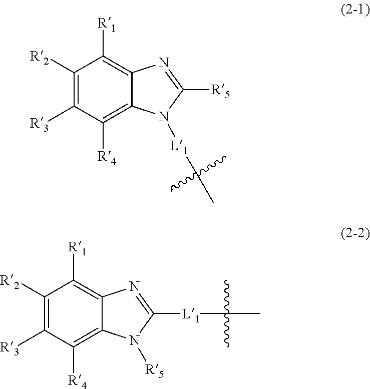
wherein,
L′₁ represents a single bond, a substituted or unsubstituted (C6-C30)arylene, or a substituted or unsubstituted (3- to 30-membered)heteroarylene;
R′₁ to R′₅ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; and [symbol]
represent a site linked to L₁₁ and L₁₂ in Formula 2.

11. The organic electroluminescent device according to claim 9, wherein at least one of Ar₂₁ to Ar₂₃ is a substituted or unsubstituted pyrimidyl, a substituted or unsubstituted pyridyl, a substituted or unsubstituted triazinyl, a substituted or unsubstituted carbazolyl, a substituted or unsubstituted dibenzofuranyl, or a substituted or unsubstituted dibenzothiophenyl.

12. The organic electroluminescent device according to claim 1, wherein the at least one light-emitting layer comprises a compound represented by the following Formula 4 or 5: 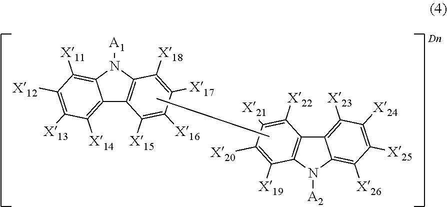
wherein,
A₁ and A₂ each independently represent a substituted or unsubstituted (C6-C30)aryl, a substituted or unsubstituted dibenzofuranyl, a substituted or unsubstituted dibenzothiophenyl, or a substituted or unsubstituted carbazolyl;
any one of X′₁₅ to X′₁₈ and any one of X′₁₉ to X′₂₂ are linked to each other to form a single bond;
X′₁₁ to X′₁₄, X′₂₃ to X′₂₆, and X′₁₅ to X′₂₂, which do not form a single bond, each independently represent hydrogen, deuterium, a substituted or unsubstituted (C6-C30)aryl, or a substituted or unsubstituted (3- to 30-membered)heteroaryl; or may be linked to the adjacent substituents to form a ring(s);
at least one of X′₁₁, X′₁₈, X′₁₉ and X′₂₆ is deuterium; and
Dₙ means that n number of hydrogens is replaced with deuterium, wherein n is an integer of 1 or more, and the upper limit of n is determined according to the number of hydrogens in the non-deuterated compound; 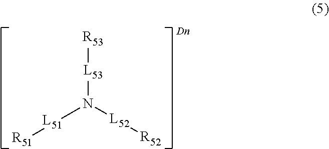
wherein,
L₅₁ to L₅₃ each independently represent a single bond, a substituted or unsubstituted (C6-C30)arylene, or a substituted or unsubstituted (3- to 30-membered)heteroarylene;
R₅₁ to R₅₃ each independently represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted a fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino; or may be linked to the adjacent substituents to form a ring(s);
provided that at least one of R₅₁ to R₅₃ in Formula 5 comprises the following Formula 5-1 or 5-2; 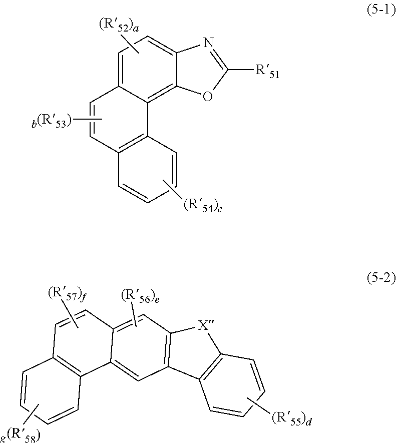
or, when L₅₁ and L₅₂ are a single bond and R₅₁ and R₅₂ are linked to each other to form a ring(s), Formula 5 is represented by any one of the following Formulas 5-3 to 5-5; 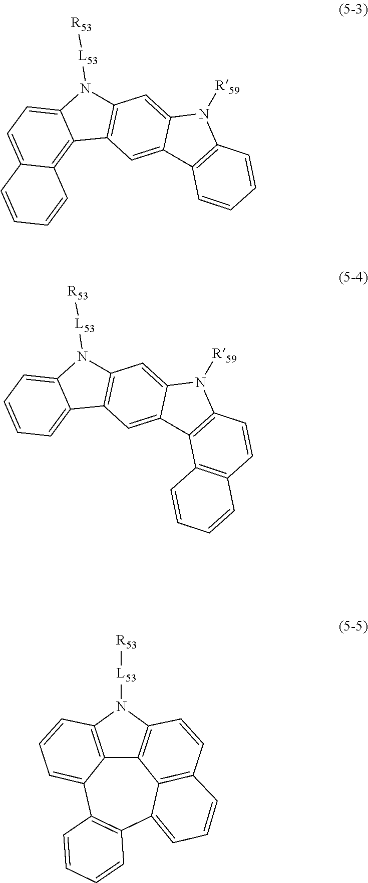
wherein
R′₅₁ to R′₅₉ are the same as the definitions of R₅₁ to R₅₃;
X″ represents —O— or —S—;
a, b, e, and f each independently represent 1 or 2, c, d, and g are an integer of 1 to 4, when a to g are an integer of 2 or more, each of R′₅₁ to each of R′₅₉ may be the same as or different from each other; and
Dₙ means that n number of hydrogens is replaced with deuterium, wherein n is an integer of 1 or more, and the upper limit of n is determined according to the number of hydrogens in the non-deuterated compound.

13. The organic electroluminescent device according to claim 1, wherein the at least one light-emitting layer comprises at least two compounds selected from compounds represented by the following Formula 6 or 7. 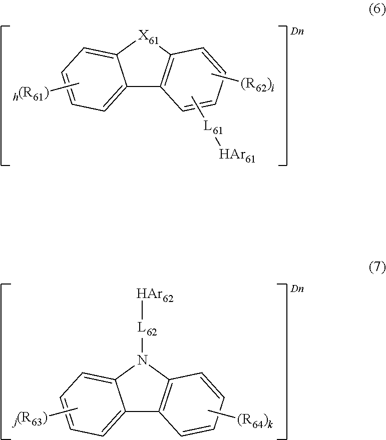
wherein,
X₆₁ represents —O— or —S—;
HAr₆₁ and HAr₆₂ each independently represent a substituted or unsubstituted (3- to 30-membered)heteroaryl containing at least one nitrogen atom;
L₆₁ and L₆₂ each independently represent a single bond, a substituted or unsubstituted (C6-C30)arylene, or a substituted or unsubstituted (3- to 30-membered)heteroarylene;
R₆₁ to R₆₄ each independently represent hydrogen, deuterium, a substituted or unsubstituted (C6-C30)aryl, or a substituted or unsubstituted (3- to 30-membered)heteroaryl; or may be linked to the adjacent substituents to form a substituted or unsubstituted indole ring, a substituted or unsubstituted benzofuran ring, a substituted or unsubstituted benzothiophene ring, a substituted or unsubstituted indene ring, or a substituted or unsubstituted benzene ring;
h to k each independently represent an integer of 1 to 4, when h to k are an integer of 2 or more, each of R₆₁ to each of R₆₄ may be the same as or different from each other; and
Dₙ means that n number of hydrogens is replaced with deuterium, wherein n is an integer of 1 or more, and the upper limit of n is determined according to the number of hydrogens in the non-deuterated compound.

14. The organic electroluminescent device according to claim 1, wherein the at least one light-emitting layer comprises a compound represented by the following Formula 8: 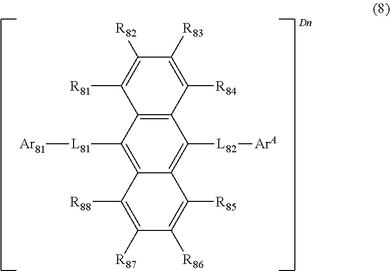
wherein,
L₈₁ and L₈₂ each independently represent a single bond, a substituted or unsubstituted (C6-C30)arylene, or a substituted or unsubstituted (3- to 30-membered)heteroarylene;
Ar₈₁ represents a substituted or unsubstituted (C6-C30)aryl or a substituted or unsubstituted (3- to 30-membered)heteroaryl;
R₈₁ to R₈₈ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted a fused ring of (C3-C30) aliphatic ring and (C6-C30) aromatic ring;
Ar^{A} represents a substituted or unsubstituted (C6-C30)aryl, a substituted or unsubstituted (3- to 30-membered)heteroaryl, or is represented by the following Formula A-1; and
Dₙ means that n number of hydrogens is replaced with deuterium, wherein n is an integer of 1 or more, and the upper limit of n is determined according to the number of hydrogens in the non-deuterated compound; 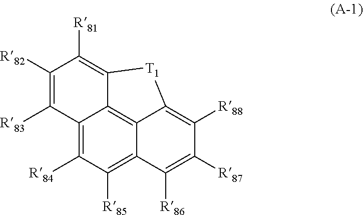
wherein,
T₁ represents —O—, —S—, or —CRₗRₘ;
R′₈₁ to R′₈₈ each independently represent a site linked to L₈₂, or hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted a fused ring of (C3-C30) aliphatic ring and (C6-C30) aromatic ring, or -L₈₃-N(Ar₈₃)(Ar₈₄);
Rₗ and Rₘ each independently represent a substituted or unsubstituted (C1-C30)alkyl or a substituted or unsubstituted (C6-C30)aryl; or may linked to each other to form a ring(s);
L₈₃ represents a single bond, a substituted or unsubstituted (C6-C30)arylene, or a substituted or unsubstituted (3- to 30-membered)heteroarylene; and
Ar₈₃ and Ar₈₄ each independently represent a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl.

15. The organic electroluminescent device according to claim 7, wherein the compound represented by Formula 1 is selected from the following compounds. 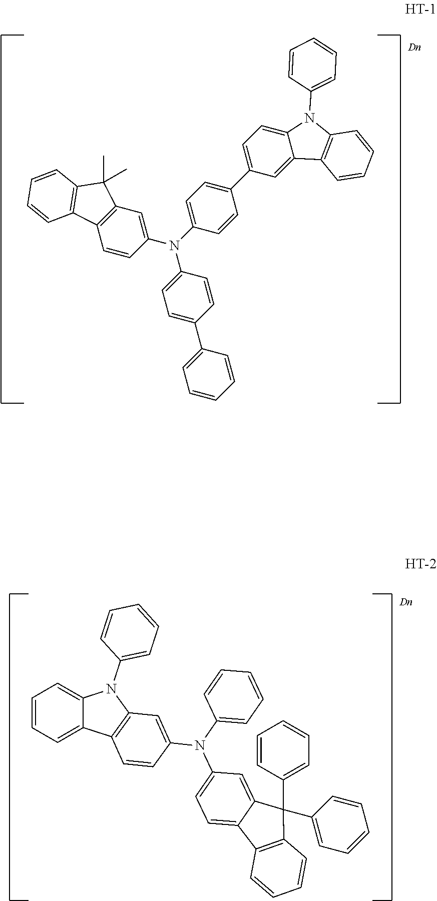 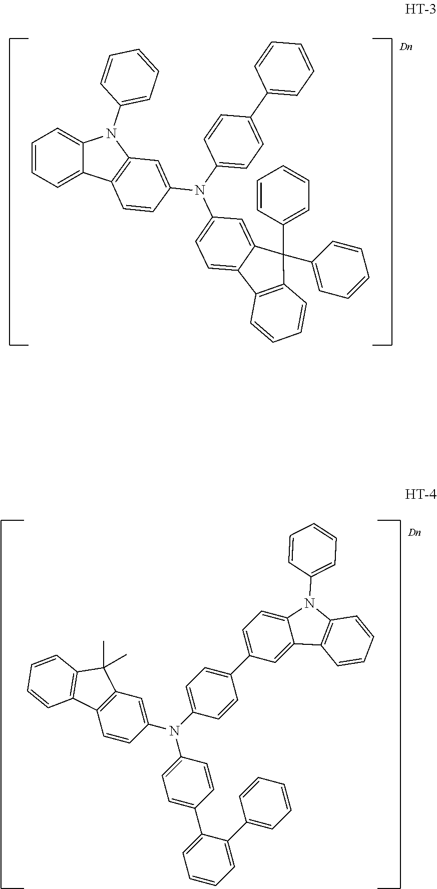 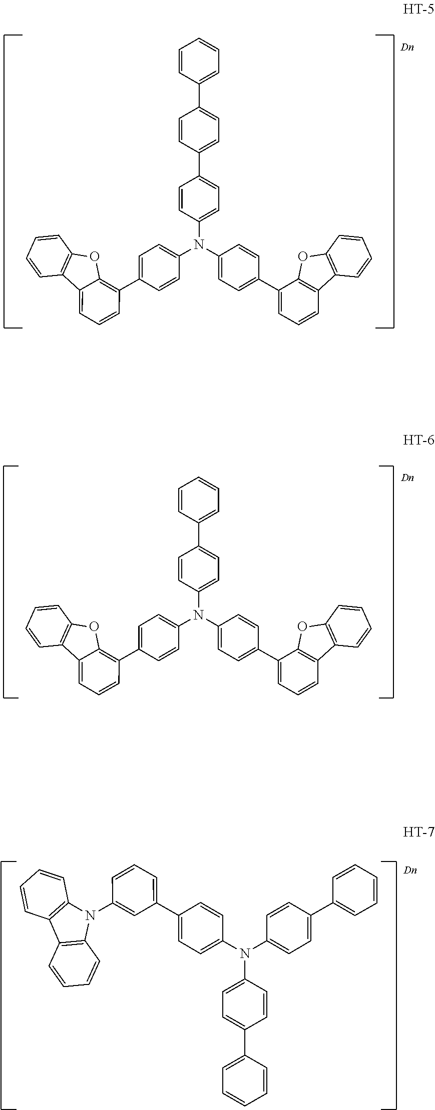 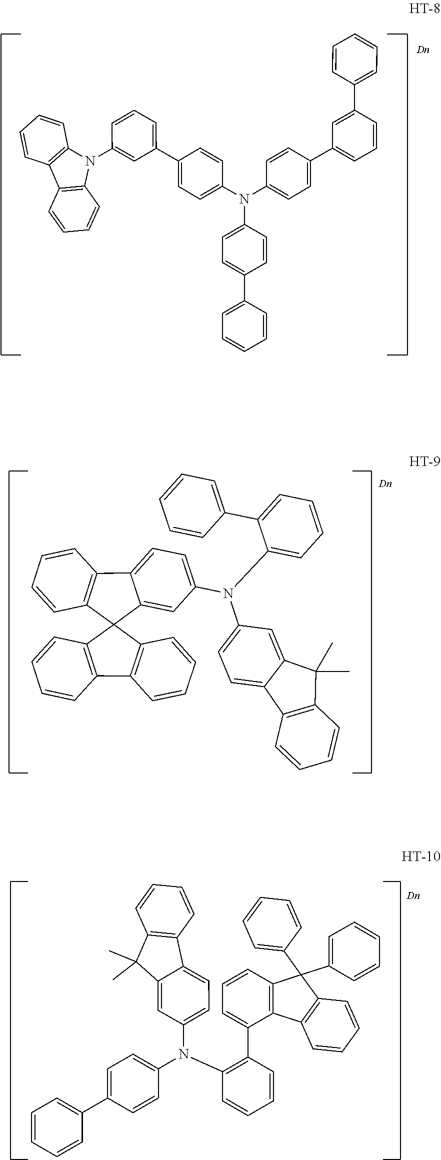 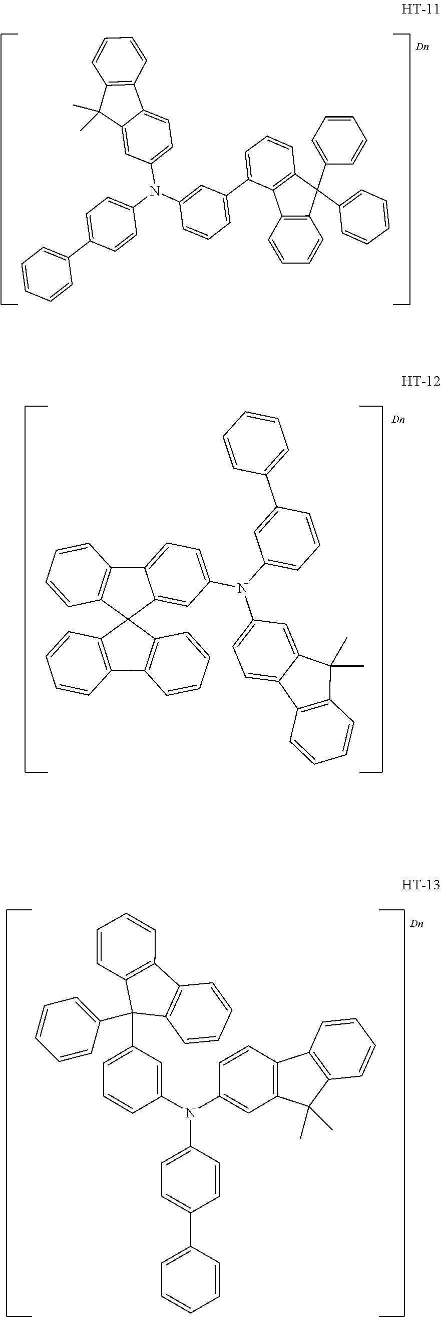 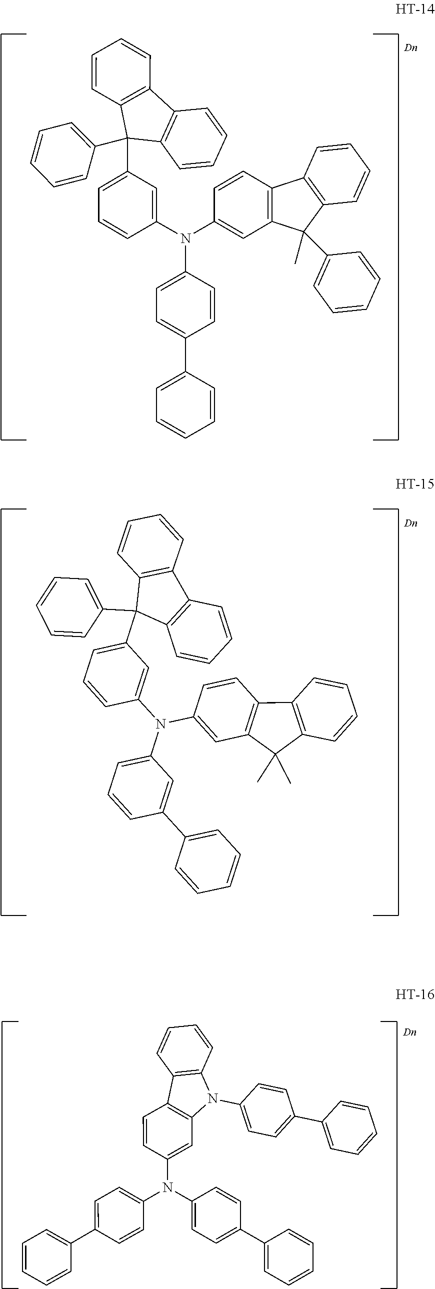 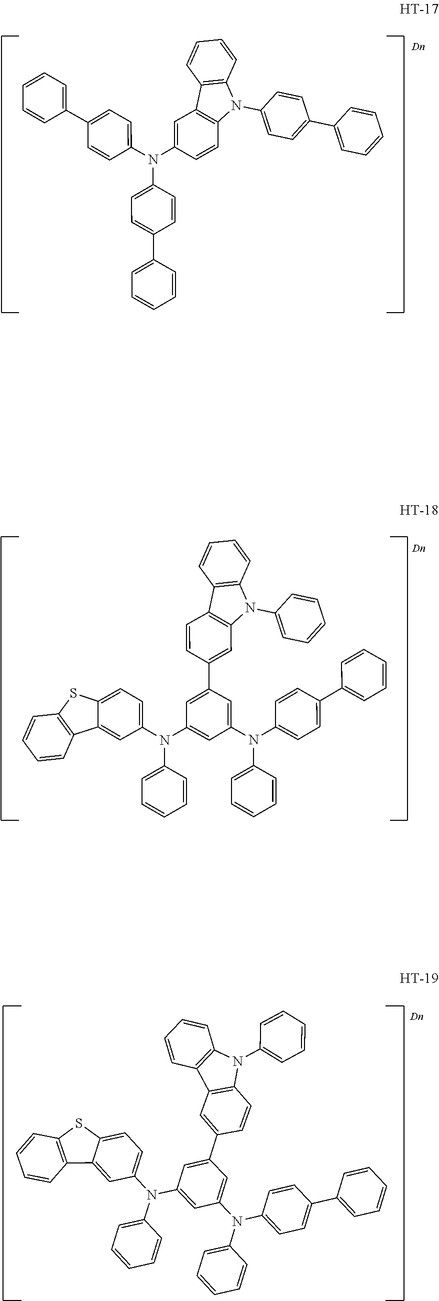 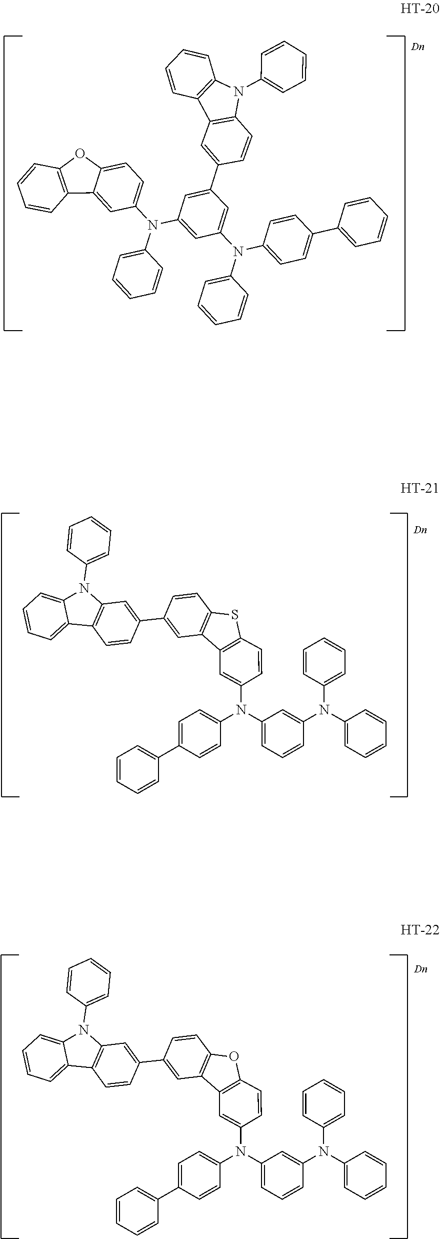 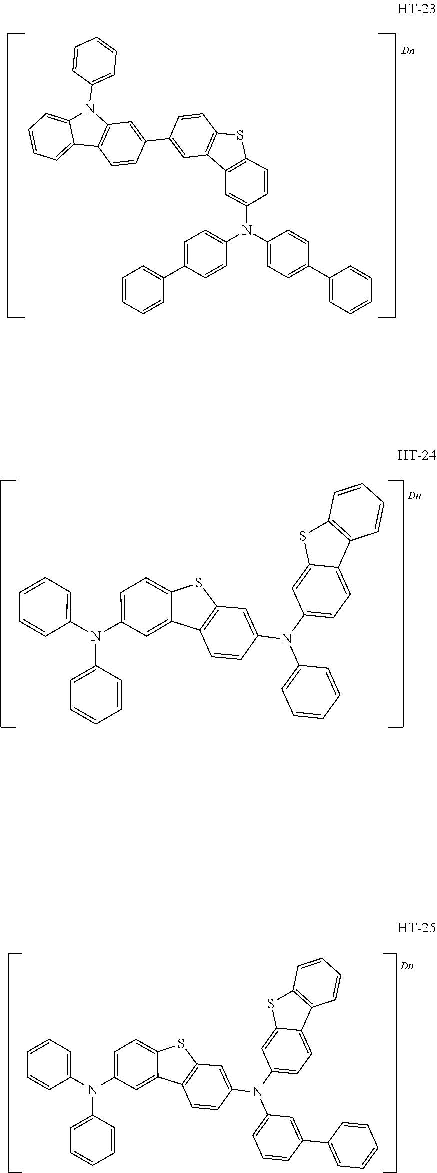 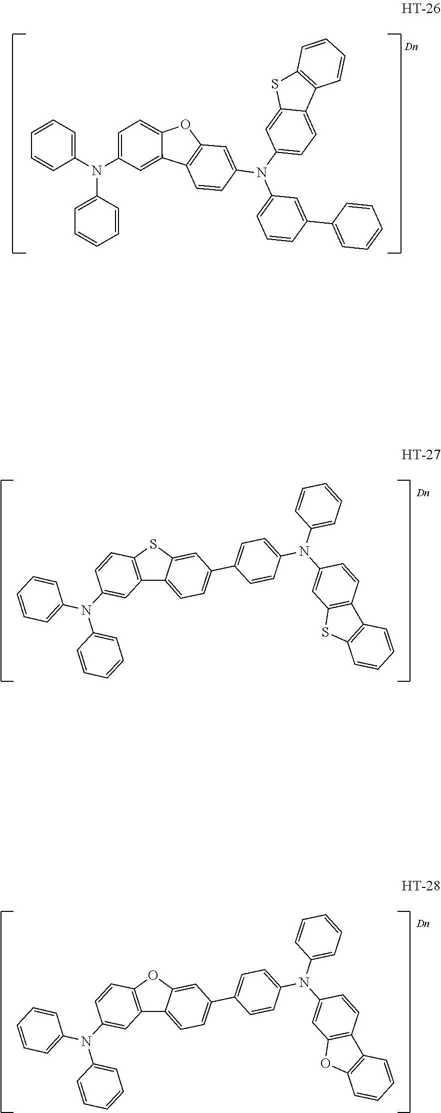 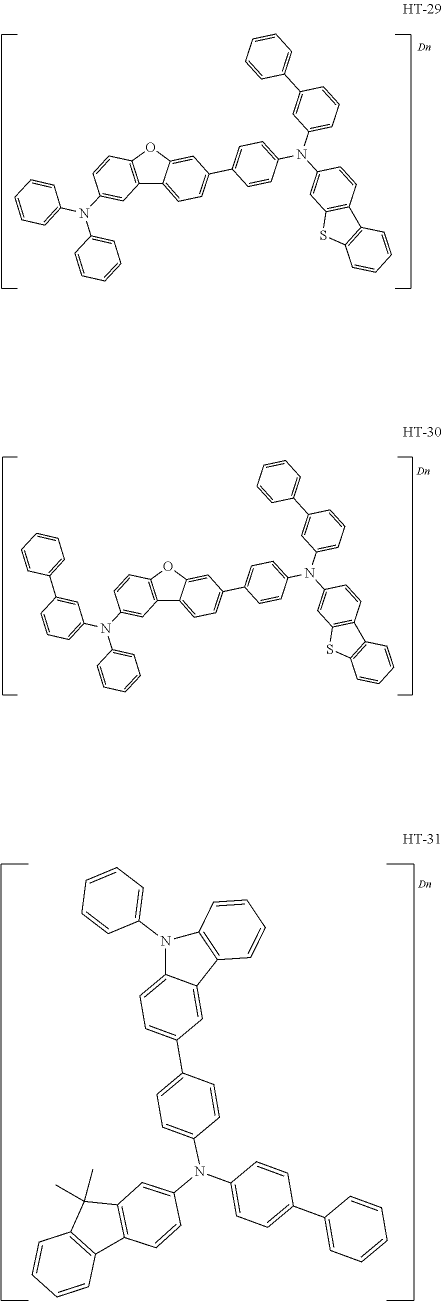 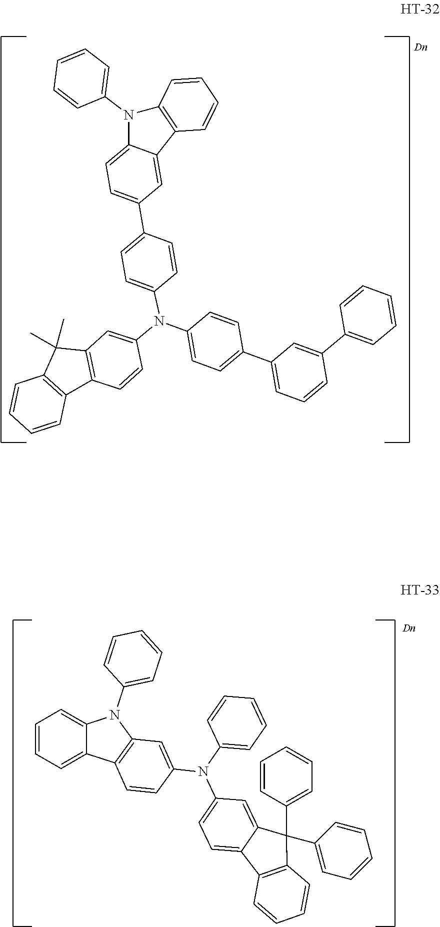 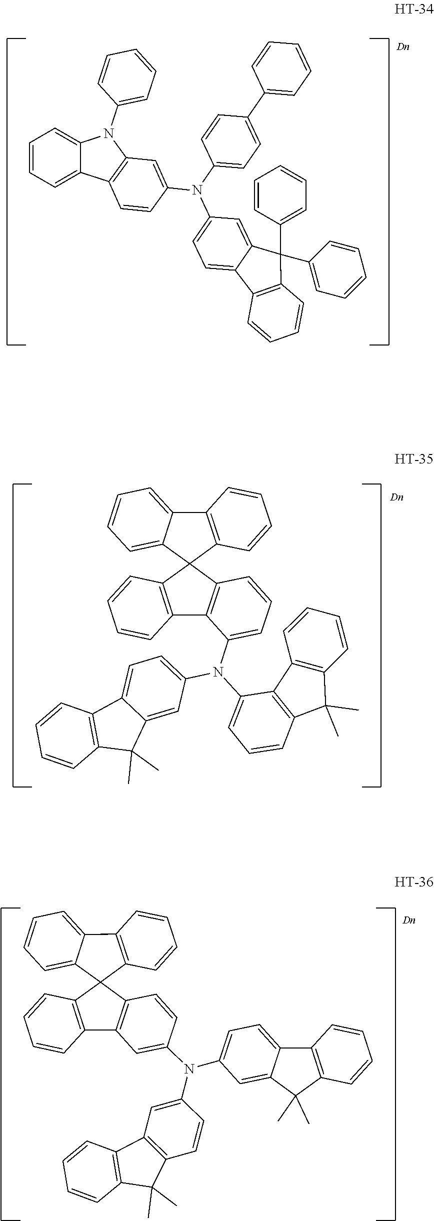 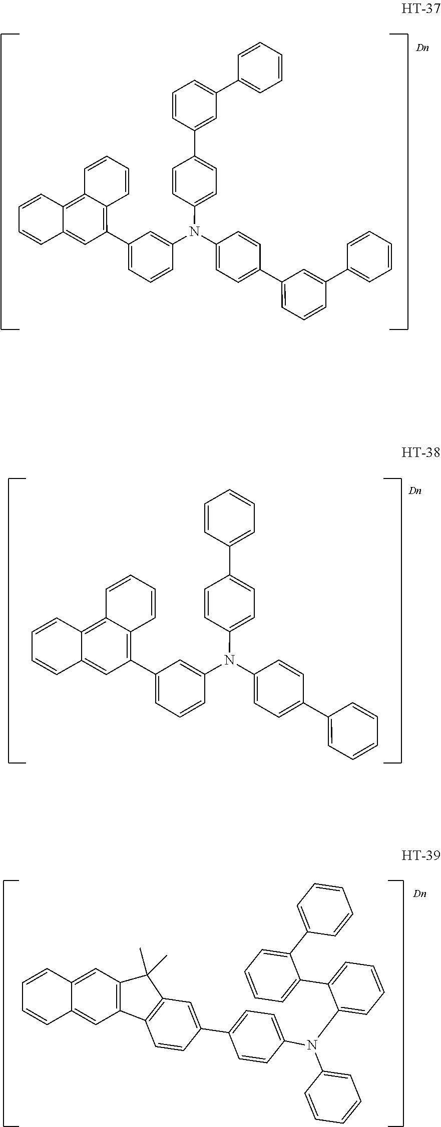 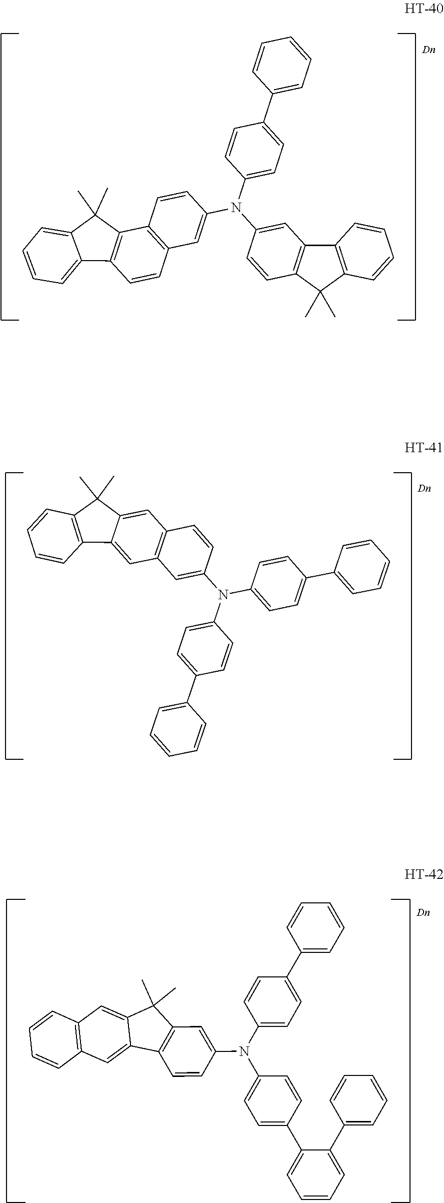 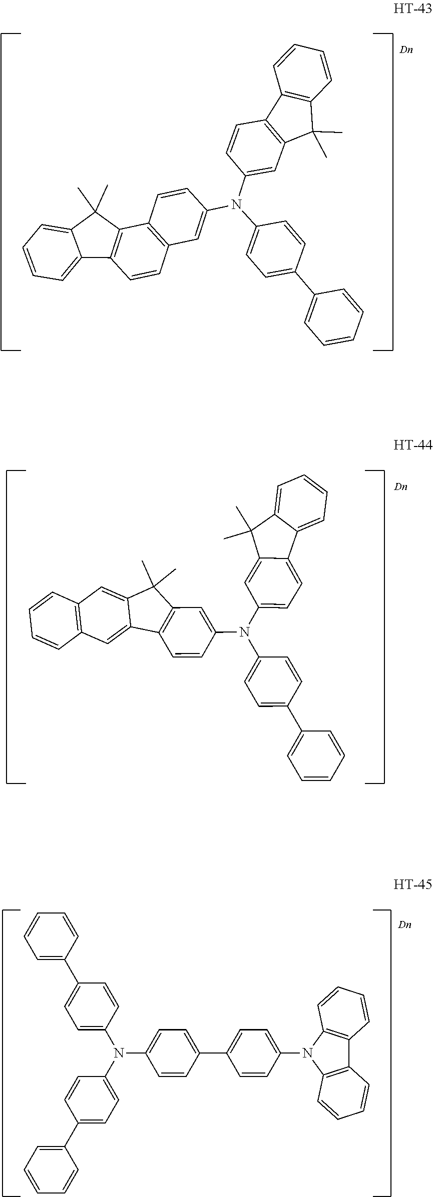 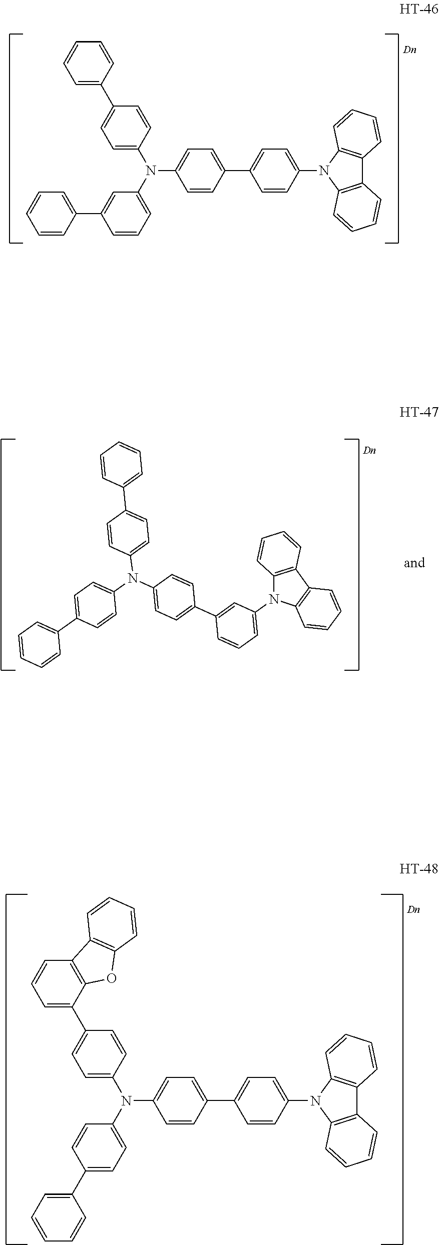
wherein Dₙ means that n number of hydrogens is replaced with deuterium, wherein n is an integer of 1 or more, and the upper limit of n is determined according to the number of hydrogens in the non-deuterated compound.

16. The organic electroluminescent device according to claim 9, wherein the compound represented by Formula 2 or 3 is selected from the following compounds. 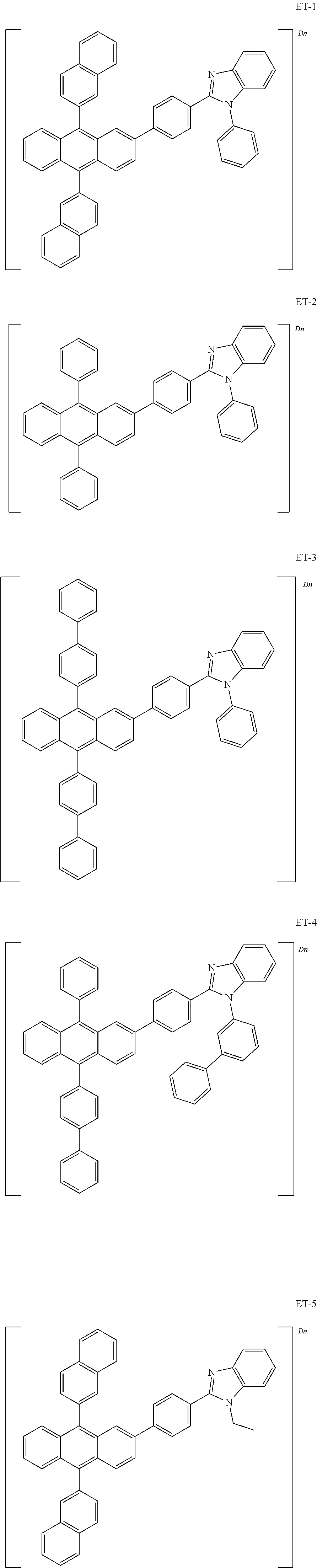 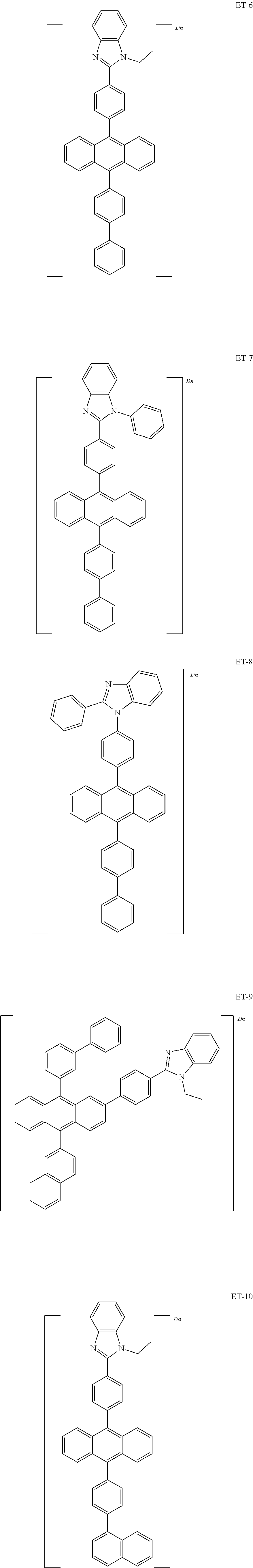 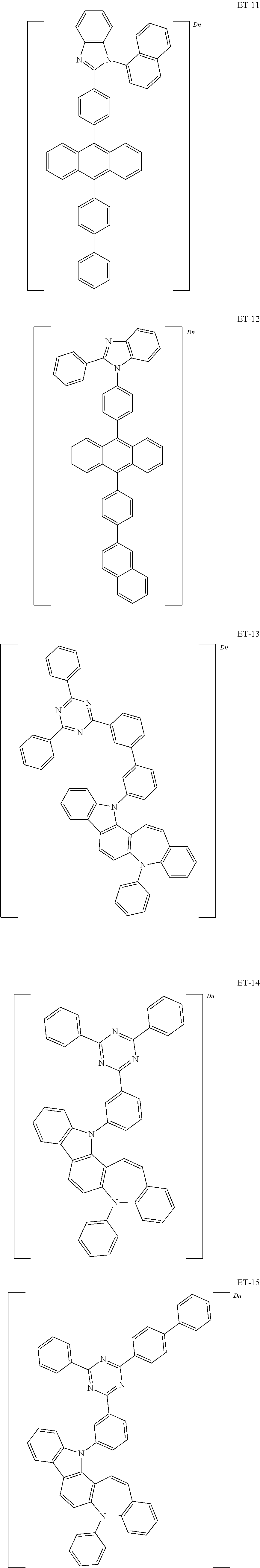 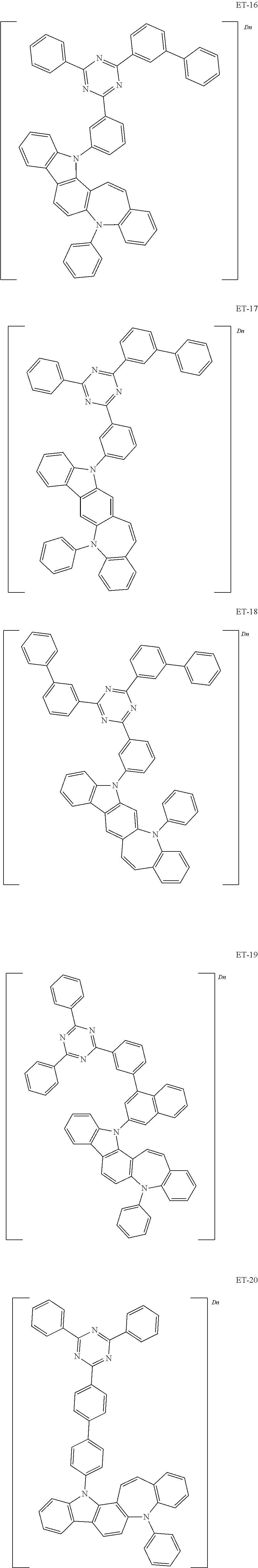 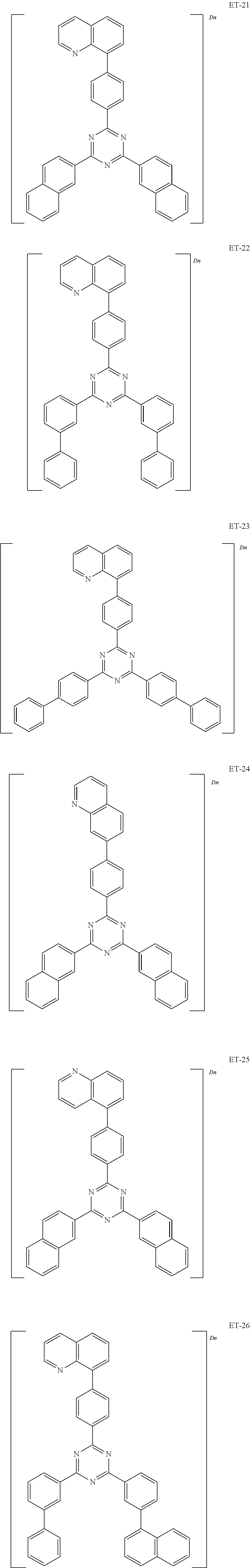 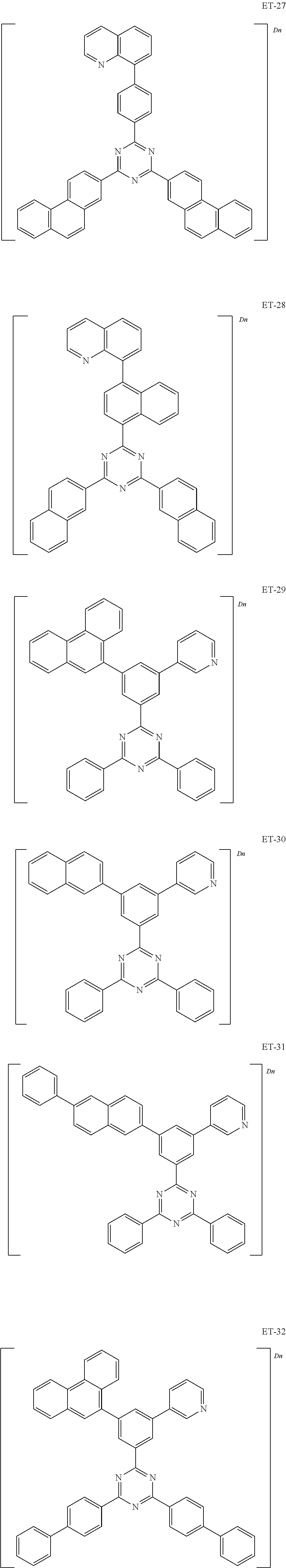 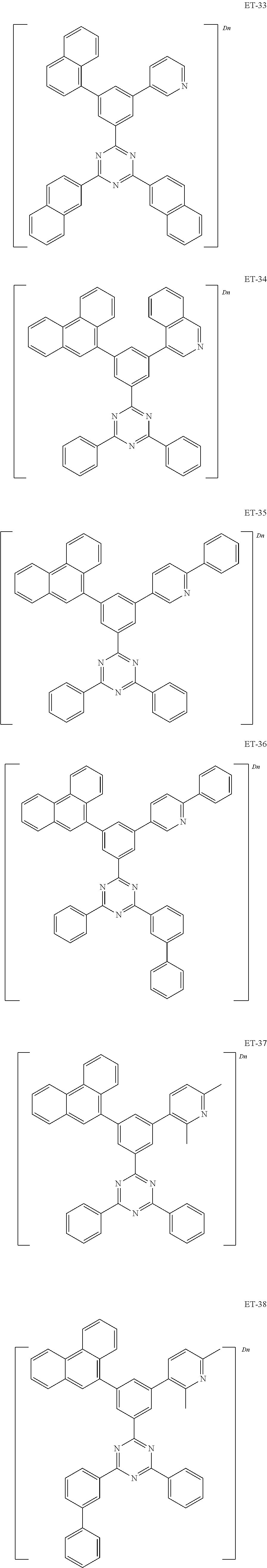 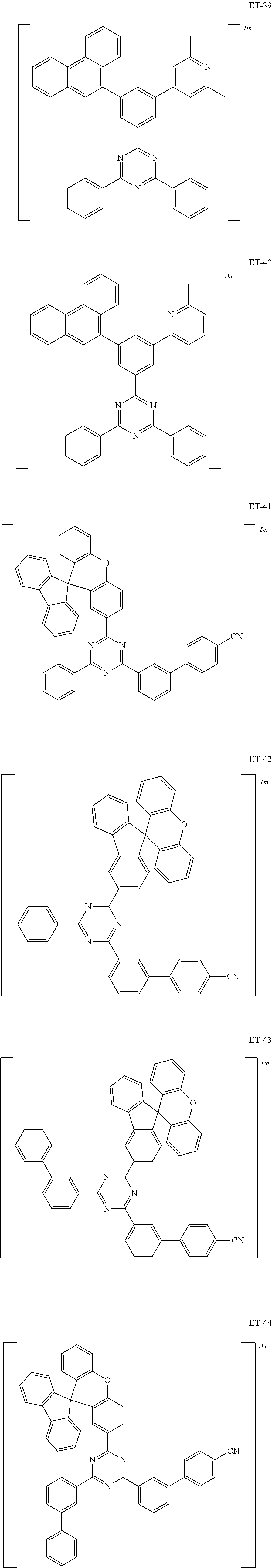 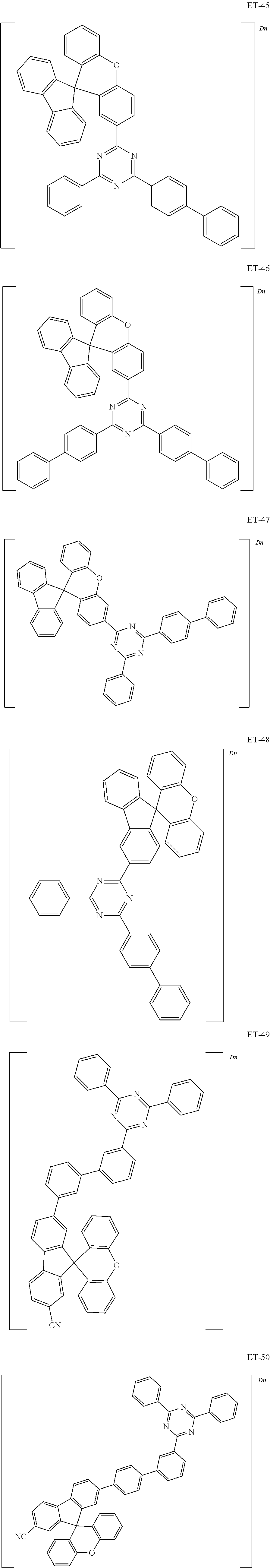 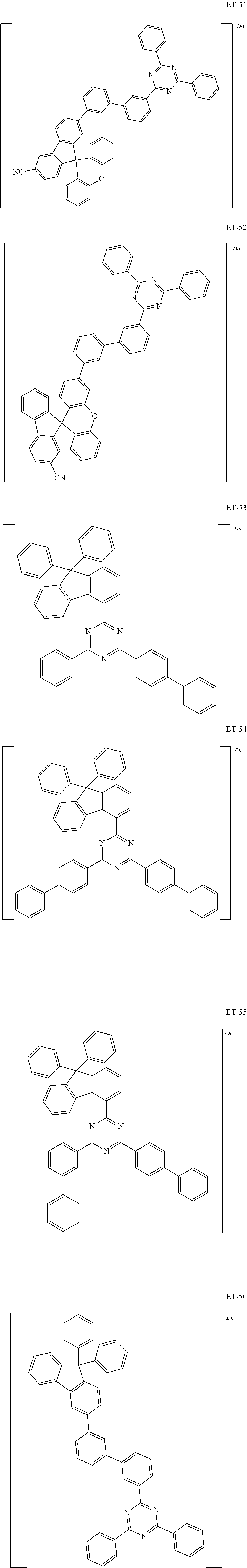 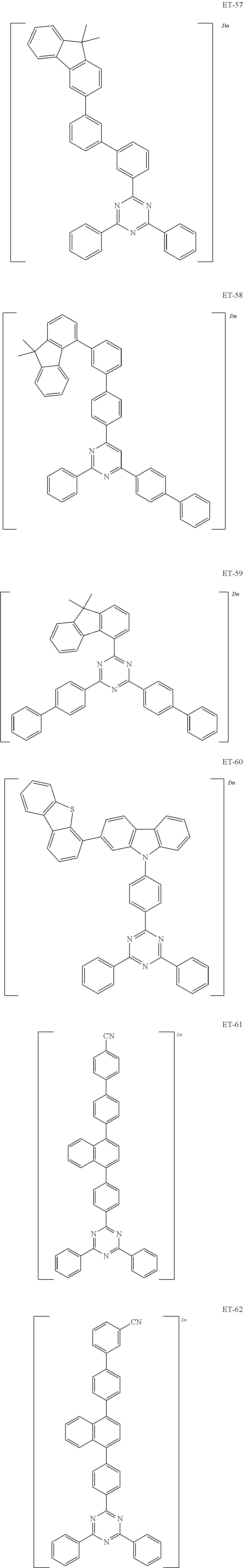 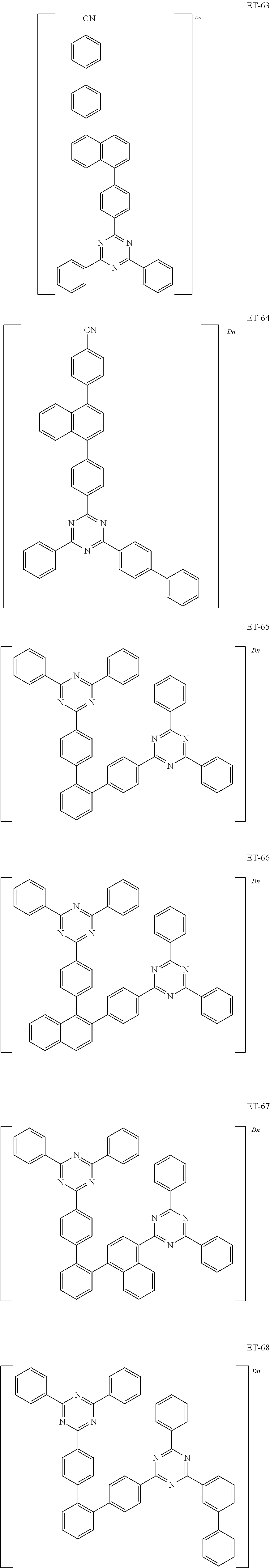 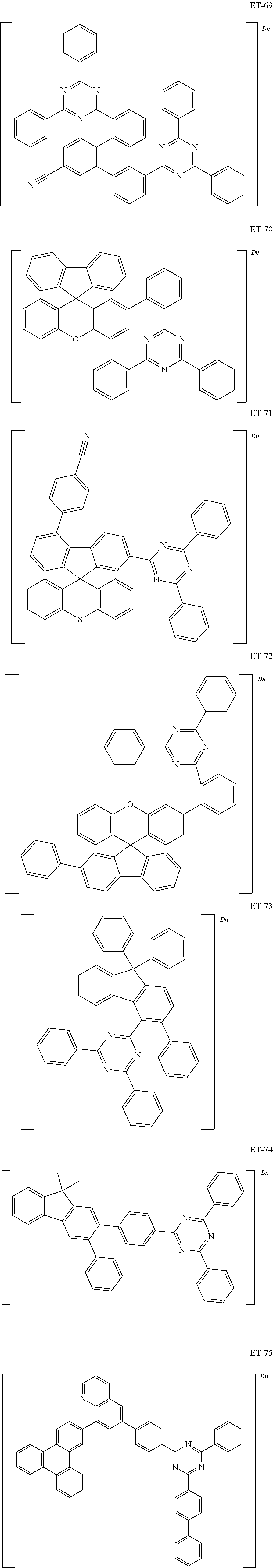 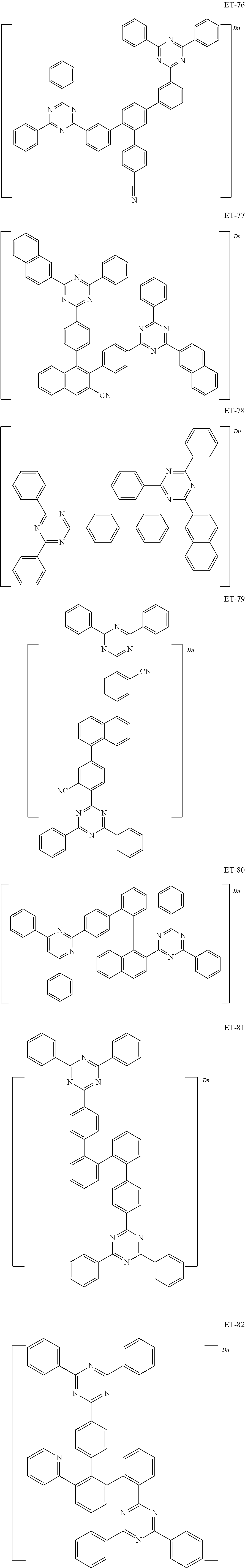 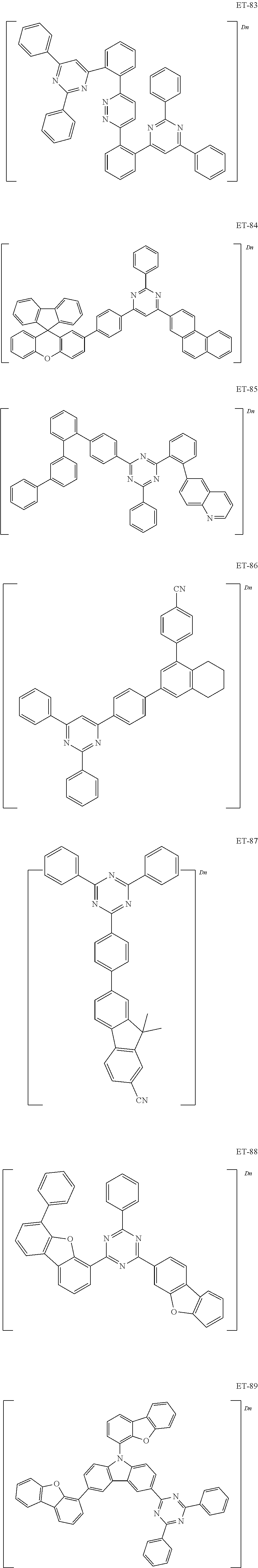 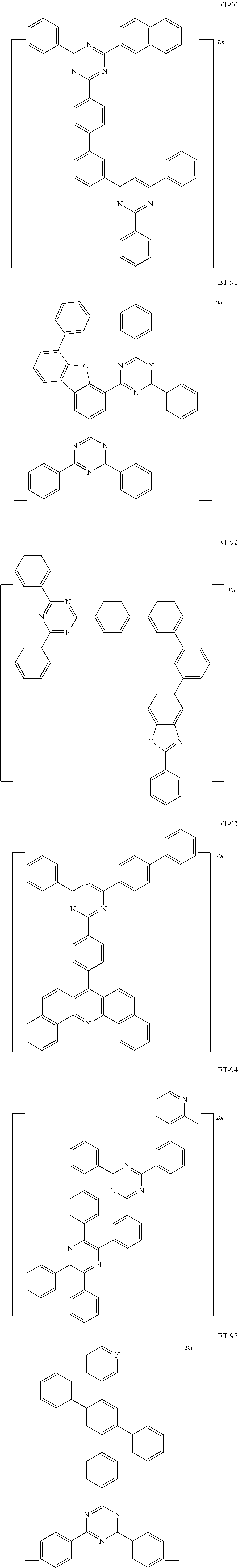 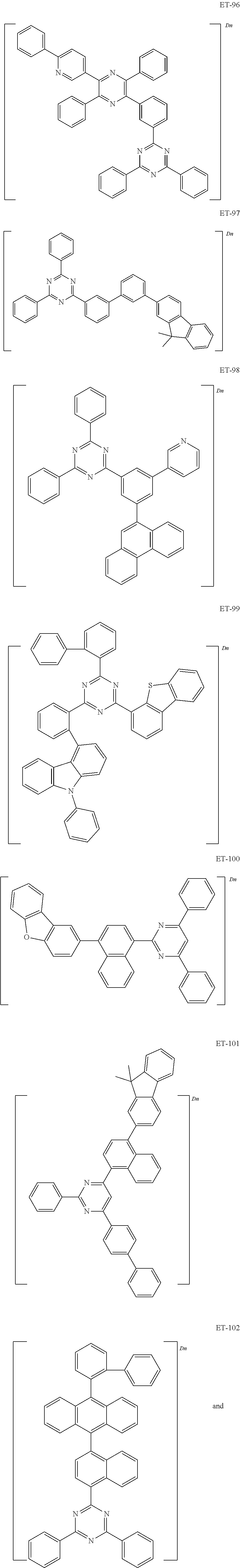 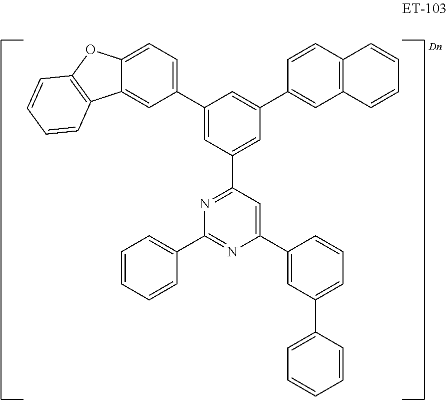
wherein Dₙ means that n number of hydrogens is replaced with deuterium, wherein n is an integer of 1 or more, and the upper limit of n is determined according to the number of hydrogens in the non-deuterated compound.

17. The organic electroluminescent device according to claim 12, wherein the compound represented by Formula 4 or 5 is selected from the following compounds. 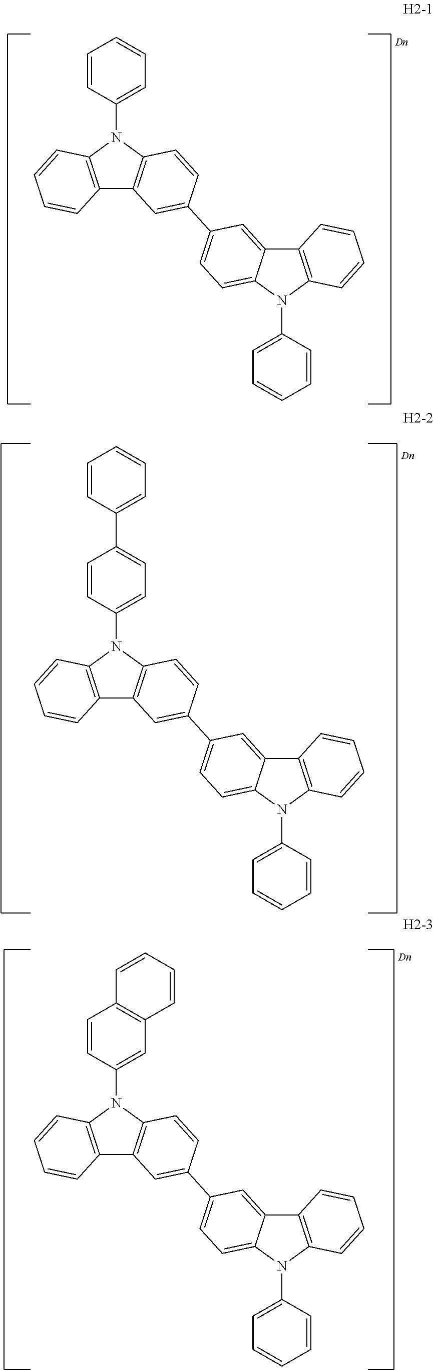 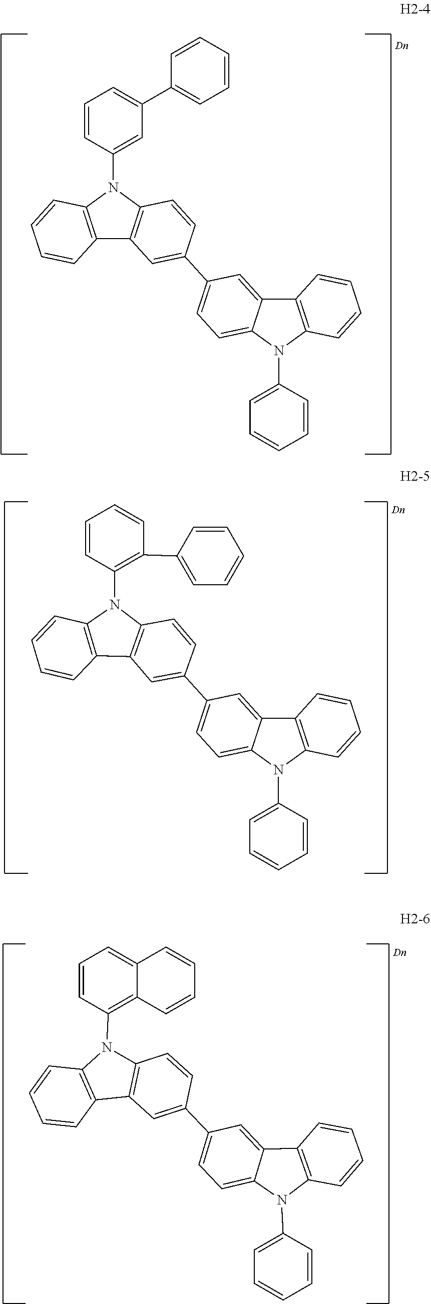 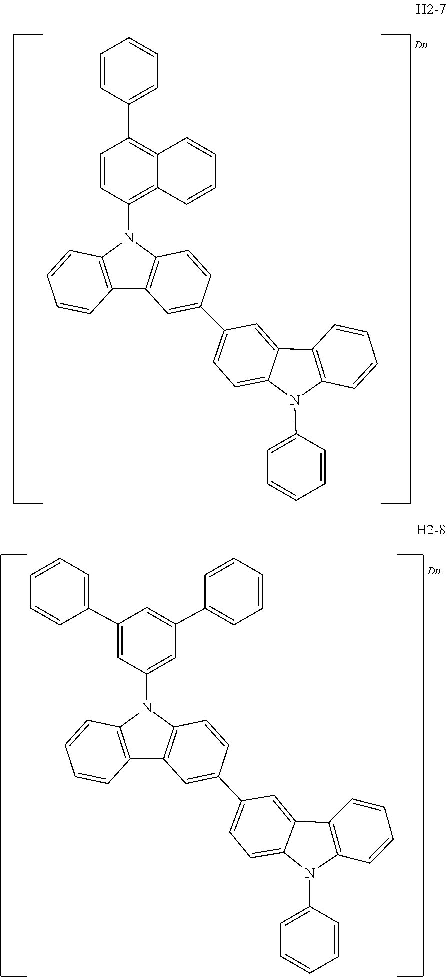 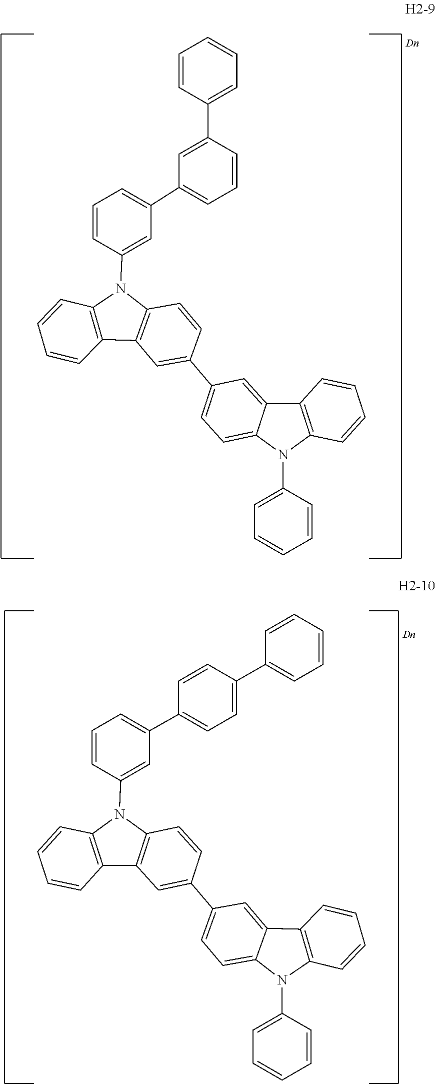 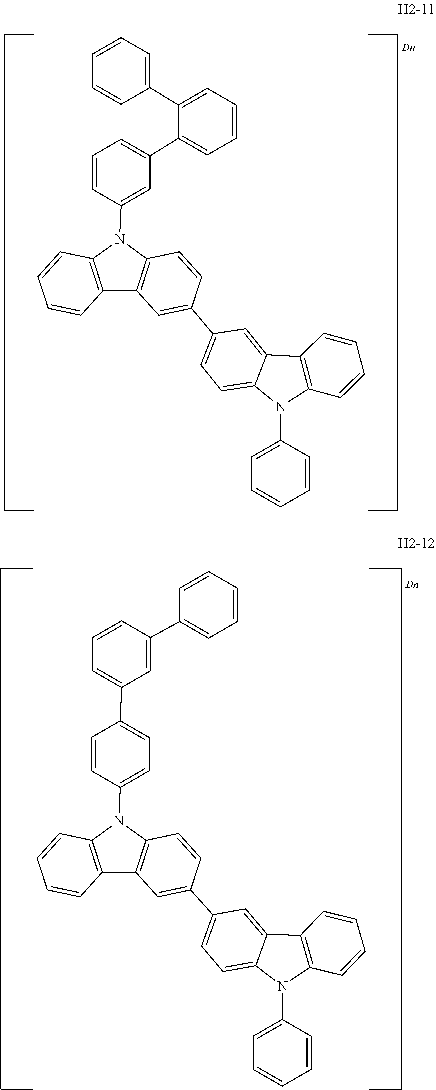 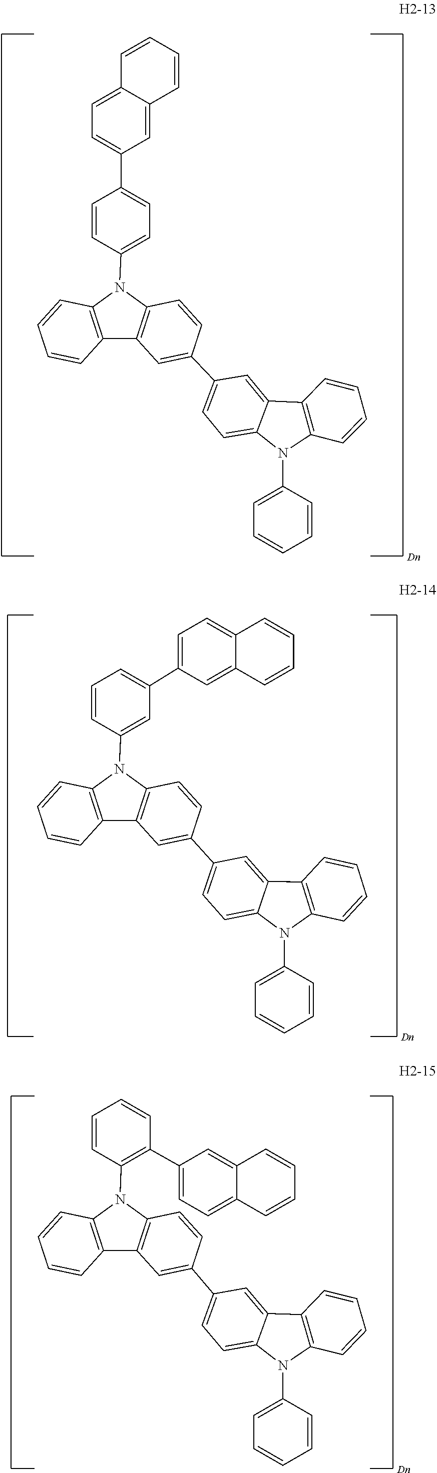 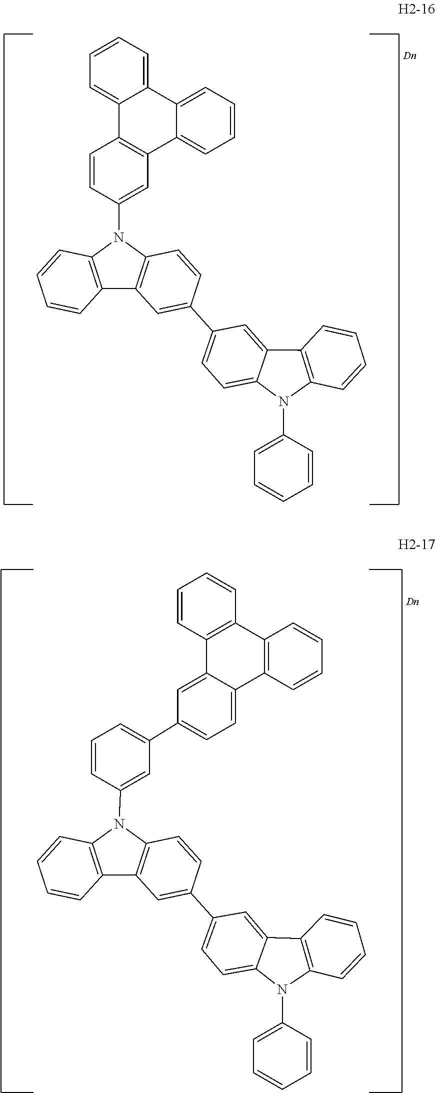 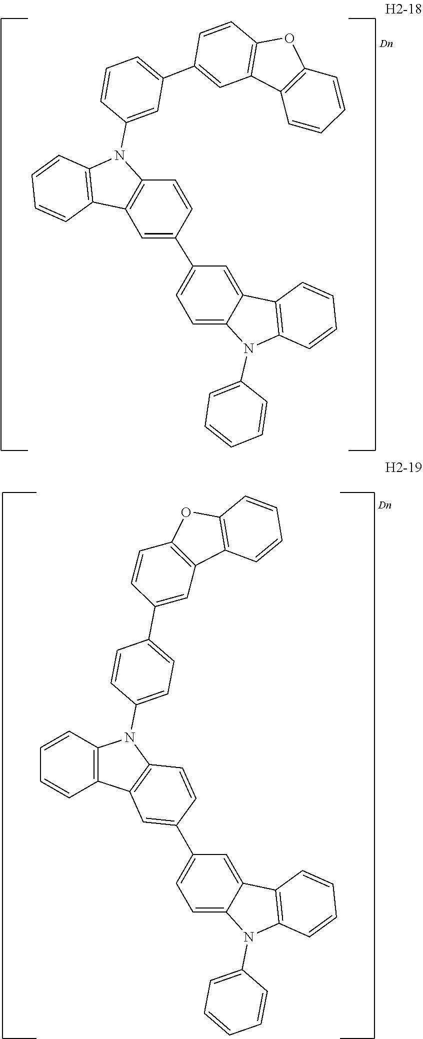 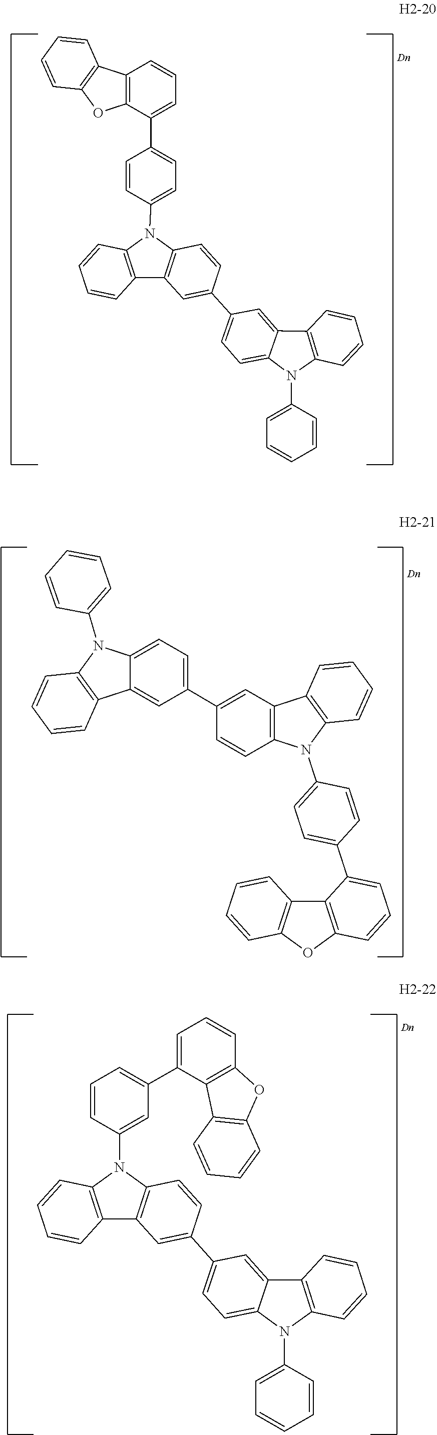 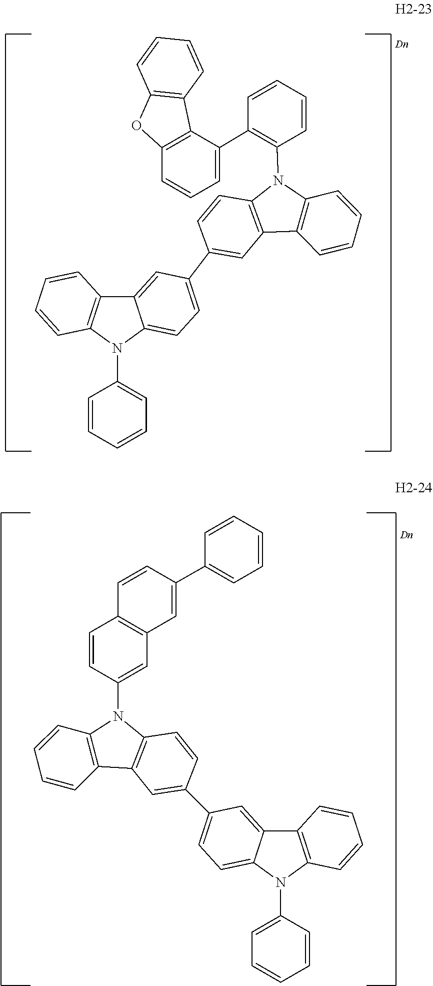 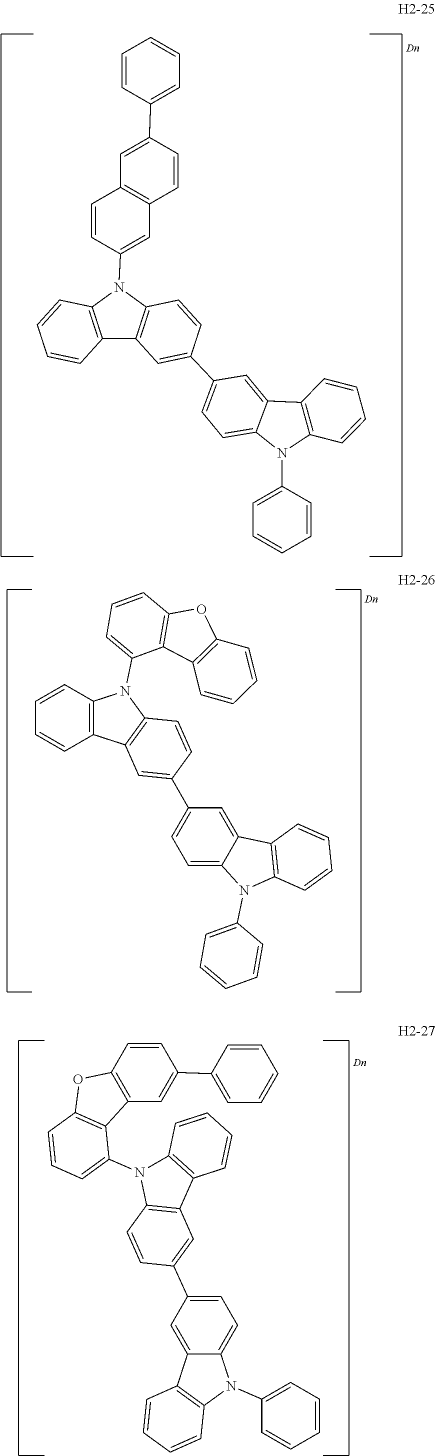 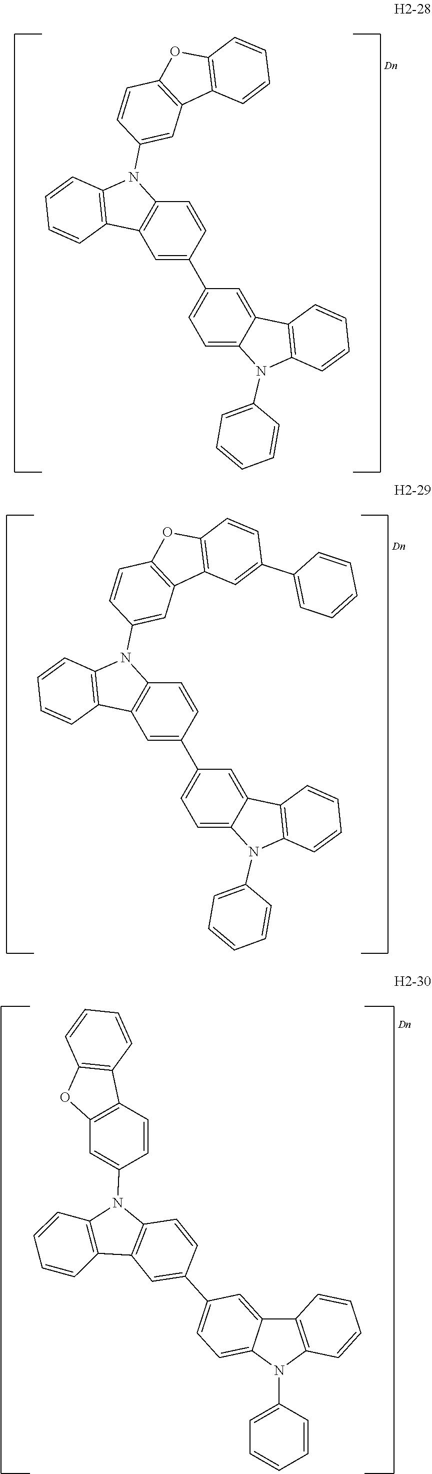 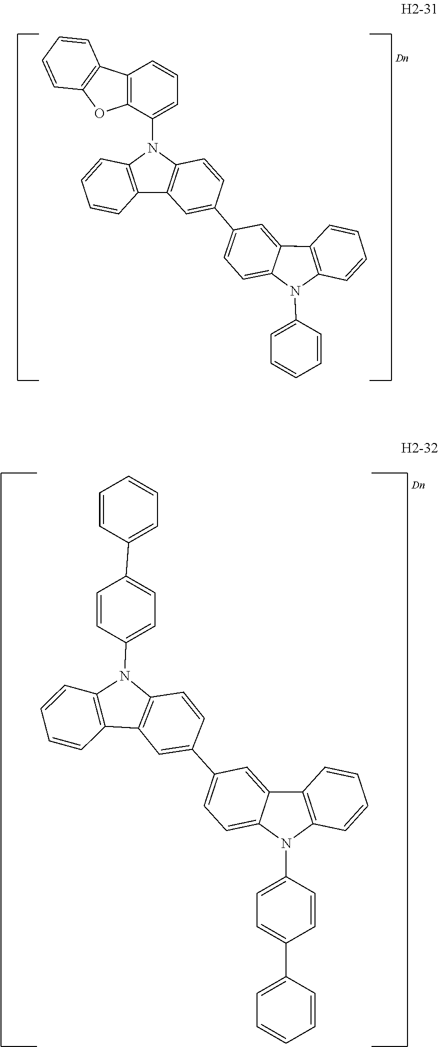 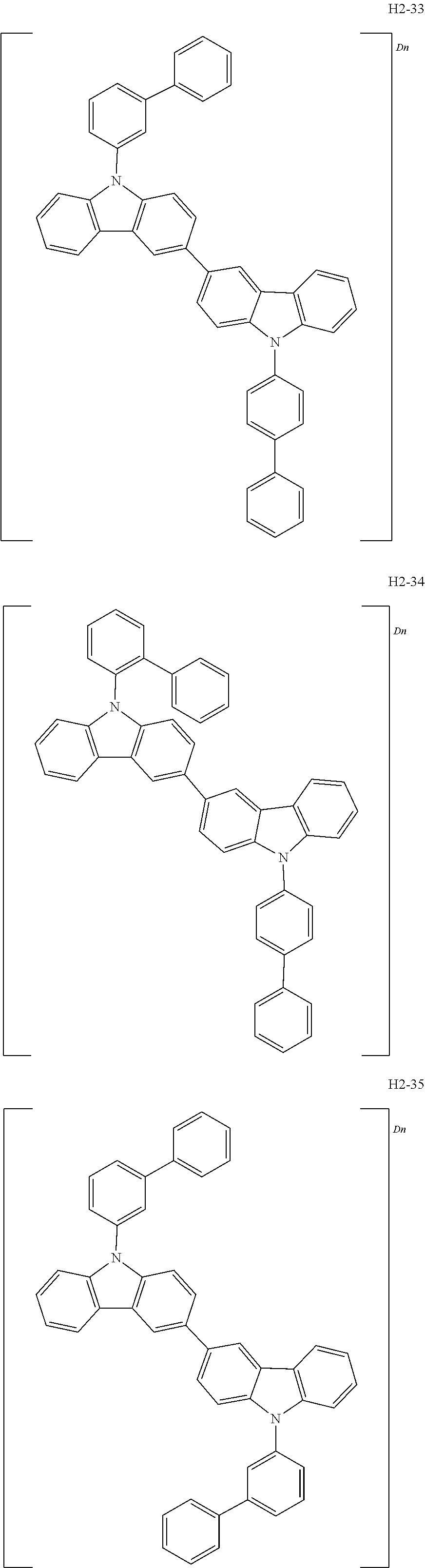 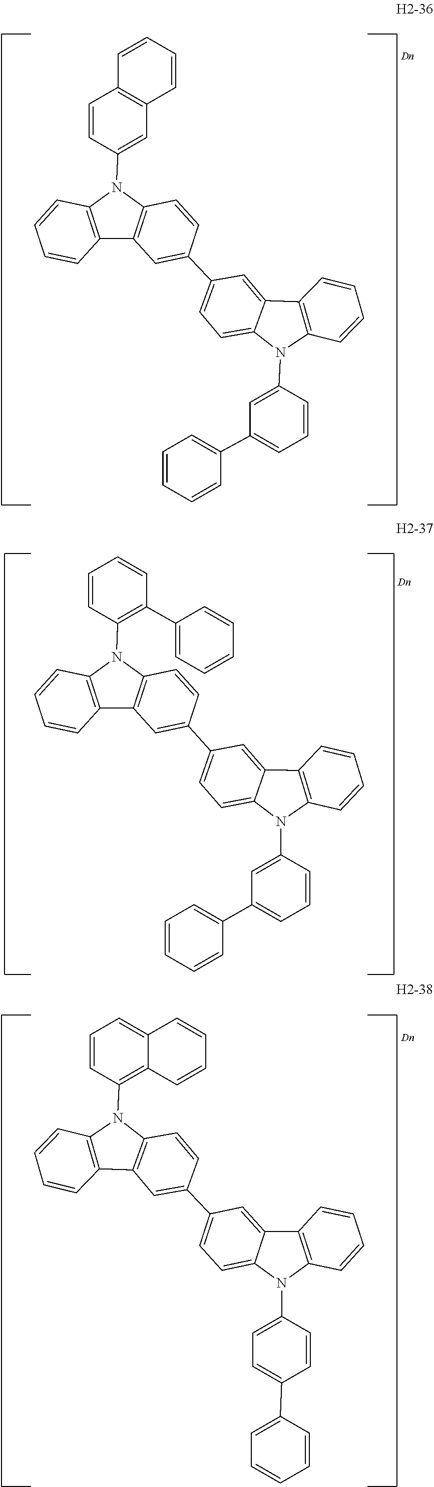 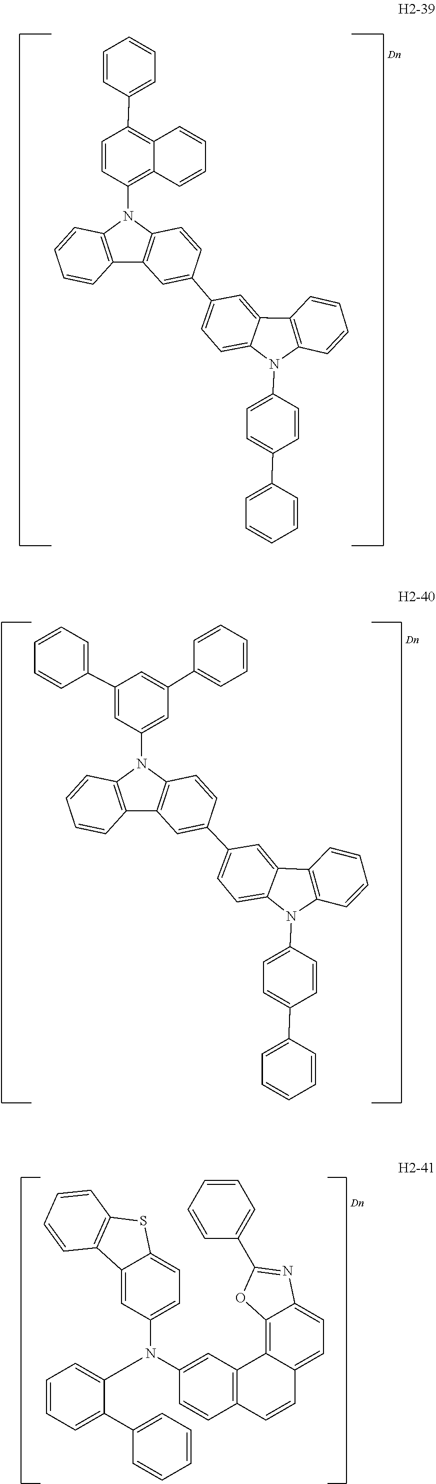 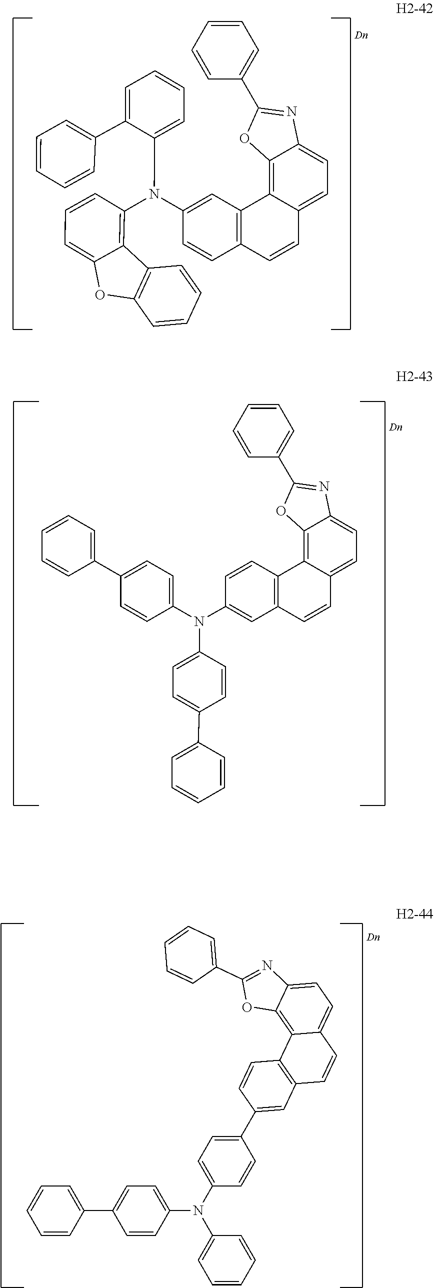 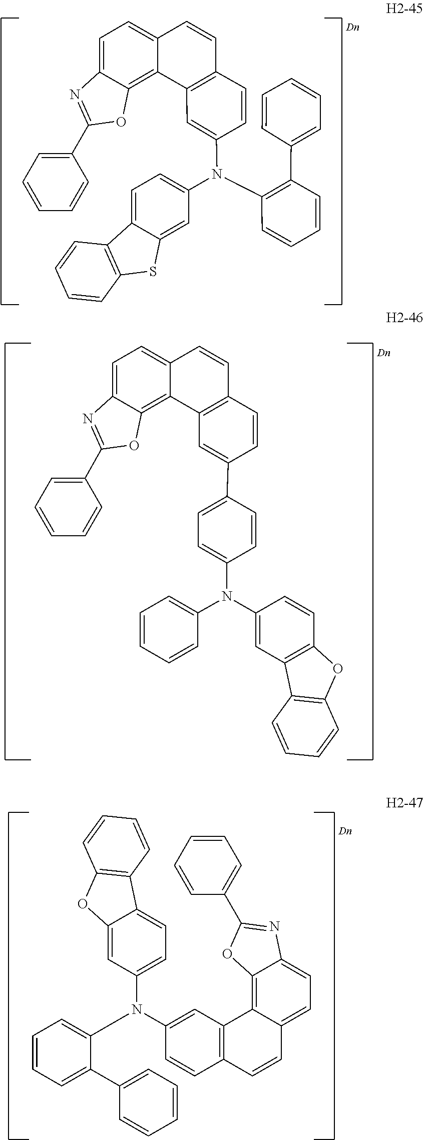 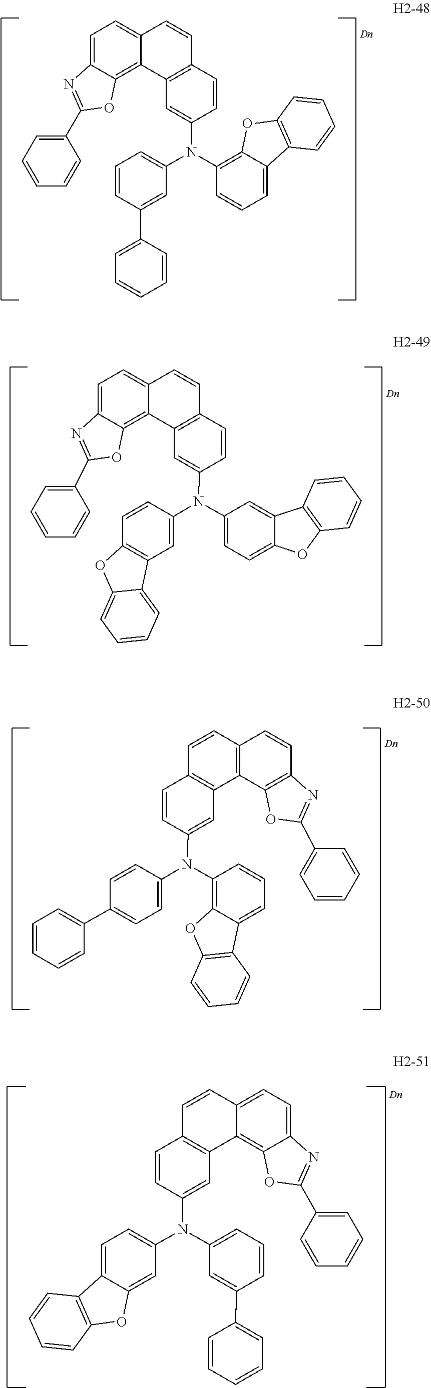 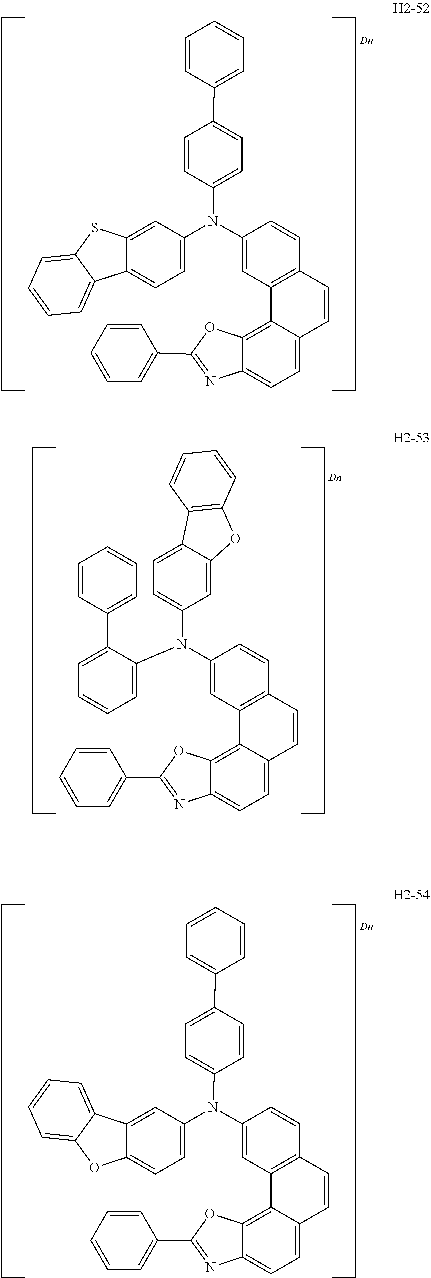 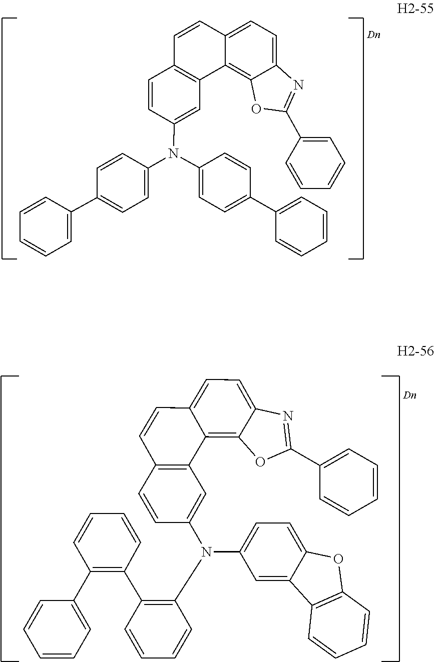 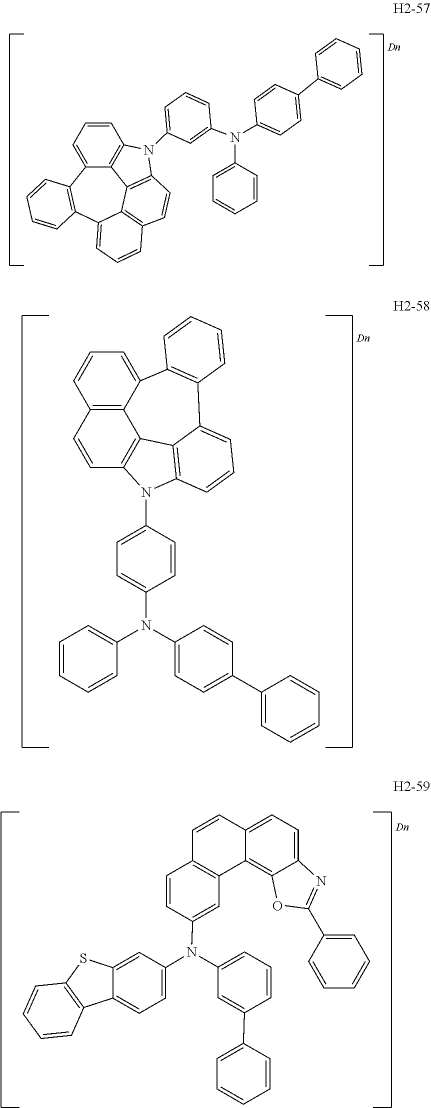 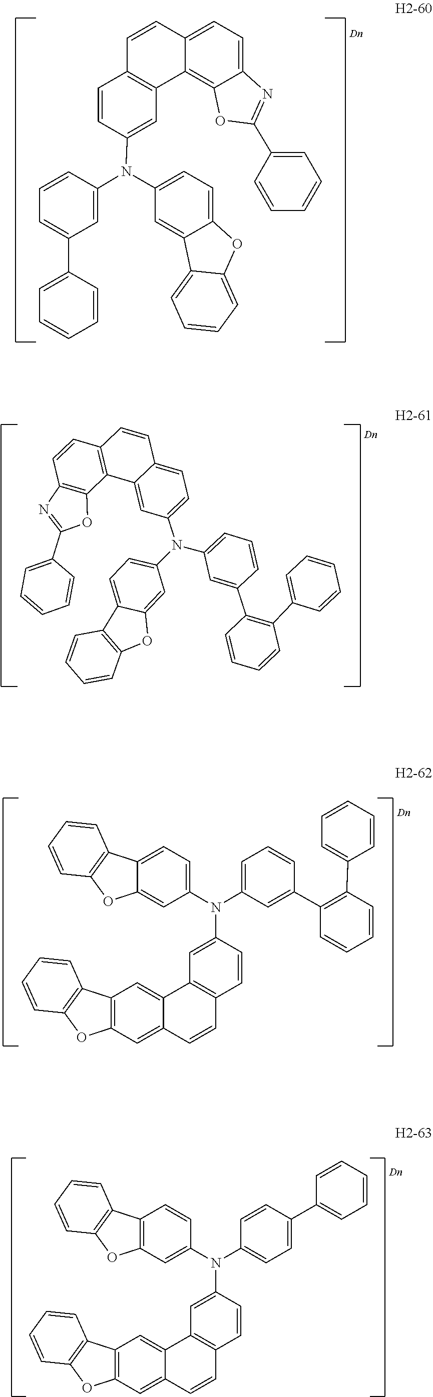 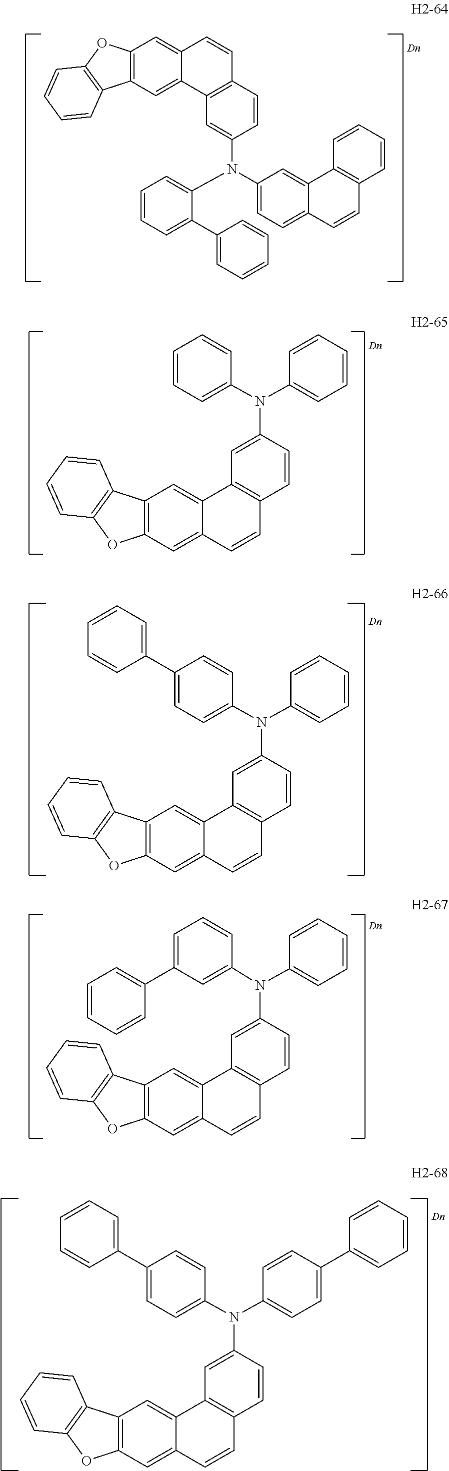 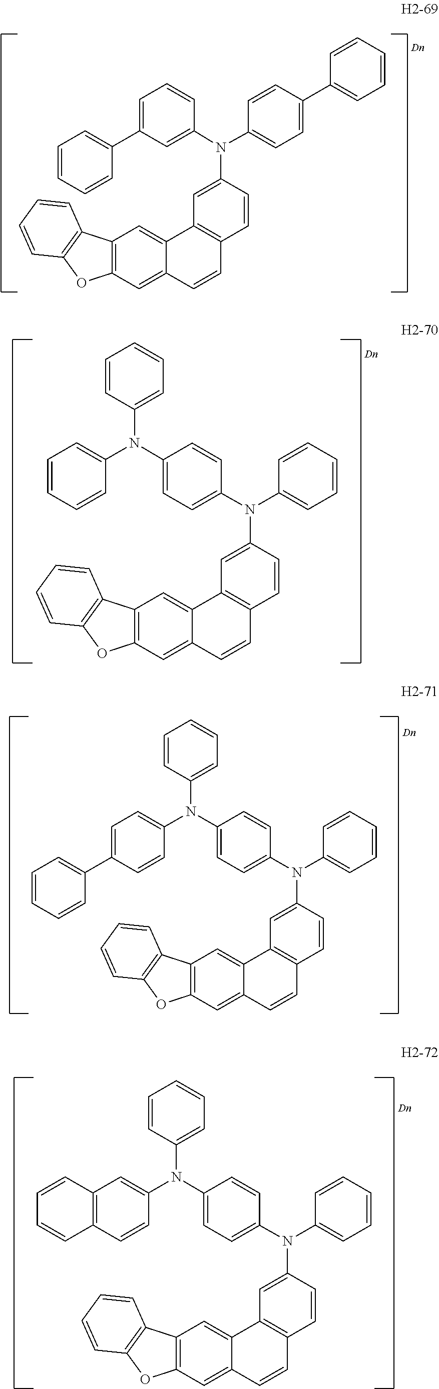 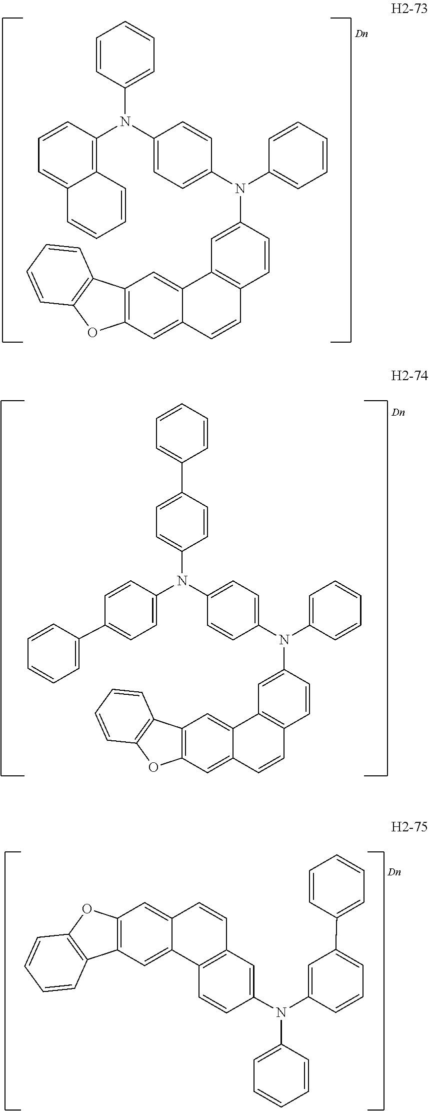 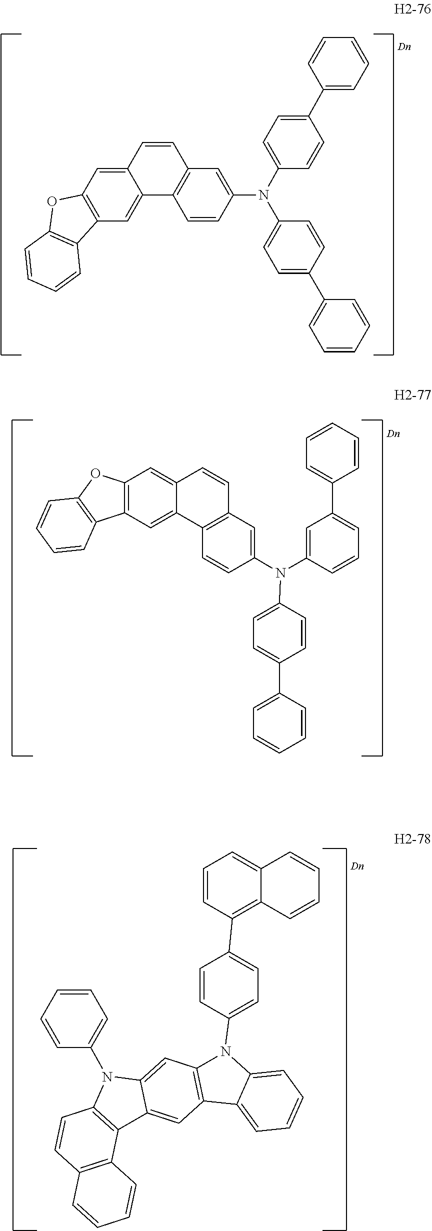 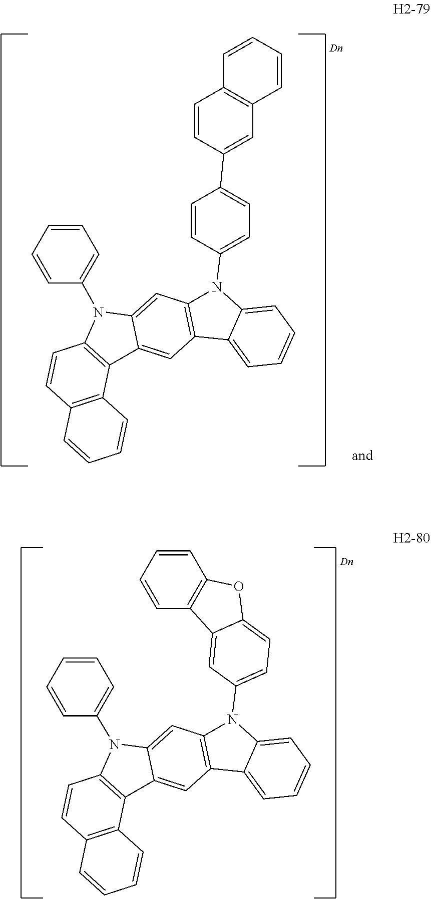
wherein Dₙ means that n number of hydrogens is replaced with deuterium, wherein n is an integer of 1 or more, and the upper limit of n is determined according to the number of hydrogens in the non-deuterated compound.

18. The organic electroluminescent device according to claim 13, wherein the compound represented by Formula 6 or 7 is selected from the following compounds: 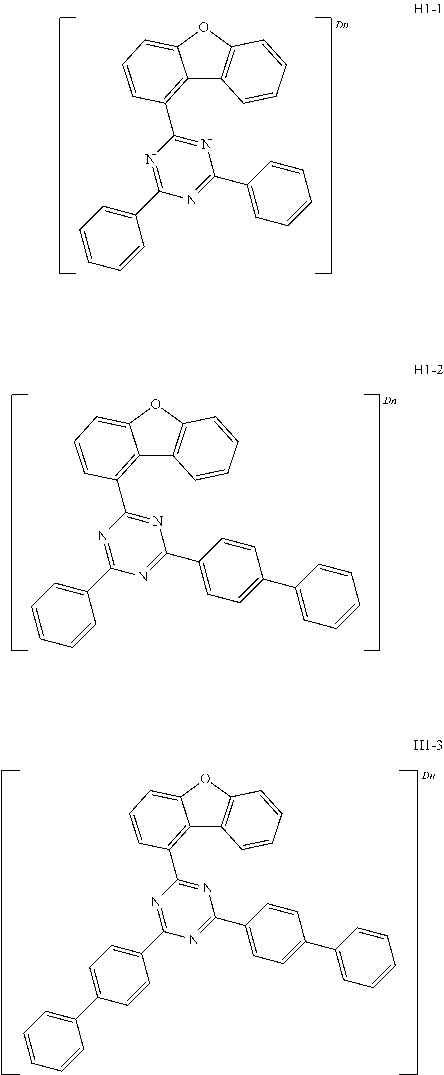 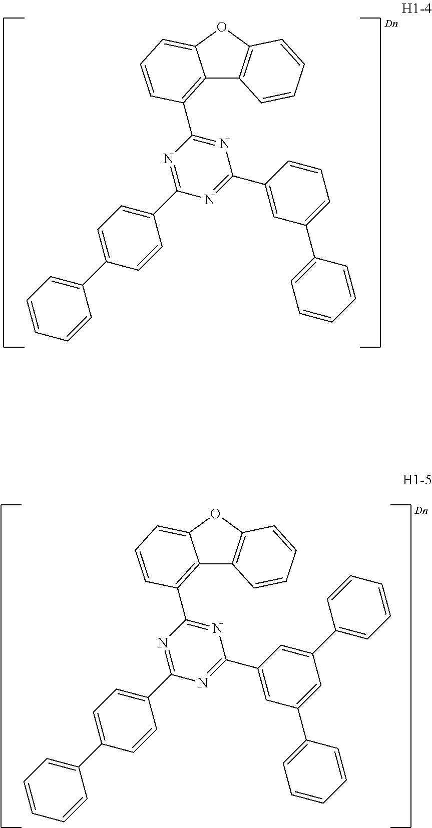 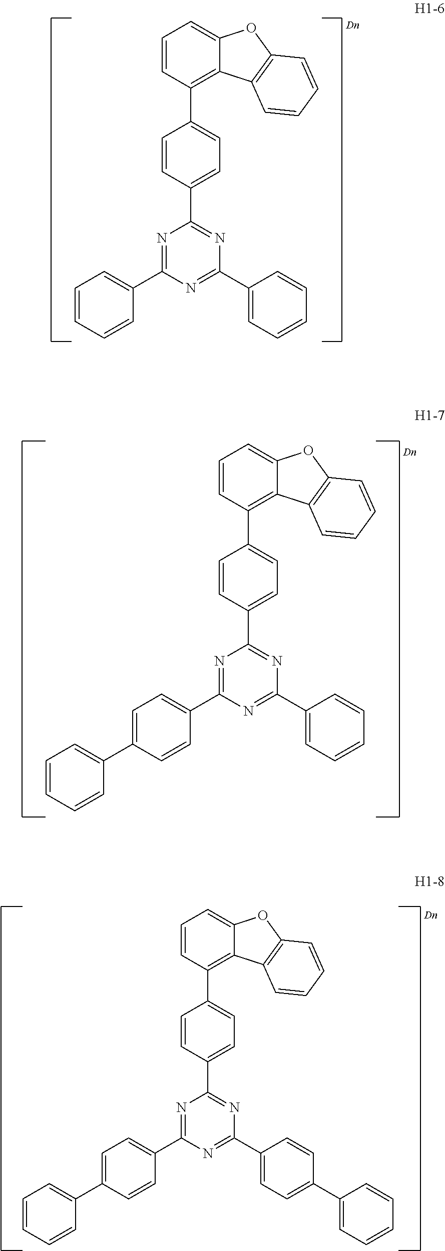 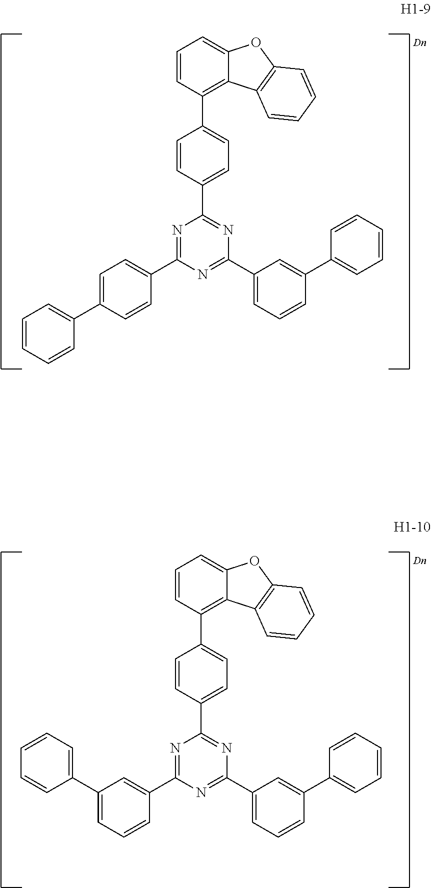 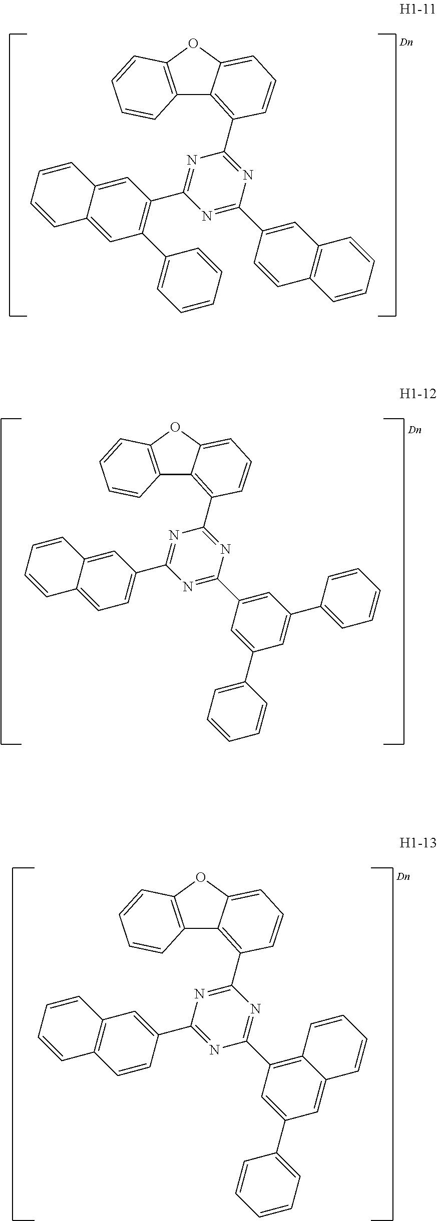 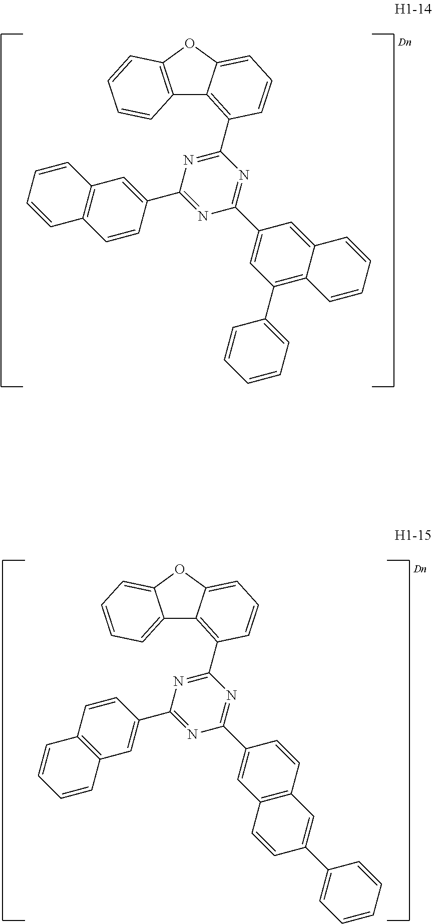 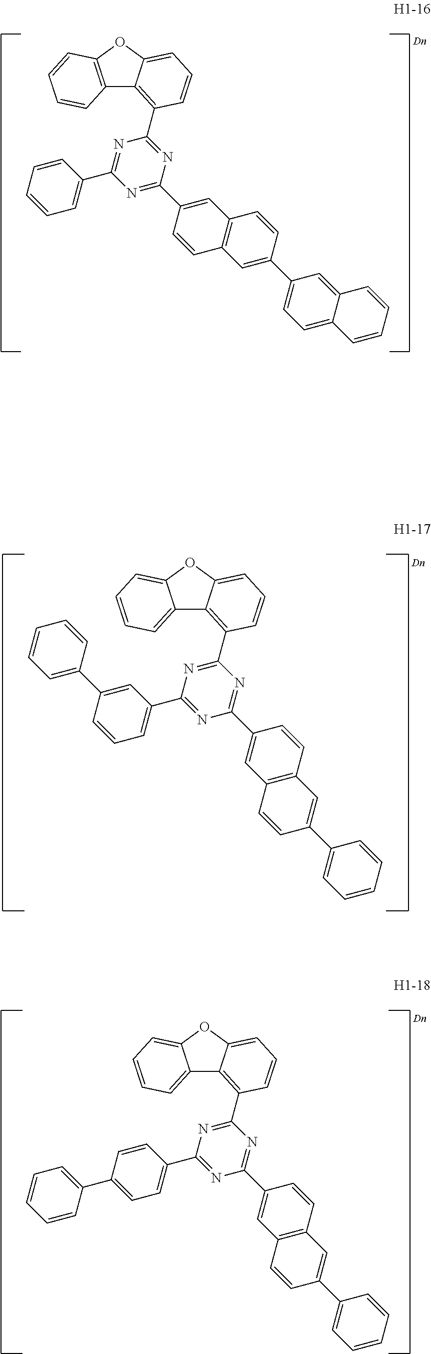 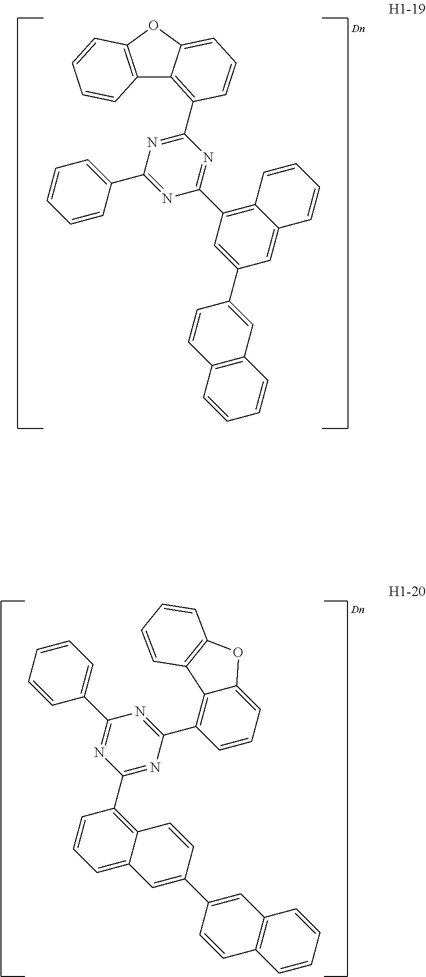 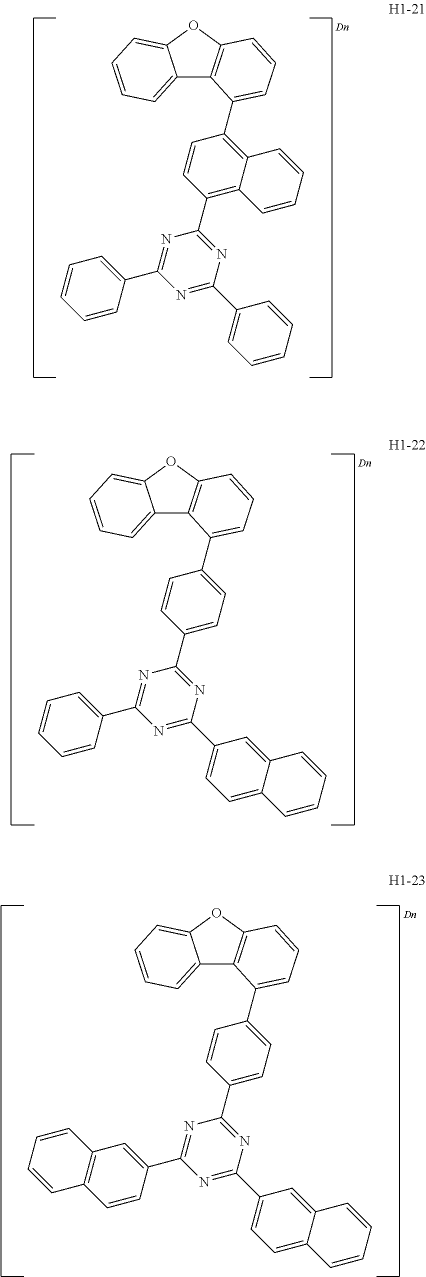 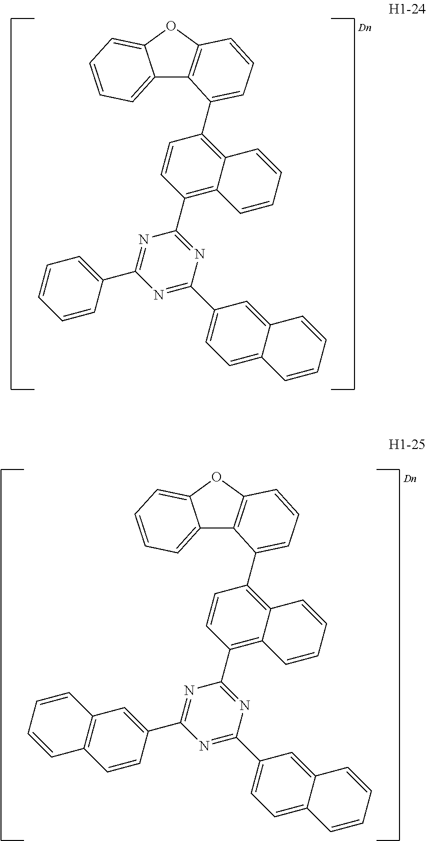 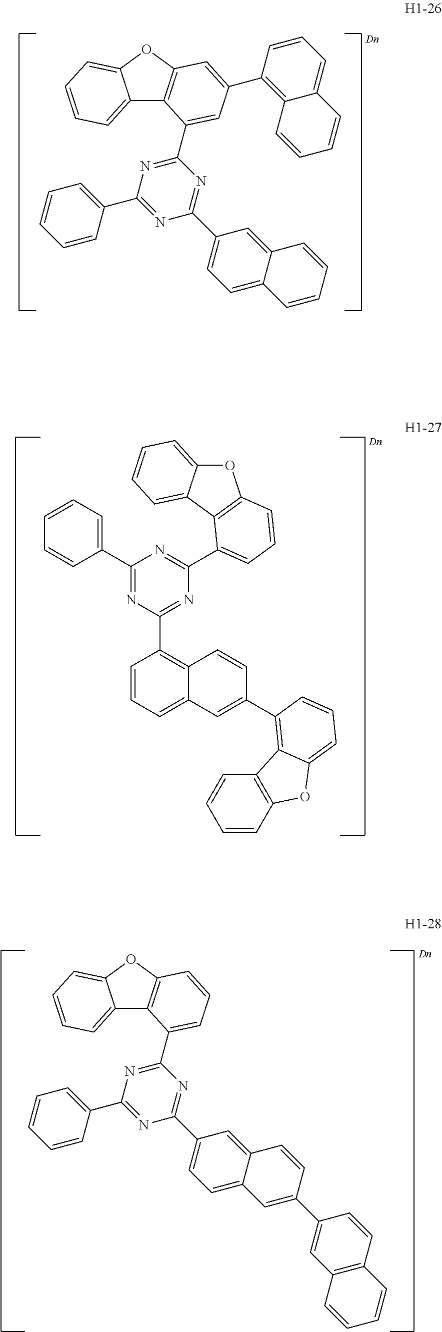 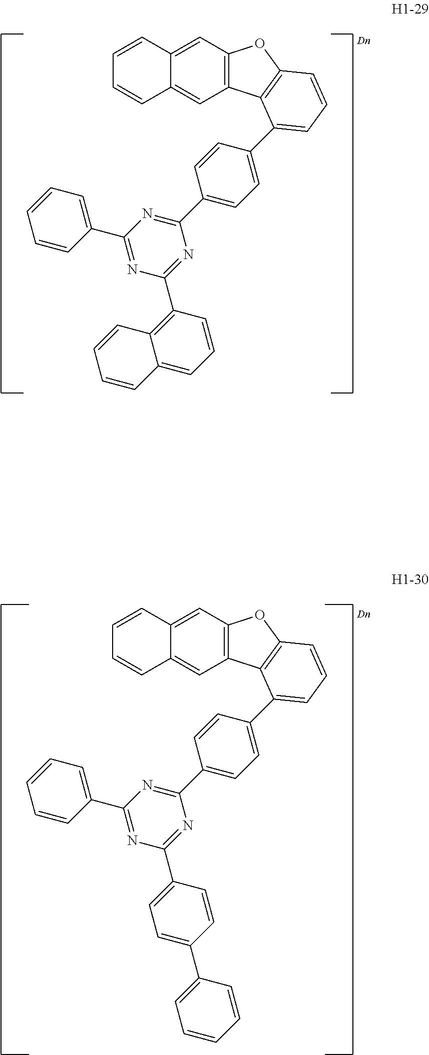 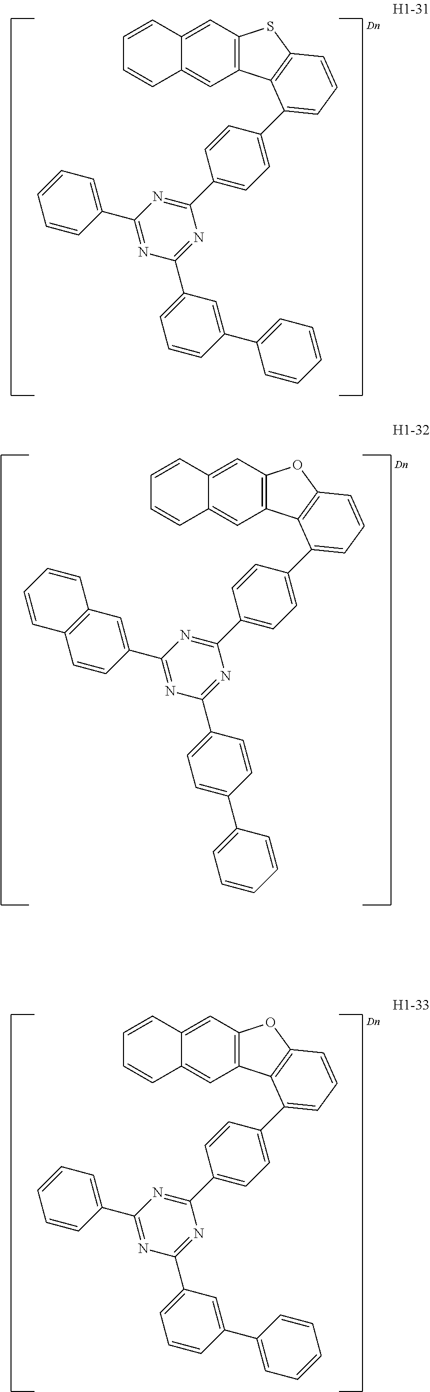 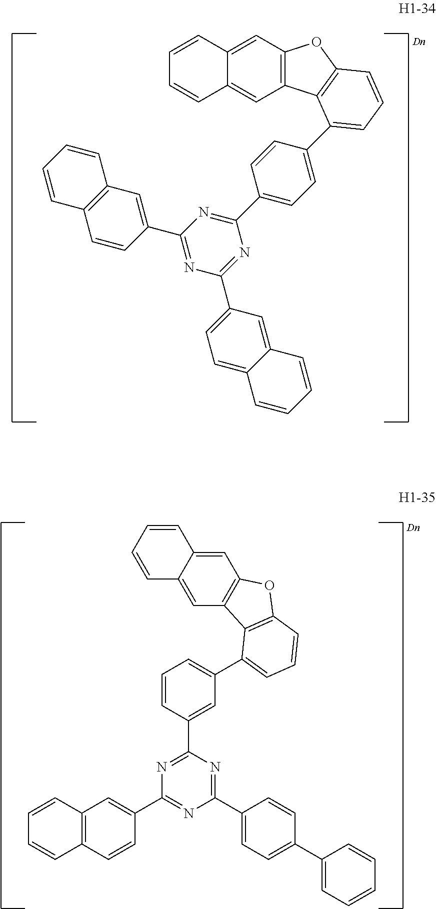 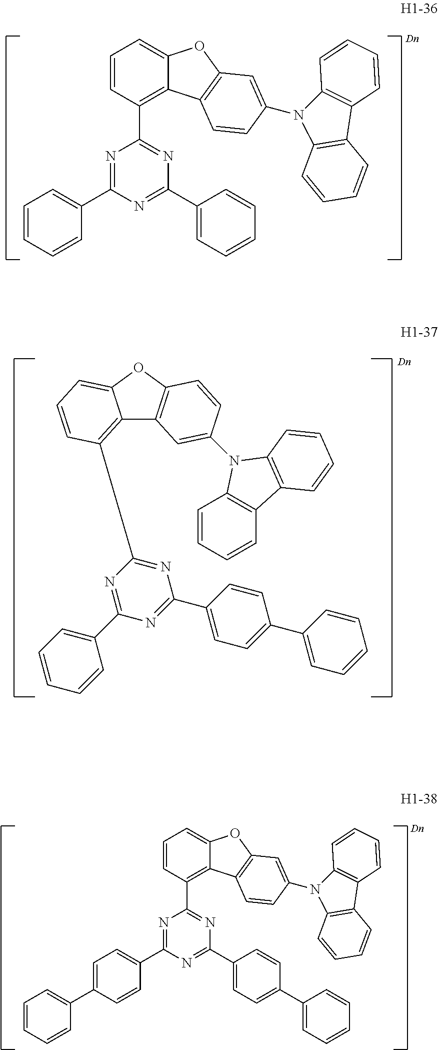 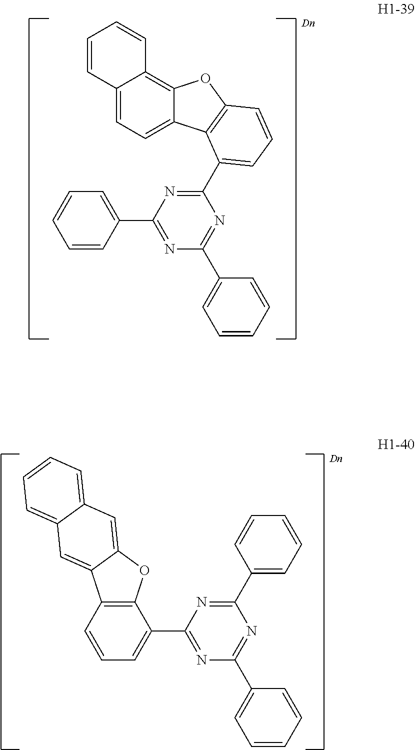 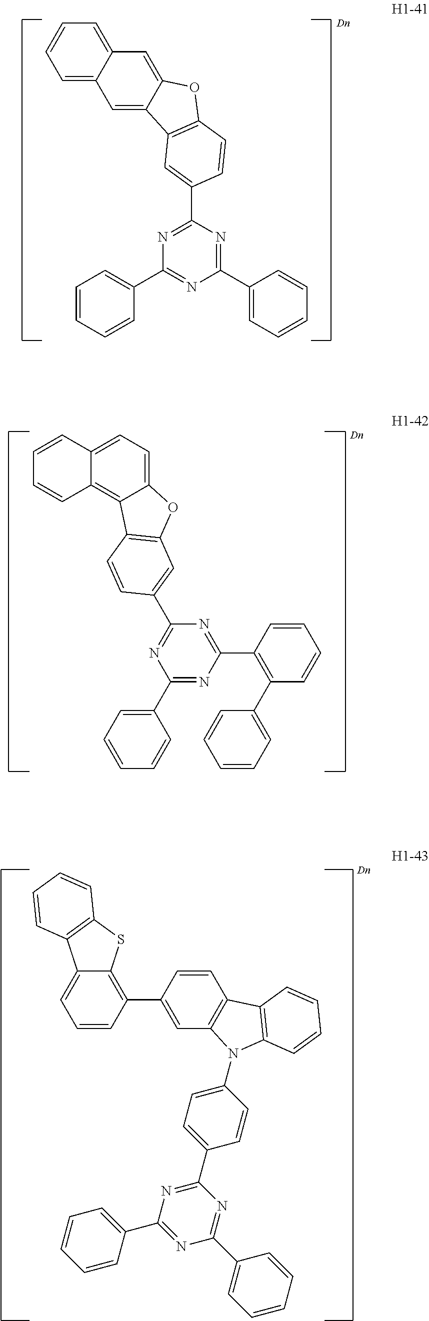 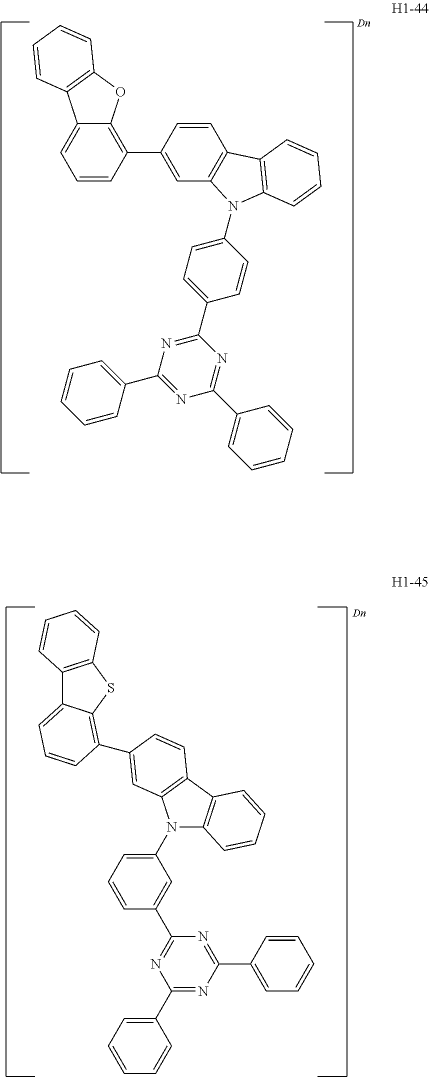 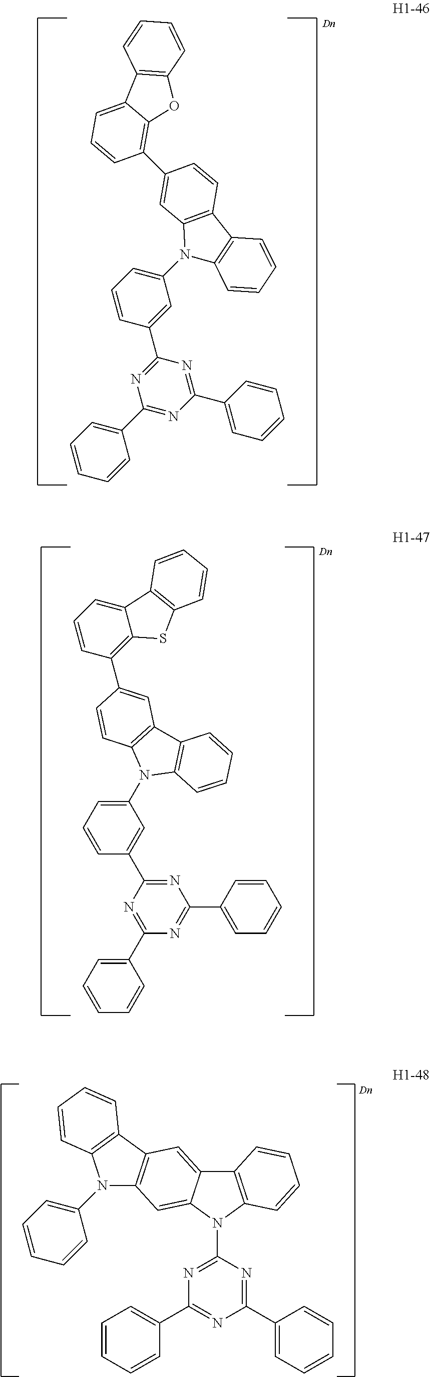 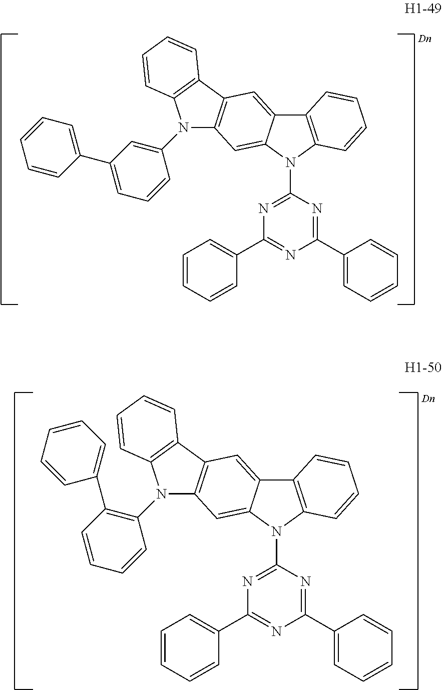 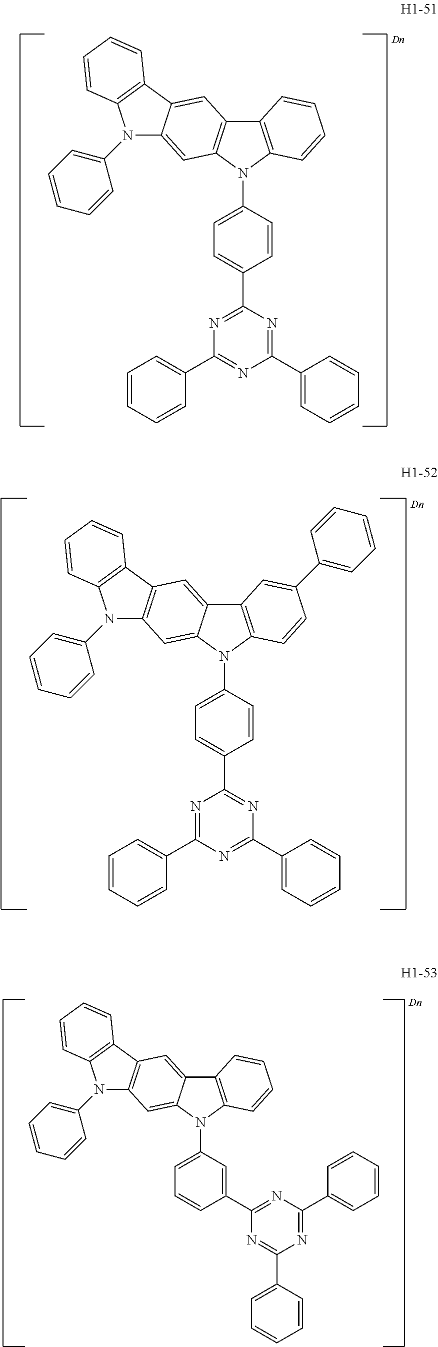 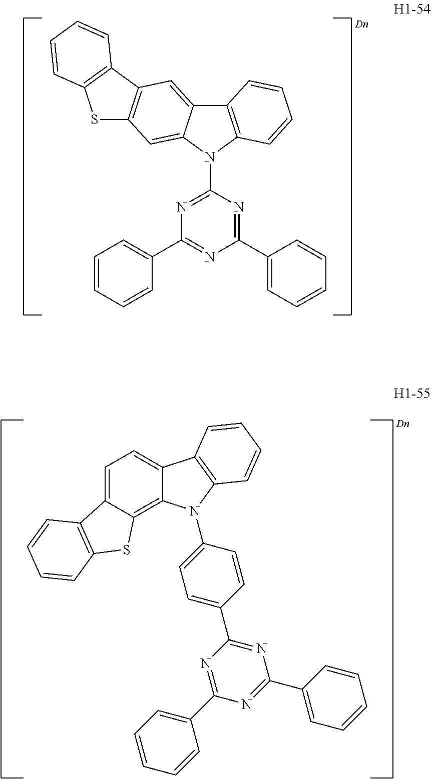 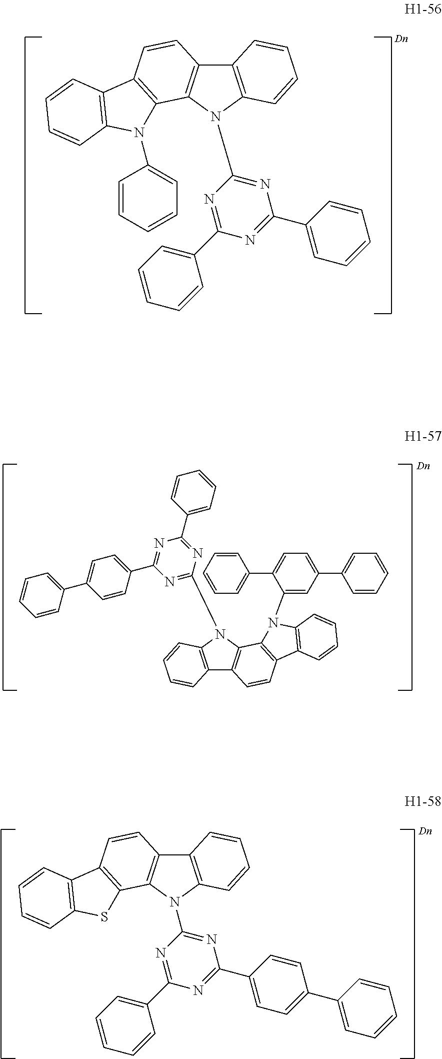 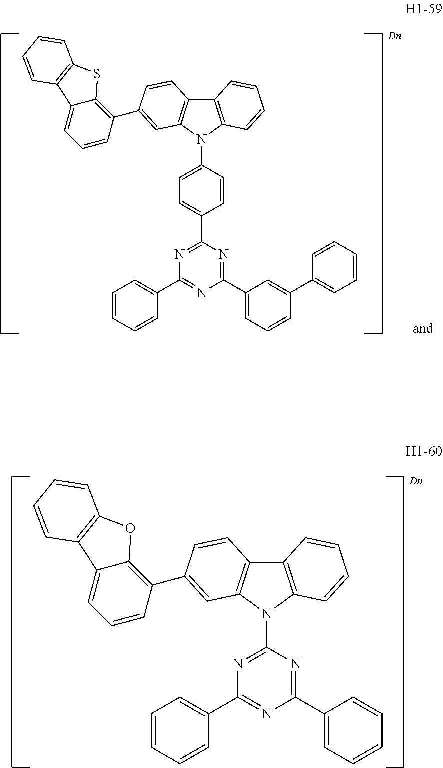
wherein Dₙ means that n number of hydrogens is replaced with deuterium, wherein n is an integer of 1 or more, and the upper limit of n is determined according to the number of hydrogens in the non-deuterated compound.

19. The organic electroluminescent device according to claim 14, wherein the compound represented by Formula 8 is selected from the following compounds. 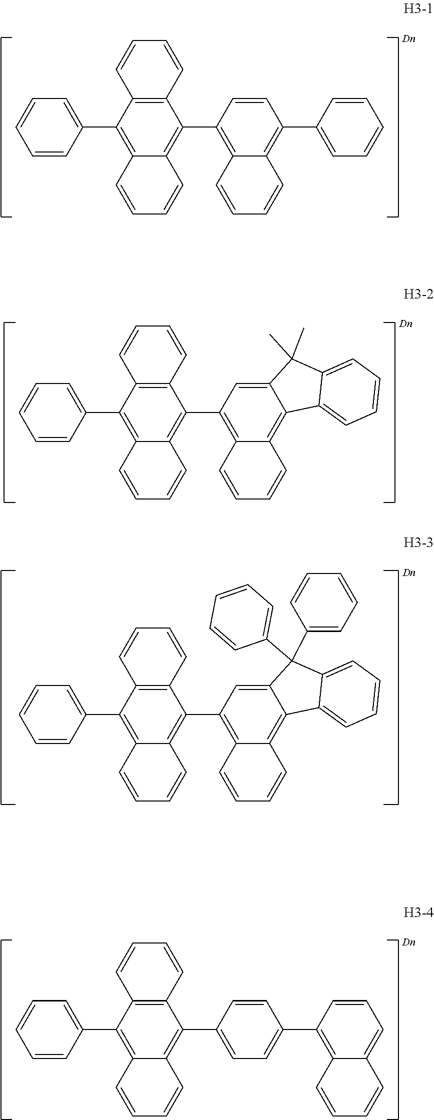 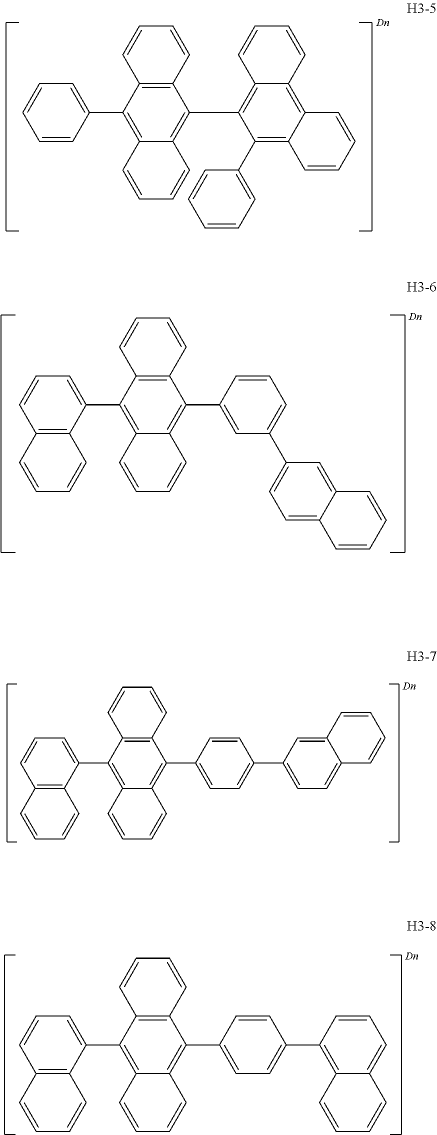 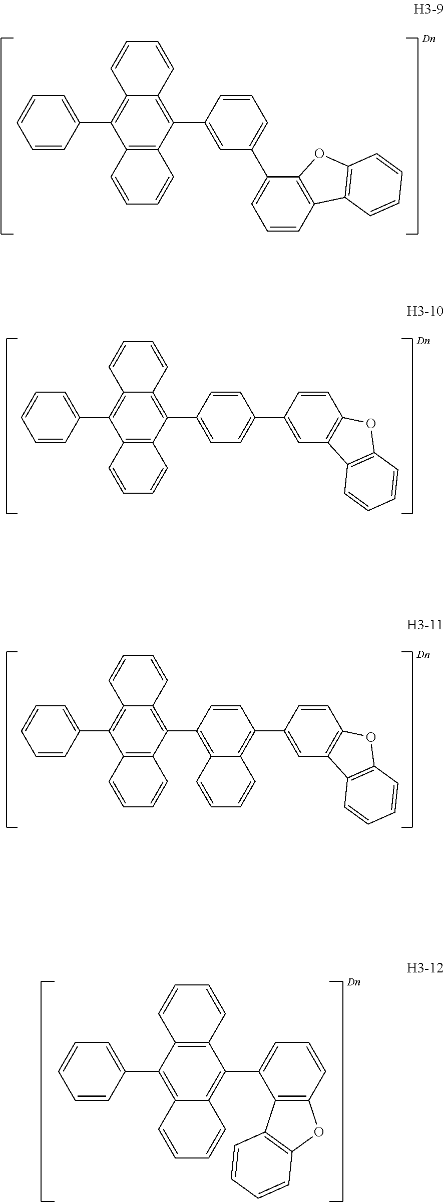 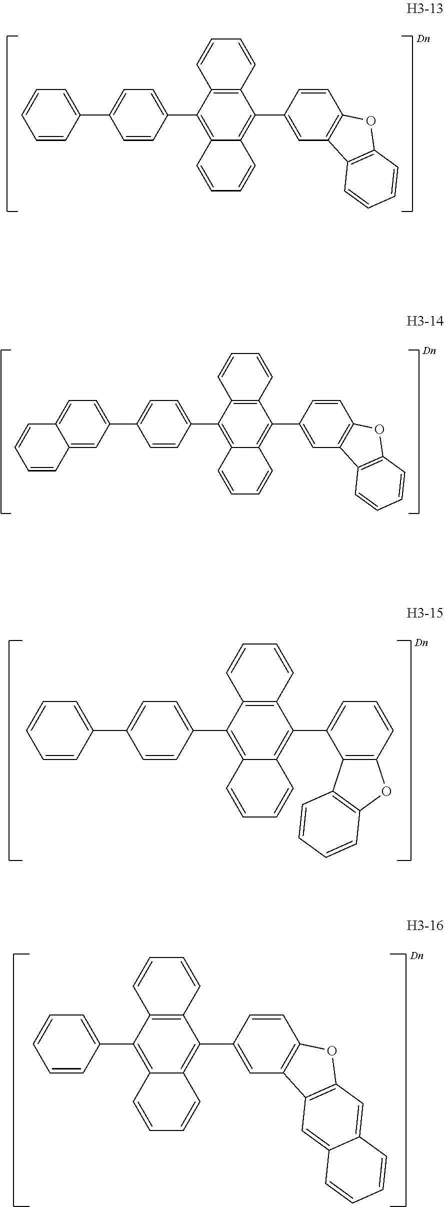 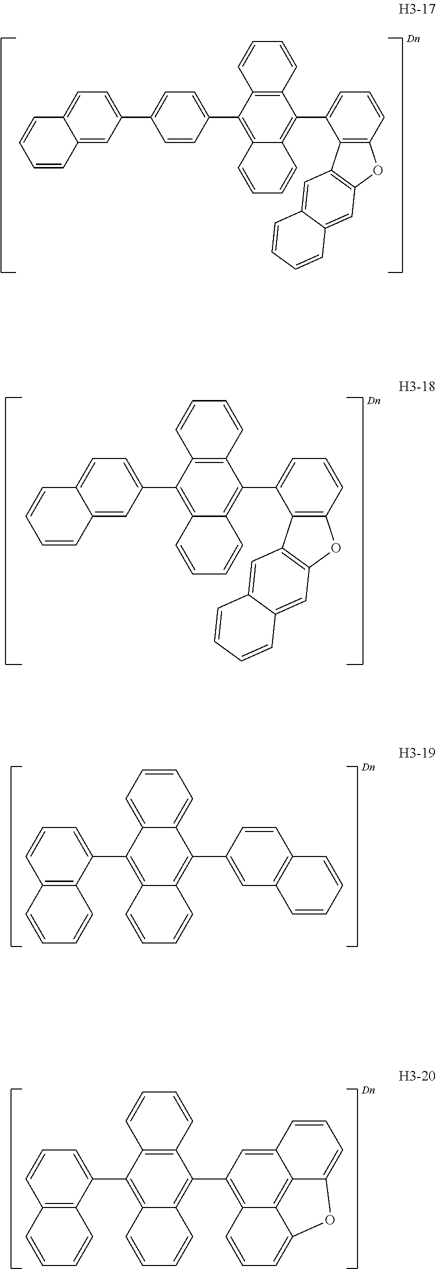 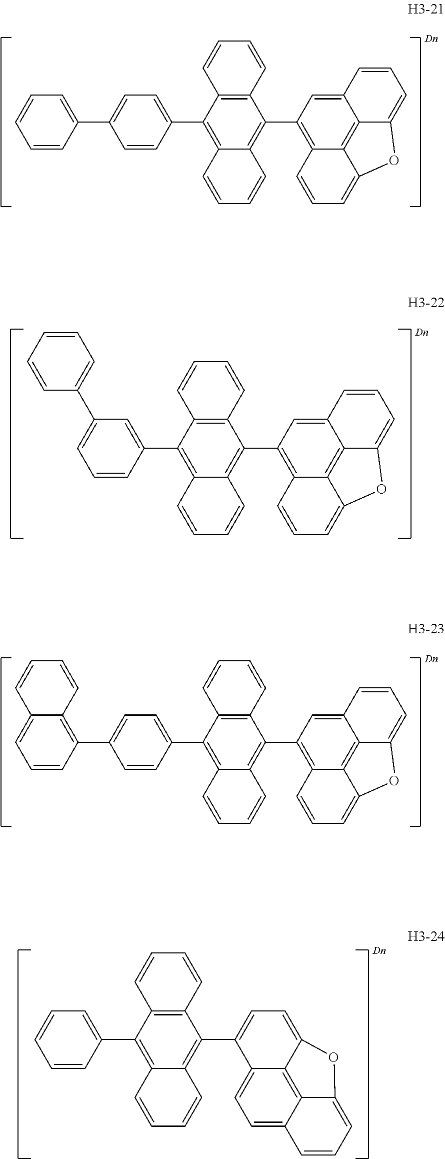 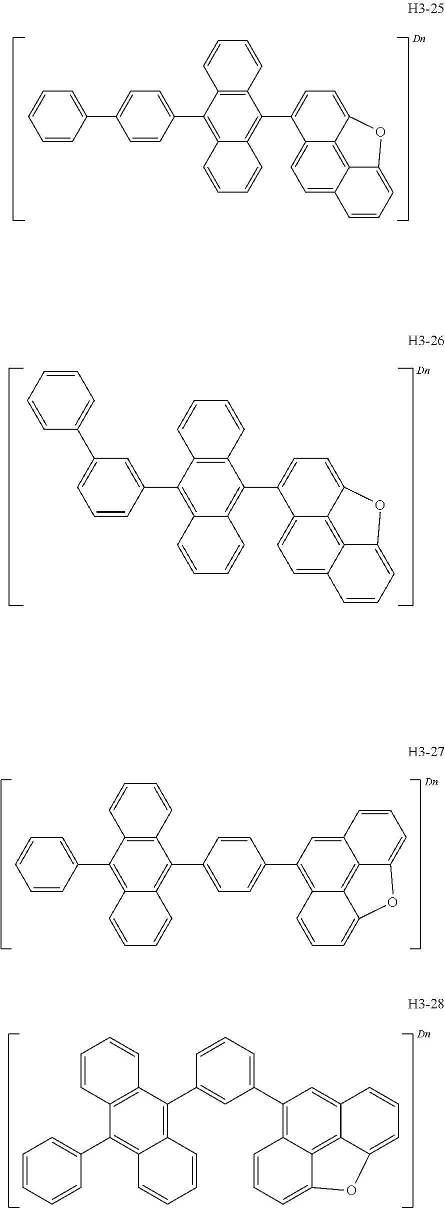 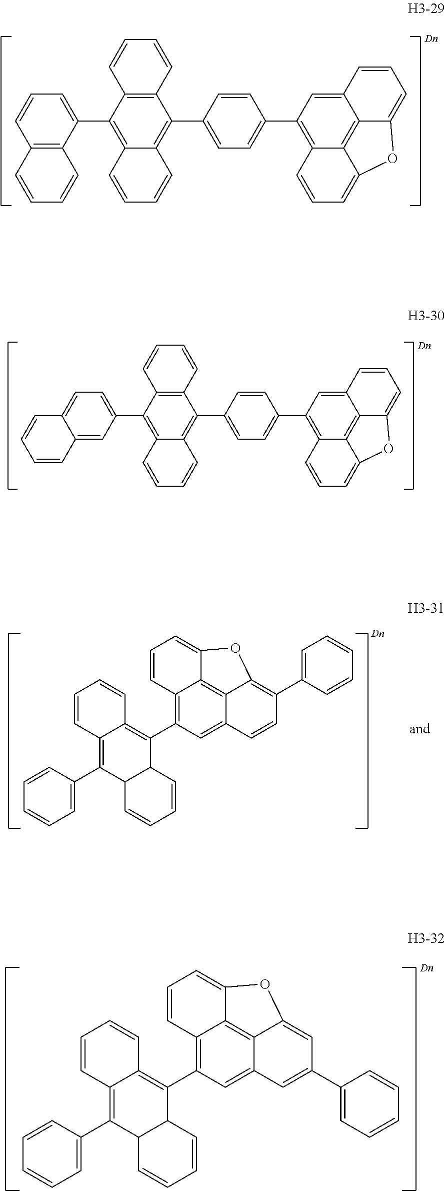
wherein Dₙ means that n number of hydrogens is replaced with deuterium, wherein n is an integer of 1 or more, and the upper limit of n is determined according to the number of hydrogens in the non-deuterated compound.
